(19) United States
(12) Patent Application Publication
(10) Pub. No.: US 2026/0333665 A1
(43) Pub. Date: Oct. 22, 2026

(54) Semiconductor Device And Electronic Device

(71) Applicant: Semiconductor Energy Laboratory Co., Ltd., Kanagawa-ken (JP)

(72) Inventors: Shunpei YAMAZAKI, Setagaya, Tokyo (JP); Hajime KIMURA, Atsugi, Kanagawa (JP); Hidetomo KOBAYASHI, Isehara, Kanagawa (JP); Takanori Takanori MATSUZAKI, Atsugi, Kanagawa (JP); Yuki OKAMOTO, Ebina, Kanagawa (JP); Hiroki INOUE, Atsugi, Kanagawa (JP)

(73) Assignee: Semiconductor Energy Laboratory Co., Ltd., Kanagawa-ken (JP)

(21) Appl. No.: 19/099,589

(22) PCT Filed: Jul. 20, 2023
(86) PCT No.: PCT/IB2023/057379

§ 371 Date: Jan. 29, 2025

(30) Foreign Application Priority Data
Aug. 2, 2022 (JP) 2022-123469
Sep. 9, 2022 (JP) 2022-143801

(51) Int. Cl. H10B 12/00; H10D 1/68; H10D 30/67

(52) U.S. Cl. CPC H10B 12/30; H10B 12/00; H10B 12/33; H10B 12/50; H10D 30/6743; H10D 30/6755; H10D 1/716; H10D 30/6734; H10D 30/6736

(57) ABSTRACT

A semiconductor device with high access speed is provided. The semiconductor device includes a first storage layer, a second storage layer, and a circuit layer. The first storage layer includes a plurality of first storage circuits, the second storage layer includes a second storage circuit, and the circuit layer includes a selector. The selector includes a plurality of input terminals and an output terminal. The first storage layer is positioned below the circuit layer, and the second storage layer is positioned above the circuit layer. The plurality of first storage circuits are electrically connected to the respective input terminals, and the second storage circuit is electrically connected to the output terminal. The selector has a function of establishing electrical continuity between one selected from the plurality of input terminals and the output terminal of the selector. The semiconductor device has a function of writing data read from the second storage circuit to the first storage circuit through the selector.

### TECHNICAL FIELD

One embodiment of the present invention relates to a semiconductor device and an electronic device.

Note that one embodiment of the present invention is not limited to the above technical field. The technical field of the invention disclosed in this specification and the like relates to an object, an operation method, or a manufacturing method. Alternatively, one embodiment of the present invention relates to a process, a machine, manufacture, or a composition of matter. Therefore, specific examples of the technical field of one embodiment of the present invention disclosed in this specification include a semiconductor device, a display apparatus, a liquid crystal display apparatus, a light-emitting apparatus, a power storage device, an imaging device, a memory device, a signal processing device, a sensor, a processor, an electronic device, a system, a driving method thereof, a manufacturing method thereof, and a testing method thereof.

### BACKGROUND ART

In recent years, the amount of data subjected to processing has been increasing, which makes a demand for a memory device having a higher memory capacity. To increase memory capacity per unit area, stacking memory cells as in the case of a 3D NAND memory device or the like is effective (see Patent Document 1 to Patent Document 3). Stacking memory cells can increase memory capacity per unit area in accordance with the number of stacked memory cells.

### REFERENCE

### Patent Document

[Patent Document 1] United States Patent Application Publication No. 2011/0065270

[Patent Document 2] United States Patent Application Publication No. 2016/0149004

[Patent Document 3] United States Patent Application Publication No. 2013/0069052

### SUMMARY OF THE INVENTION

### Problems to be Solved by the Invention

A short time necessary for accessing memory, i.e., a high writing speed and a high reading speed, for example, is requirements for storage devices applicable to a cache memory, a main memory, or the like in computers. For example, an SRAM (Static Random Access Memory) and a DRAM (Dynamic Random Access Memory) each enables an access time (also called a delay time, latency, or the like in some cases) approximately from several nanoseconds to several tens of nanoseconds and thus have been used for a cache memory, a main memory, or the like in computers.

A storage device at the upper level of the memory hierarchy, such as a register or a cache memory, provided in a processor such as a CPU (Central Processing Unit), has smaller storage capacity than a storage device at the lower level of the memory hierarchy; thus, necessary data is not stored in the register or the cache memory in some cases (this is referred to as a cache miss in some cases). When a cache miss occurs, the processor accesses a storage device at the lower level of the memory hierarchy to obtain necessary data (this is referred to as a cache miss penalty in some cases). Data is transmitted between the processor and the storage device at the lower level of the memory hierarchy through a bus wiring. Note that since the access speed from the CPU to the storage device at the lower level of the memory hierarchy is low through the bus wiring, the operation speed of the processor is likely to be affected.

An object of one embodiment of the present invention is to provide a semiconductor device with high access speed. Another object of one embodiment of the present invention is to provide a semiconductor device with reduced power consumption. Another object of one embodiment of the present invention is to provide a semiconductor device with a small circuit area. Another object of one embodiment of the present invention is to provide an electronic device including the above semiconductor device. Another object of one embodiment of the present invention is to provide a novel semiconductor device or a novel electronic device.

Note that the objects of one embodiment of the present invention are not limited to the objects listed above. The objects listed above do not preclude the presence of other objects. Note that the other objects are objects that are not described in this section and are described below. The objects that are not described in this section are derived from the description of the specification, the drawings, and the like and can be extracted as appropriate from the description by those skilled in the art. Note that one embodiment of the present invention is to achieve at least one of the objects listed above and the other objects. Note that one embodiment of the present invention does not necessarily achieve all of the objects listed above and the other objects.

### Means for Solving the Problems

(1) One embodiment of the present invention is a semiconductor device including a first storage layer, a second storage layer, and a circuit layer. The first storage layer includes a plurality of first storage circuits, the second storage layer includes a second storage circuit, and the circuit layer includes a selector. The selector includes a plurality of input terminals and an output terminal. The first storage layer is positioned below the circuit layer, and the second storage layer is positioned above the circuit layer. The plurality of first storage circuits are electrically connected to the respective input terminals, and the second storage circuit is electrically connected to the output terminal. The selector has a function of establishing electrical continuity between one selected from the plurality of input terminals and the output terminal. The semiconductor device has a function of writing data read from the second storage circuit to the first storage circuit through the selector.
(2) Another embodiment of the present invention may be the semiconductor device described in (1) which includes a semiconductor substrate containing silicon. In particular, the first storage layer is preferably positioned over the semiconductor substrate, and the first storage circuit preferably includes a first transistor. Note that the first transistor contains silicon in a channel formation region.
(3) Another embodiment of the present invention may be the semiconductor device described in (2) in which the second storage circuit includes a second transistor. In particular, the second transistor preferably contains a metal oxide in a channel formation region.

Note that the metal oxide contains one or more selected from indium, zinc, and an element M. The element M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, magnesium, and antimony.
(4) Another embodiment of the present invention may be the semiconductor device described in (3) in which the data has a size of 1 bit, 2 bits, 4 bits, 8 bits, 16 bits, 32 bits, 64 bits, 128 bits, or 256 bits.
(5) Another embodiment of the present invention may be the semiconductor device described in (4) in which the first storage circuit and the second storage circuit are not connected through a system bus.
(6) One embodiment of the present invention is a semiconductor device including a first storage layer, a second storage layer, and a circuit layer. The first storage layer includes a plurality of first storage circuits, the second storage layer includes a second storage circuit, and the circuit layer includes a selector. The second storage circuit includes a capacitor and a second transistor. The capacitor includes a first conductor, a second conductor, a first insulator, and a second insulator, and the second transistor includes the second conductor, a third conductor, a fourth conductor, a third insulator, a fourth insulator, and a metal oxide. The selector includes a plurality of input terminals and an output terminal. The first storage layer is positioned below the circuit layer, and the second storage layer is positioned above the circuit layer.

The first insulator includes a first opening. The first conductor is positioned on a side surface and a bottom surface of the first opening and a top surface of the first insulator. The second insulator is positioned on a top surface of the first insulator and a top surface of the first conductor. The second conductor is positioned in a region of a top surface of the second insulator that overlaps with the first conductor. The third insulator is positioned on a top surface of the second conductor, and the third conductor is positioned on a top surface of the third insulator. The third insulator and the third conductor include a second opening. The metal oxide is positioned on a side surface of the second opening, a top surface of the second conductor, and a top surface of the third conductor. The fourth insulator is positioned on a top surface of the metal oxide and a top surface of the third conductor. The fourth conductor is positioned in a region of a top surface of the fourth insulator that overlaps with the metal oxide.

The plurality of first storage circuits are electrically connected to the respective input terminals, and the third conductor is electrically connected to the output terminal. The selector has a function of establishing electrical continuity between one selected from the plurality of input terminals and the output terminal. The semiconductor device has a function of writing data read from the second storage circuit to the first storage circuit through the selector.
(7) Another embodiment of the present invention may be the semiconductor device described in (6) in which the metal oxide includes one or more selected from indium, zinc, and an element M.

Note that the element Mis one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, magnesium, and antimony.
(8) Another embodiment of the present invention may be the semiconductor device described in (7) which includes a semiconductor substrate containing silicon. In particular, the first storage layer is preferably positioned over the semiconductor substrate, and the first storage circuit preferably includes a first transistor. Note that the first transistor contains silicon in a channel formation region.
(9) Another embodiment of the present invention may be the semiconductor device described in (8) in which the second insulator includes oxide containing one or more selected from hafnium, aluminum, gallium, yttrium, zirconium, tungsten, titanium, tantalum, nickel, germanium, and magnesium.
(10) Another embodiment of the present invention may be the semiconductor device described in (9) in which the data has a size of 1 bit, 2 bits, 4 bits, 8 bits, 16 bits, 32 bits, 64 bits, 128 bits, or 256 bits.
(11) Another embodiment of the present invention may be the semiconductor device described in (10) in which the first storage circuit and the second storage circuit are not connected through a system bus.
(12) Another embodiment of the present invention is an electronic device including any one of the semiconductor devices described above in (1) to (11) and a housing.

### Effect of the Invention

One embodiment of the present invention can provide a semiconductor device with high access speed. Another embodiment of the present invention can provide a semiconductor device with reduced power consumption. Another embodiment of the present invention can provide a semiconductor device with a small circuit area. Another embodiment of the present invention can provide an electronic device including the above semiconductor device. Another embodiment of the present invention can provide a novel semiconductor device or a novel electronic device.

Note that the effects of one embodiment of the present invention are not limited to the effects listed above. The effects listed above do not preclude the presence of other effects. The other effects are effects that are not described in this section and will be described below. The effects that are not described in this section can be derived from the description of the specification, the drawings, and the like and can be extracted as appropriate from the description by those skilled in the art. One embodiment of the present invention has at least one of the effects listed above and the other effects. Accordingly, one embodiment of the present invention does not have the effects listed above in some cases.

### BRIEF DESCRIPTION OF THE DRAWINGS

FIG. 1A is a schematic perspective view illustrating a structure example of a semiconductor device, and FIG. 1B is a block diagram illustrating a structure example of the semiconductor device.

FIG. 2 is a conceptual diagram illustrating a memory hierarchy in which a plurality of storage devices provided in a computer are associated with each other.

FIG. 3 is a schematic perspective view illustrating a structure example of a semiconductor device.

FIG. 4 is a schematic perspective view illustrating a structure example of a semiconductor device.

FIG. 5 is a block diagram illustrating a structure example of a semiconductor device.

FIG. 6 is a block diagram illustrating a structure example of a semiconductor device.

FIG. 7 is a circuit diagram illustrating a structure example of a semiconductor device.

FIG. 8A and FIG. 8B are circuit diagrams illustrating structure examples of a semiconductor device.

FIG. 9 is a block diagram illustrating a structure example of a semiconductor device.

FIG. 10 is a circuit diagram illustrating a structure example of a semiconductor device.

FIG. 11 is a circuit diagram illustrating a structure example of a semiconductor device.

FIG. 12 is a block diagram illustrating a structure example of a semiconductor device.

FIG. 13 is a block diagram illustrating a structure example of a semiconductor device.

FIG. 14 is a circuit diagram illustrating a structure example of a semiconductor device.

FIG. 15 is a schematic perspective view illustrating a structure example of a storage device.

FIG. 16 is a block diagram illustrating a structure example of a semiconductor device.

FIG. 17 is a block diagram illustrating a structure example of a storage circuit provided in a semiconductor device.

FIG. 18A to FIG. 18E are circuit diagrams illustrating structure examples of a memory cell provided in a semiconductor device.

FIG. 19A to FIG. 19C are circuit diagrams illustrating structure examples of a memory cell provided in a semiconductor device.

FIG. 20A and FIG. 20B are circuit diagrams illustrating structure examples of a memory cell provided in a semiconductor device.

FIG. 21 is a schematic cross-sectional view illustrating a structure example of a semiconductor device.

FIG. 22 is a schematic cross-sectional view illustrating a structure example of a semiconductor device.

FIG. 23A and FIG. 23B are schematic cross-sectional views illustrating structure examples of a transistor included in a semiconductor device.

FIG. 24 is a schematic cross-sectional view illustrating a structure example of a transistor included in a semiconductor device.

FIG. 25 is a schematic cross-sectional view illustrating a structure example of a capacitor included in a semiconductor device.

FIG. 26 is a schematic cross-sectional view illustrating a structure example of a semiconductor device.

FIG. 27A to FIG. 27C are plan views illustrating a structure example of a transistor included in a semiconductor device, and FIG. 27D is a cross-sectional view illustrating the structure example of the transistor included in the semiconductor device.

FIG. 28A is a plan view illustrating a structure example of a transistor included in a semiconductor device, and FIG. 28B is a cross-sectional view illustrating the structure example of the transistor included in the semiconductor device.

FIG. 29A and FIG. 29B are diagrams illustrating examples of electronic components.

FIG. 30A and FIG. 30B are diagrams illustrating examples of electronic devices, and FIG. 30C to FIG. 30E are diagrams illustrating an example of a large computer.

FIG. 31 is a diagram illustrating an example of a device for space.

FIG. 32 is a diagram illustrating an example of a storage system that can be used for a data center.

FIG. 33A is a schematic perspective view illustrating a structure example of a display apparatus, and FIG. 33B is a block diagram illustrating the structure example of the display apparatus.

FIG. 34 is a circuit diagram illustrating a configuration example of a pixel circuit included in a display apparatus.

FIG. 35 is a schematic perspective view illustrating a structure example of a stacked-layer structure included in a display apparatus.

FIG. 36A to FIG. 36I are perspective views illustrating examples of electronic devices.

### MODE FOR CARRYING OUT THE INVENTION

In this specification and the like, a semiconductor device refers to a device that utilizes semiconductor characteristics, and means a circuit including a semiconductor element (e.g., a transistor, a diode, and a photodiode), or a device including the circuit. The semiconductor device also means all devices that can function by utilizing semiconductor characteristics. For example, an integrated circuit, a chip including an integrated circuit, and an electronic component including a chip in a package are each an example of the semiconductor device. Moreover, a memory device, a display apparatus, a light-emitting apparatus, a lighting device, an electronic device, and the like themselves are semiconductor devices in some cases and include semiconductor devices in other cases.

In the case where there is description “X and Y are connected” in this specification and the like, the case where X and Y are electrically connected, the case where X and Y are functionally connected, and the case where X and Y are directly connected are regarded as being disclosed in this specification and the like. Accordingly, without being limited to a predetermined connection relation, for example, a connection relation shown in drawings or texts, a connection relation other than one shown in drawings or texts is regarded as being disclosed in the drawings or the texts. Each of X and Y denotes an object (e.g., a device, an element, a circuit, a wiring, an electrode, a terminal, a conductive film, or a layer).

For example, in the case where X and Y are electrically connected, one or more elements that allow electrical connection between X and Y (e.g., a switch, a transistor, a capacitor, an inductor, a resistor, a diode, a display device, a light-emitting device, and a load) can be connected between X and Y. Note that a switch has a function of being controlled to be turned on or off. That is, the switch has a function of being in a conducting state (on state) or a non-conducting state (off state) to control whether current flows or not.

In the case where an element and a power supply line (e.g., a wiring supplying VDD (high power supply potential), VSS (low power supply potential), GND (the ground potential), or a desired potential) are both provided between X and Y, X and Y are not defined as being electrically connected. In the case where only a power supply line is provided between X and Y, there is no element between X and Y; therefore, X and Y are directly connected. Accordingly, in the case where only a power supply line is provided between X and Y, X and Y can be expressed as being “electrically connected”. However, in the case where an element and a power supply line are both provided between X and Y, X and Y are not defined as being electrically connected, although X and the power supply line are electrically connected (through the element) and Y and the power supply line are electrically connected. Note that in the case where a gate and a source of a transistor are provided between X and Y, X and Y are not defined as being electrically connected. Note that in the case where a gate and a drain of a transistor are provided between X and Y, X and Y are not defined as being electrically connected. That is, in the case where a drain and a source of a transistor are provided between X and Y, X and Y are defined as being electrically connected. Note that in the case where a capacitor is provided between X and Y, X and Y are defined as being electrically connected in some cases and not defined in other cases. For example, in the case where a capacitor is provided between X and Y in a structure of a digital circuit or a logic circuit, X and Y are not defined as being electrically connected in some cases. On the other hand, for example, in the case where a capacitor is provided between X and Y in a structure of an analog circuit, X and Y are defined as being electrically connected in some cases.

For example, in the case where X and Y are functionally connected, one or more circuits that allow functional connection between X and Y (e.g., a logic circuit (e.g., an inverter, a NAND circuit, or a NOR circuit); a signal converter circuit (e.g., a digital-analog converter circuit, an analog-digital converter circuit, or a gamma correction circuit); a potential level converter circuit (e.g., a power supply circuit such as a step-up circuit or a step-down circuit, or a level shifter circuit for changing the potential level of a signal); a voltage source; a current source; a switching circuit; an amplifier circuit (e.g., a circuit that can increase signal amplitude, the amount of a current, or the like, an operational amplifier, a differential amplifier circuit, a source follower circuit, or a buffer circuit); a signal generation circuit; a memory circuit; or a control circuit) can be connected between X and Y. For instance, even if another circuit is provided between X and Y, X and Y are regarded as being functionally connected when a signal output from X is transmitted to Y.

Note that an explicit description “X and Y are electrically connected” includes the case where X and Y are electrically connected (i.e., the case where X and Y are connected with another element or another circuit provided therebetween) and the case where X and Y are directly connected (i.e., the case where X and Y are connected without another element or another circuit provided therebetween).

For example, an expression “X, Y, a source (sometimes called one of a first terminal and a second terminal) of a transistor, and a drain (sometimes called the other of the first terminal and the second terminal) of the transistor are electrically connected to each other, and X, the source of the transistor, the drain of the transistor, and Y are electrically connected to each other in this order” can be used. Alternatively, an expression “a source of a transistor is electrically connected to X; a drain of the transistor is electrically connected to Y; and X, the source of the transistor, the drain of the transistor, and Y are electrically connected to each other in this order” can be used. Alternatively, the expression “X is electrically connected to Y through a source and a drain of a transistor, and X, the source of the transistor, the drain of the transistor, and Y are provided in this connection order” can be used. When the connection order in a circuit structure is defined by an expression like the above examples, a source and a drain of a transistor can be distinguished from each other to specify the technical scope. Note that these expressions are non-limiting examples. Here, X and Y each denote an object (e.g., a device, an element, a circuit, a wiring, an electrode, a terminal, a conductive film, or a layer).

Even when independent components are electrically connected to each other in a circuit diagram, one component has functions of a plurality of components in some cases. For example, when part of a wiring also functions as an electrode, one conductive film has both functions of a wiring and an electrode. Thus, electrical connection in this specification includes, in its category, such a case where one conductive film has functions of a plurality of components.

In this specification and the like, a “resistor” can be, for example, a circuit element having a resistance value higher than 0Ω or a wiring having a resistance value higher than 0Ω. Therefore, in this specification and the like, a “resistor” includes a wiring having a resistance value, a transistor in which a current flows between a source and a drain, a diode, and a coil. Thus, the term “resistor” can sometimes be replaced with the terms “resistance”, “load”, or “region having a resistance value”. Conversely, the terms “resistance”, “load”, or “region having a resistance value” can sometimes be replaced with the term “resistor”. The resistance value can be, for example, preferably higher than or equal to 1 mΩ and lower than or equal to 10Ω, further preferably higher than or equal to 5 mΩ and lower than or equal to 5Ω, still further preferably higher than or equal to 10 mΩ and lower than or equal to 1Ω. For another example, the resistance value may be higher than or equal to 1Ω and lower than or equal to 1×10⁹Ω.

In this specification and the like, a “capacitor” can be, for example, a circuit element having an electrostatic capacitance value higher than 0 F, a region of a wiring having an electrostatic capacitance value higher than 0 F, parasitic capacitance, or gate capacitance of a transistor. The term “capacitor”, “parasitic capacitance”, or “gate capacitance” can be replaced with the term “capacitance” in some cases. Conversely, the term “capacitance” can be replaced with the term “capacitor”, “parasitic capacitance”, or “gate capacitance” in some cases. In addition, a “capacitor” (including a “capacitor” with three or more terminals) includes an insulator and a pair of conductors between which the insulator is interposed. Thus, the term “pair of conductors” of “capacitor” can be replaced with “pair of electrodes”, “pair of conductive regions”, “pair of regions”, or “pair of terminals”. In addition, the terms “one of a pair of terminals” and “the other of the pair of terminals” are referred to as a first terminal and a second terminal, respectively, in some cases. Note that the electrostatic capacitance value can be higher than or equal to 0.05 fF and lower than or equal to 10 pF, for example. For another example, the electrostatic capacitance value may be higher than or equal to 1 pF and lower than or equal to 10 μF.

In this specification and the like, a transistor includes three terminals called a gate, a source, and a drain. The gate is a control terminal for controlling the conduction state of the transistor. Two terminals functioning as the source and the drain are input/output terminals of the transistor. One of the two input/output terminals serves as the source and the other serves as the drain on the basis of the conductivity type (n-channel type or p-channel type) of the transistor and the levels of potentials applied to the three terminals of the transistor. Thus, the terms “source” and “drain” can sometimes be replaced with each other in this specification and the like. In this specification and the like, expressions “one of a source and a drain” (or a first electrode or a first terminal) and “the other of the source and the drain” (or a second electrode or a second terminal) are used in description of the connection relation of a transistor. Depending on the transistor structure, a transistor may include a back gate in addition to the above three terminals. In that case, in this specification and the like, one of the gate and the back gate of the transistor may be referred to as a first gate and the other of the gate and the back gate of the transistor may be referred to as a second gate. Moreover, the terms “gate” and “back gate” can be replaced with each other in one transistor in some cases. In the case where a transistor includes three or more gates, the gates may be referred to as a first gate, a second gate, a third gate, and the like in this specification and the like.

In this specification and the like, for example, a transistor with a multi-gate structure having two or more gate electrodes can be used as the transistor. With the multi-gate structure, channel formation regions are connected in series; accordingly, a plurality of transistors are connected in series. Thus, with the multi-gate structure, the amount of an off-state current can be reduced, and the breakdown voltage of the transistor can be increased (the reliability can be improved). Alternatively, with the multi-gate structure, drain-source current does not change very much even if drain-source voltage changes at the time of an operation in a saturation region, so that a flat slope of voltage-current characteristics can be obtained. By utilizing the flat slope of the voltage-current characteristics, an ideal current source circuit or an active load having an extremely high resistance value can be obtained. Accordingly, a differential circuit, a current mirror circuit, and the like having excellent properties can be obtained.

The case where a single circuit element is illustrated in a circuit diagram may include a case where the circuit element includes a plurality of circuit elements. For example, the case where a single resistor is illustrated in a circuit diagram may include a case where two or more resistors are electrically connected to each other in series. For another example, the case where a single capacitor is illustrated in a circuit diagram may include a case where two or more capacitors are electrically connected to each other in parallel. For another example, the case where a single transistor is illustrated in a circuit diagram may include a case where two or more transistors are electrically connected to each other in series and their gates are electrically connected to each other. Similarly, for another example, the case where a single switch is illustrated in a circuit diagram may include a case where the switch includes two or more transistors which are electrically connected to each other in series or in parallel and whose gates are electrically connected to each other.

In this specification and the like, a node can be referred to as a terminal, a wiring, an electrode, a conductive layer, a conductor, or an impurity region depending on the circuit structure and the device structure. Furthermore, a terminal, a wiring, or the like can be referred to as a node.

In this specification and the like, a selector sometimes refers to, for example, a circuit in which a plurality of input terminals and one output terminal are included, one of the plurality of input terminals is selected, and electrical continuity is established between the selected input terminal and the one output terminal. In other words, the selector is sometimes a circuit in which one of input signals input to the plurality of input terminals is selected and the selected input signal is output to the output terminal. Alternatively, for example, a selector sometimes refers to a circuit in which a plurality of output terminals and one input terminal are included, one of the plurality of output terminals is selected, and electrical continuity is established between the selected output terminal and the one input terminal. In other words, the selector is sometimes a circuit in which one of the plurality of output terminals is selected and an input signal input to the input terminal is output to the selected output terminal. That is, the selector sometimes refers to a multiplexer or a demultiplexer.

In this specification and the like, a “voltage” and a “potential” can be replaced with each other as appropriate. A “voltage” refers to a potential difference from a reference potential, and when the reference potential is a ground potential, for example, a “voltage” can be replaced with a “potential”. Note that the ground potential does not necessarily mean 0 V. Moreover, potentials are relative values, and a potential supplied to a wiring, a potential applied to a circuit or the like, and a potential output from a circuit or the like, for example, change with a change of the reference potential.

In this specification and the like, the terms “high-level potential” and “low-level potential” do not mean a particular potential. For example, in the case where two wirings are both described as “functioning as a wiring for supplying a high-level potential”, the levels of the high-level potentials supplied from the wirings are not necessarily equal to each other. Similarly, in the case where two wirings are both described as “functioning as a wiring for supplying a low-level potential”, the levels of the low-level potentials supplied from the wirings are not necessarily equal to each other.

A “current” means a charge transfer phenomenon (electrical conduction); for example, the description “electrical conduction of positively charged particles occurs” can be rephrased as “electrical conduction of negatively charged particles occurs in the opposite direction”. Therefore, unless otherwise specified, a “current” in this specification and the like refers to a charge transfer phenomenon (electrical conduction) accompanying carrier movement. Examples of a carrier here include an electron, a hole, an anion, a cation, and a complex ion, and the type of carrier differs between current flow systems (e.g., a semiconductor, a metal, an electrolyte solution, and a vacuum). The “direction of a current” in a wiring or the like refers to the direction in which a carrier with positive charge moves, and the amount of the current is expressed as a positive value. In other words, the direction in which a carrier with negative charge moves is opposite to the direction of a current, and the amount of the current is expressed as a negative value. Thus, in the case where the polarity of a current (or the direction of a current) is not specified in this specification and the like, the description “a current flows from element A to element B” can be rephrased as “a current flows from element B to element A”. The description “a current is input to element A” can be rephrased as “a current is output from element A”.

Ordinal numbers such as “first”, “second”, and “third” in this specification and the like are used in order to avoid confusion among components. Thus, the terms do not limit the number of components. The terms do not limit the order of components, either. For example, a “first” component in one embodiment in this specification and the like can be referred to as a “second” component in other embodiments or the scope of claims. For another example, a “first” component in one embodiment in this specification and the like can be omitted in other embodiments or the scope of claims.

In this specification and the like, the terms for describing positioning, such as “over” and “under”, are sometimes used for convenience to describe the positional relation between components with reference to drawings. The positional relationship between components is changed as appropriate in accordance with the direction in which the components are described. Thus, the positional relation is not limited to the terms described in the specification and the like, and can be described with another term as appropriate depending on the situation. For example, the expression “an insulator located over (on) a top surface of a conductor” can be replaced with the expression “an insulator located under (on) a bottom surface of a conductor” when the direction of a drawing illustrating these components is rotated by 180°.

Furthermore, the terms “over” and “under” do not necessarily mean that a component is placed directly over or directly under and in direct contact with another component. For example, the expression “electrode B over insulating layer A” does not necessarily mean that the electrode B is formed over and in direct contact with the insulating layer A, and does not exclude the case where another component is provided between the insulating layer A and the electrode B. Similarly, for example, the expression “electrode B above insulating layer A” does not necessarily mean that the electrode B is formed above and in direct contact with the insulating layer A, and does not exclude the case where another component is provided between the insulating layer A and the electrode B. Similarly, for example, the expression “electrode B under insulating layer A” does not necessarily mean that the electrode B is formed under and in direct contact with the insulating layer A, and does not exclude the case where another component is provided between the insulating layer A and the electrode B.

In this specification and the like, components arranged in a matrix and their positional relationship are sometimes described using terms such as “row” and “column”. The positional relationship between components is changed as appropriate in accordance with the direction in which the components are described. Thus, the positional relationship is not limited to the terms described in the specification and the like, and can be described with another term as appropriate depending on the situation. For example, the term “row direction” can be replaced with the term “column direction” when the direction of the diagram is rotated by 90°.

In this specification and the like, the terms “film” and “layer” can be interchanged with each other depending on the situation. For example, the term “conductive layer” can be replaced with the term “conductive film” in some cases. For another example, the term “insulating film” can be changed into the term “insulating layer” in some cases. Alternatively, the terms “film” and “layer” are not used and can be interchanged with another term depending on the case or the situation. For example, the term “conductive layer” or “conductive film” can be changed into the term “conductor” in some cases. Furthermore, for example, the term “insulating layer” or “insulating film” can be changed into the term “insulator” in some cases.

In this specification and the like, the terms “electrode”, “wiring”, “terminal”, and the like do not limit the functions of such components. For example, an “electrode” is used as part of a “wiring” in some cases, and vice versa. Furthermore, the term “electrode” or “wiring” also includes, for example, the case where a plurality of “electrodes” or “wirings” are formed in an integrated manner. For example, a “terminal” is used as part of a “wiring” or an “electrode” in some cases, and vice versa. Furthermore, the term “terminal” also includes the case where one or more selected from “electrodes”, “wirings”, and “terminals” are formed in an integrated manner, for example. Therefore, for example, an “electrode” can be part of a “wiring” or a “terminal”, and a “terminal” can be part of a “wiring” or an “electrode”. Moreover, the term “electrode”, “wiring”, or “terminal” is sometimes replaced with the term “region” depending on the case.

In this specification and the like, the terms “wiring”, “signal line”, and “power supply line” can be interchanged with each other depending on the case or the situation. For example, the term “wiring” can be changed into the term “signal line” in some cases. For another example, the term “wiring” can be changed into the term “power supply line” or the like in some cases. Conversely, the term “signal line” or “power supply line” can be changed into the term “wiring” in some cases. The term “power supply line” can be changed into the term “signal line” in some cases. Similarly, the term “signal line” can be changed into the term “power supply line” in some cases. The term “potential” that is applied to a wiring can be changed into the term “signal” depending on the case or the situation. Conversely, the term “signal” can be changed into the term “potential” in some cases.

In this specification and the like, a timing chart is used in some cases to describe an operation method of a semiconductor device. In this specification and the like, the timing chart shows an ideal operation example and a period, a level of a signal (e.g., a potential or a current), and a timing described in the timing chart are not limited unless otherwise specified. In the timing chart described in this specification and the like, the level of a signal (e.g., a potential or a current) input to a wiring (including a node) and a timing can be changed depending on the situation. For example, even when two periods are shown to have an equal length, the two periods have different lengths in some cases. Furthermore, for example, even when one of two periods is shown long and the other is shown short, the two periods can have the equal length in some cases, or the one period has a short length and the other has a long length in other cases.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is included in a channel formation region of a transistor, the metal oxide is referred to as an oxide semiconductor in some cases. That is, when a metal oxide can form a channel formation region of a transistor that has at least one of an amplifying function, a rectifying function, and a switching function, the metal oxide can be referred to as a metal oxide semiconductor. In the case where an OS transistor is mentioned, the OS transistor can also be referred to as a transistor including a metal oxide or an oxide semiconductor.

In this specification and the like, a metal oxide containing nitrogen is also referred to as a metal oxide in some cases. Alternatively, a metal oxide containing nitrogen may be called a metal oxynitride.

In this specification and the like, an impurity in a semiconductor refers to, for example, an element other than a main component of a semiconductor layer. For example, an element with a concentration of lower than 0.1 atomic % is an impurity. When an impurity is contained, for example, one or more of an increase in the density of defect states in a semiconductor, a decrease in carrier mobility, and a decrease in crystallinity occur in some cases. In the case where the semiconductor is an oxide semiconductor, examples of an impurity that changes characteristics of the semiconductor include Group 1 elements, Group 2 elements, Group 13 elements, Group 14elements, Group 15 elements, and transition metals other than the main components; specific examples are hydrogen (contained also in water), lithium, sodium, silicon, boron, phosphorus, carbon, and nitrogen.

In this specification and the like, a switch has a function of being in a conducting state (on state) or a non-conducting state (off state) to control whether current flows or not. Alternatively, a switch has a function of selecting and changing a current path. Thus, a switch may have two terminals or three or more terminals through which current flows, in addition to a control terminal. For example, an electrical switch or a mechanical switch can be used. That is, a switch can be any element capable of controlling current, and is not limited to a particular element.

Examples of an electrical switch include a transistor (e.g., a bipolar transistor and a MOS transistor), a diode (e.g., a PN diode, a PIN diode, a Schottky diode, a MIM (Metal Insulator Metal) diode, a MIS (Metal Insulator Semiconductor) diode, and a diode-connected transistor), and a logic circuit in which such elements are combined. Note that in the case of using a transistor as a switch, a “conducting state” of the transistor refers to a state where a source electrode and a drain electrode of the transistor can be regarded as being electrically short-circuited or a state where a current can be made to flow between the source electrode and the drain electrode. Furthermore, a “non-conducting state” of the transistor refers to a state where the source electrode and the drain electrode of the transistor can be regarded as being electrically disconnected. Note that in the case where a transistor operates just as a switch, there is no particular limitation on the polarity (conductivity type) of the transistor.

An example of a mechanical switch is a switch formed using a MEMS (micro electro mechanical systems) technology. Such a switch includes an electrode that can be moved mechanically, and operates by controlling conduction and non-conduction with movement of the electrode.

In this specification, “parallel” indicates a state where two straight lines are placed at an angle greater than or equal to −10° and less than or equal to 10°. Thus, the case where the angle is greater than or equal to −5° and less than or equal to 5° is also included. In addition, “approximately parallel” or “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Thus, the case where the angle is greater than or equal to 85° and less than or equal to 95° is also included. Furthermore, “approximately perpendicular” or “substantially perpendicular” indicates a state where two straight lines are placed at an angle greater than or equal to 60° and less than or equal to 120°.

In this specification and the like, one embodiment of the present invention can be constituted by appropriately combining a structure described in an embodiment with any of the structures described in the other embodiments. In addition, in the case where a plurality of structure examples are described in one embodiment, the structure examples can be combined as appropriate.

Note that a content (or part of the content) described in one embodiment can be applied to, combined with, or replaced with at least one of another content (or part of the content) in the embodiment and a content (or part of the content) described in one or a plurality of different embodiments.

Note that in each embodiment, a content described in the embodiment is a content described using a variety of diagrams or a content described with text disclosed in the specification.

Note that by combining a diagram (or part thereof) described in one embodiment with at least one of another part of the diagram, a different diagram (or part thereof) described in the embodiment, and a diagram (or part thereof) described in one or a plurality of different embodiments, much more diagrams can be provided.

Embodiments described in this specification are described with reference to the drawings. Note that the embodiments can be implemented in many different modes, and it will be readily appreciated by those skilled in the art that modes and details can be changed in various ways without departing from the spirit and scope thereof. Thus, the present invention should not be interpreted as being limited to the description in the embodiments. Note that in the structures of the invention in the embodiments, the same portions or portions having similar functions are denoted by the same reference numerals in different drawings, and repeated description thereof is omitted in some cases. In perspective views and the like, illustration of some components may be omitted for clarity of the drawings.

In this specification and the like, when a plurality of components are denoted with the same reference numerals, and in particular need to be distinguished from each other, an identification sign such as “_1”, “[n]”, or “[m, n]” is sometimes added to the reference numerals. Components denoted with identification signs such as “_1”, “[n]”, and “[m, n]” in the drawings and the like are sometimes described without such identification signs in this specification and the like when the components do not need to be distinguished from each other.

In the drawings in this specification, the size, the layer thickness, or the region is exaggerated for clarity in some cases. Therefore, the size, the layer thickness, or the region is not limited to the illustrated scale. The drawings are schematic views showing ideal examples, and embodiments of the present invention are not limited to shapes, values, or the like shown in the drawings. For example, variations in a signal, a voltage, or a current due to noise, variations in a signal, a voltage, or a current due to difference in timing, or the like can be included.

### EMBODIMENT 1

In this embodiment, a semiconductor device of one embodiment of the present invention will be described.

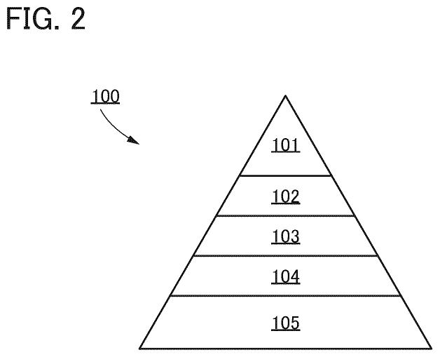

First, a concept of a memory hierarchy in which a variety of storage devices provided in a computer are associated with each other will be described. FIG. 2 illustrates an example of the memory hierarchy, and a memory hierarchy 100 illustrated in FIG. 2 includes a register 101, a first cache memory 102, a second cache memory 103, a main memory 104, and an auxiliary storage device 105.

The register 101 is a storage device included in a processor such as a CPU or a GPU (Graphics Processing Unit), for example. The register 101 has a function of temporarily retaining input data to an arithmetic circuit included in the processor and output data calculated by the arithmetic circuit. The register 101 may also have a function of temporarily retaining not only data related to the arithmetic circuit but also data related to a control device included in the processor.

The register 101 includes a flip-flop circuit, for example.

The first cache memory 102 is, for example, a storage device between the register 101 and the main memory 104 in the memory hierarchy 100 and has a function of retaining data that is particularly frequently accessed by the CPU. Note that the first cache memory 102 is generally referred to as a primary cache memory in some cases.

The second cache memory 103 is, for example, a storage device between the register 101 and the main memory 104 in the memory hierarchy 100 and has a function of retaining data that is accessed by the CPU with second-highest frequently, following data retained in the first cache memory 102. Note that the second cache memory 103 is generally referred to as a secondary cache memory in some cases.

The first cache memory 102 and the second cache memory 103 each include an SRAM, for example.

Depending on the computer, the second cache memory 103 is not necessarily provided in the memory hierarchy 100. Alternatively, a cache memory with lower access speed and higher storage capacity than the second cache memory 103 (sometimes referred to as a third cache memory or a tertiary cache memory) may be provided in the memory hierarchy 100. That is, one or two or more cache memories may be included in the memory hierarchy 100.

The memory hierarchy 100 may have a configuration in which the first cache memory 102 and the second cache memory 103 are included in the processor. Alternatively, the memory hierarchy 100 may have a configuration in which the first cache memory 102 is included in the processor and the second cache memory 103 is included in the main memory 104 described later.

The main memory 104 is, for example, a storage device between the first cache memory 102 and the second cache memory 103 and the auxiliary storage device 105 in the memory hierarchy 100 and has a function of directly writing or reading data by receiving an instruction signal from the processor including the register 101.

The main memory 104 includes a dram, for example.

The auxiliary storage device 105 has high storage capacity, and a nonvolatile storage device is mainly used as the auxiliary storage device 105, for example. Examples of the nonvolatile storage device include a magnetic storage medium (e.g., an HDD (Hard Disk Drive) or a magnetic tape) and a flash memory (e.g., an SSD (Solid State Drive) or a USB memory).

Note that the memory hierarchy 100 may have a configuration in which a storage device called a disk cache is provided between the main memory 104 and the auxiliary storage device 105. Providing the disk cache between the main memory 104 and the auxiliary storage device 105 can increase the speed of data transfer between the main memory 104 and the auxiliary storage device 105.

A difference is likely to be generated between the operation speed of the processor and the operation speed of each storage device included in the memory hierarchy 100 (in particular, the storage device positioned at a lower level than the first cache memory 102) (the operation speed of the storage device is sometimes referred to as access speed). Therefore, in general, a storage device at an upper level in the memory hierarchy 100 is required to have higher access speed. In addition, the storage device at an upper level is required to be closer to the arithmetic circuit or the control circuit included in the processor.

In the memory hierarchy 100, the storage capacity of a storage device frequently accessed is preferably low. This is because in the case where the storage capacity is low, the time required for searching of data stored in the storage device is shortened and the operation speed of the storage device becomes high. Meanwhile, in the case where a large amount of data is desired to be processed by the processor, the storage capacity in the whole memory hierarchy 100 is preferably high. Therefore, the storage device at the lower level is required to have higher storage capacity. For example, the first cache memory 102 preferably has higher storage capacity than the register 101, the second cache memory 103 preferably has higher storage capacity than the first cache memory 102, the main memory 104 preferably has higher storage capacity than the second cache memory 103, and the auxiliary storage device 105 preferably has higher storage capacity than the main memory 104.

In the case where the processor performs reading of necessary data in the memory hierarchy from the register 101 to the main memory 104, the processor makes an order of access from a high-level storage device in the memory hierarchy 100. In the case where necessary data is not retained in a storage device at an upper level (in the case where a cache miss occurs), the processor accesses a storage device at a lower level than the storage device at the upper level. In particular, the storage device at a lower level is farther from the processor (the register 101), and thus requires a longer time for access (cache miss penalty occurs). In the transfer of data between storage devices at two different levels, a bus wiring (e.g., an internal bus or an external bus) is used in some cases, and as the amount of data flowing through the bus wiring increases, the influence is applied to the performance (operation speed) of the processor.

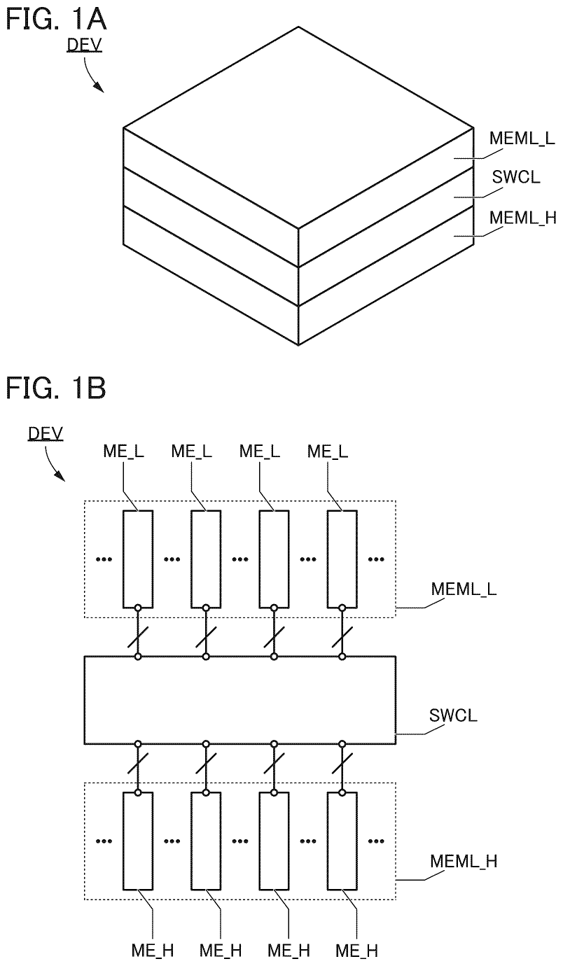

FIG. 1A and FIG. 1B illustrate a semiconductor device of one embodiment of the present invention, which solves the above problem. FIG. 1A is a schematic perspective view illustrating a structure example of a semiconductor device DEV of one embodiment of the present invention, and FIG. 1B is a block diagram of the semiconductor device DEV.

The semiconductor device DEV includes a storage layer MEML_L, which is a lower-level storage device in the memory hierarchy 100, a storage layer MEML_H, which is an upper-level storage device in the memory hierarchy 100, and a circuit layer SWCL. Note that the storage layer MEML_H is positioned below the circuit layer SWCL, and the storage layer MEML_L is positioned above the circuit layer SWCL. That is, in the semiconductor device DEV, the storage layer MEML_H, the circuit layer SWCL, and the storage layer MEML_L are stacked from the bottom.

The storage layer MEML_L includes, for example, the register 101, the first cache memory 102, the second cache memory 103, or the main memory 104 in the memory hierarchy 100.

The storage layer MEML_H is, for example, a storage layer included in the upper level of the storage layer MEML_L in the memory hierarchy 100. For example, in the case where the storage layer MEML_L includes the first cache memory 102, the storage layer MEML_H preferably includes the register 101. For another example, in the case where the storage layer MEML_L includes the second cache memory 103, the storage layer MEML_H preferably includes the first cache memory 102. For another example, in the case where the storage layer MEML_L includes the main memory 104, the storage layer MEML_H preferably includes the second cache memory 103.

Note that in FIG. 1A and FIG. 1B, the storage layer MEML_L includes a plurality of storage circuits ME_L, and the storage layer MEML_H includes a plurality of storage circuits ME_H.

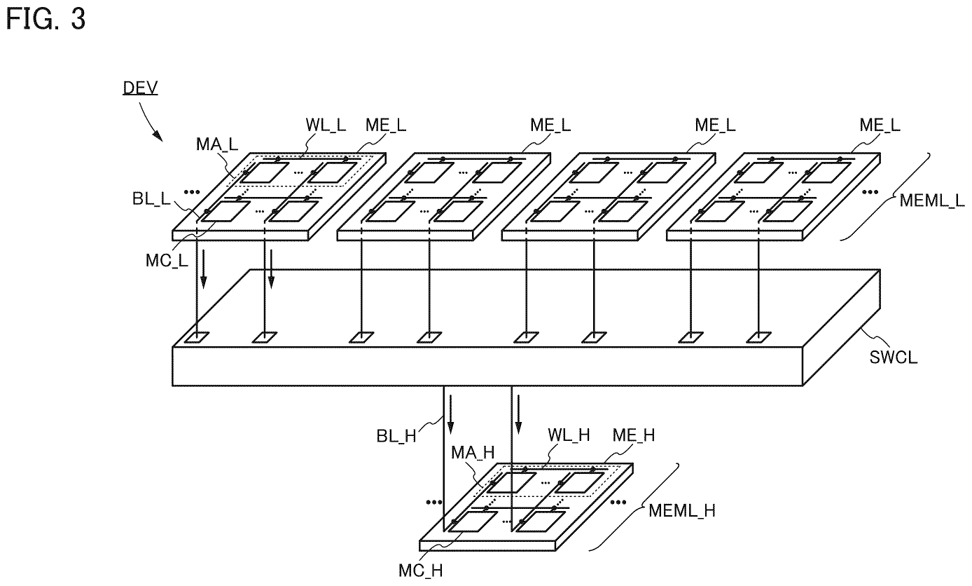

The storage circuit ME_L includes, for example, a memory cell array in which a plurality of memory cells MC_L are arranged in a matrix of one or more rows as illustrated in FIG. 3. In the case where a wiring WL_L extends in the row direction as a read word line in the memory cell array, a wiring BL_L preferably extends in the column direction as a bit line that transmits data read from the memory cell MC_L. One piece of data is preferably retained in the memory cells MC_L for one row in the memory cell array (denoted as a region MA_L in FIG. 3). For example, in the case where one memory cell MC_L has one-bit storage capacity and the number of columns of the memory cell array is 8, one piece of data with 8-bit storage capacity is retained in the memory cells MC_L (the memory cell MC_L in the region MA_L) for one row in the memory cell array. That is, 8-bit (1-byte) data can be read by one reading operation. For another example, in the case where one memory cell MC_L has 1-bit storage capacity and the number of columns of the memory cell array is 64, one piece of data with 64-bit storage capacity is retained in the memory cells MC_L in the region MA_L. That is, 64-bit (8-byte) data can be read by one reading operation. Note that the number of columns of the memory cell array is not limited to a multiple of eight and may be an integer greater than or equal to 1.

That is, when the number of rows of the memory cell array of the storage circuit ME_L is set to m (here, m is an integer greater than or equal to 1) and the number of columns thereof is set to n (here, n is an integer greater than or equal to 1), it can be said that the storage circuit ME_L can retain m pieces of n-bit data.

Like the storage circuit ME_L, the storage circuit ME_H includes a memory cell array in which a plurality of memory cells MC_H are arranged in a matrix of one or more rows, for example. Note that the memory cell included in the storage circuit ME_H may have the same structure as or a different structure from the memory cell included in the storage circuit ME_L. In the case where the wiring WL_H extends in the row direction as a write word line in the memory cell array, the wiring BL_H preferably extends in the column direction as a bit line that transmits data to be written to the memory cell MC_H. One piece of data is preferably retained in the memory cells MC_H for one row in the memory cell array (denoted by a region MA_H in FIG. 3). For example, in the case where one memory cell MC_H has one-bit storage capacity and the number of columns of the memory cell array is 8, one piece of data with 8-bit (1-byte) storage capacity can be written to the memory cells MC_H in the region MA_H. For example, in the case where one memory cell MC_H has 1-bit storage capacity and the number of columns of the memory cell array is 64, one piece of data with 64-bit (8-byte) storage capacity can be written to the memory cells MC_H in the region MA_H. Note that the number of columns of the memory cell array is not limited to 8 and may be an integer greater than or equal to 1.

Like the storage circuit ME_L, when the number of rows of the memory cell array of the storage circuit ME_H is set to m (here, m is an integer greater than or equal to 1) and the number of columns thereof is set to n (here, n is an integer greater than or equal to 1), the storage circuit ME_H can retain m pieces of n-bit data.

In particular, the storage capacity of data retained in the region MA_H is preferably the same as the storage capacity of data retained in the region MA_L. That is, the number of rows and the number of columns of the memory cell array in the storage circuit ME_H are preferably equal to the number of rows and the number of columns of the memory cell array in the storage circuit ME_L.

As illustrated in FIG. 1B and FIG. 3, the semiconductor device DEV has a structure in which one storage circuit ME_L transmits one piece of 1-bit or multi-bit data to the circuit layer SWCL. In the semiconductor device DEV, the storage circuit ME_H receives 1-bit or multi-bit one data from the circuit layer SWCL. Thus, each of the storage circuit ME_L and the storage circuit ME_H is a storage circuit that stores digital data, for example.

For example, the storage circuit ME_L has a function of reading 8-bit (1-byte) data and transmitting the data to the circuit layer SWCL. The storage circuit ME_H has a function of writing 8-bit data transmitted from the storage circuit ME_L through the circuit layer SWCL. Note that the storage circuit ME_L and the storage circuit ME_H may process data of less than 8 bits, such as 1-bit, 2-bit, or 4-bit data, for example. Data of more than 8 bits, such as 16-bit, 32-bit, 64-bit, 128-bit, or 256-bit data, may be processed, for example.

In the case where the read word line extends in the row direction in the memory cell array included in the storage circuit ME_H, the number of columns of the memory cell array is preferably equal to the number of columns of the memory cell array included in the storage circuit ME_L. For example, in the case where a memory cell can retain 1-bit data in each of the storage circuit ME_L and the storage circuit ME_H, when the number of columns of the memory cell array in each of the storage circuit ME_L and the storage circuit ME_H is 8, each of the storage circuit ME_L and the storage circuit ME_H can be a storage circuit that processes 8-bit data. At this time, the number of wirings BL_L used for transmitting data from the storage circuit ME_L to the circuit layer SWCL can be 8, and the number of wirings BL_H used for transmitting data from the circuit layer SWCL to the storage circuit ME_H can also be 8. When the number of columns of memory cell array in each of the storage circuit ME_L and the storage circuit ME_H is 64, for example, each of the storage circuit ME_L and the storage circuit ME_H can be a storage circuit that processes 64-bit data. At this time, 64 the number of wirings BL_L used for transmitting data from the storage circuit ME_L to the circuit layer SWCL can be 64 and the number of wirings BL_H used for transmitting data from the circuit layer SWCL to the storage circuit ME H can also be 64.

In the case where the wiring WL_H functioning as the read word line extends in the row direction in the memory cell array included in the storage circuit ME_H, the number of rows of the memory cell array included in the storage circuit ME_H is preferably equal to the number of rows of the memory cell array included in the storage circuit ME_L.

Note that specific circuit configurations of the storage circuit ME_L and the storage circuit ME H will be described later.

Since the storage layer MEML_L overlaps with the storage layer MEML_H with the circuit layer SWCL therebetween, for example, when wirings functioning as plugs are formed in the storage layer MEML_L, the circuit layer SWCL, and the storage layer MEML_H, the storage layer MEML_L and the circuit layer SWCL can be electrically connected to each other and the circuit layer SWCL and the storage layer MEML_H can also be electrically connected to each other. That is, electrical connection between the storage layer MEML_L and the circuit layer SWCL and electrical connection between the circuit layer SWCL and the storage layer MEML_H can be obtained by wirings in the stacking direction. In that case, the length of the wiring can be shortened and the number of wirings can be increased as compared with the case where a wiring is formed on a plane. Thus, by stacking the storage layer MEML_L, the circuit layer SWCL, and the storage layer MEML_H and forming wirings in the stacking direction, the amount of data transmitted between the storage layer MEML_L and the storage layer MEML_H can be increased. Furthermore, the data transfer speed between the storage layer MEML_L and the storage layer MEML_H can be increased.

Since the storage layer MEML_L and the storage layer MEML_H are electrically connected to each other through the circuit layer SWCL, a system bus is not necessarily provided between the storage layer MEML_L and the storage layer MEML_H, for example. A system bus is a transmission path (wiring) for connecting a processor to each device included in a computer, and is divided into an external bus connecting a processor to each external device (e.g., a main memory, an auxiliary storage device, or an optical drive) and an internal bus connecting circuits (e.g., a cache memory, a control device, or an arithmetic circuit) in the processor. In particular, when the processor is a CPU, the system bus is referred to as a CPU bus in some cases. Since the system bus is connected to each device, the transmission path (wiring) tends to be long, which might increase the time and power consumption required for data transmission.

Data is directly transmitted between the storage layer MEML_L and the storage layer MEML_H not through a system bus as in the semiconductor device DEV, whereby the processor including the semiconductor device DEV can have higher access speed and lower power consumption.

The circuit layer SWCL has a function of selecting one of the plurality of storage circuits ME_L included in the storage layer MEML_L and one of the plurality of storage circuits ME_H included in the storage layer MEML_H to establish electrical continuity between the selected storage circuit ME_L and storage circuit ME_H. Furthermore, each of the plurality of non-selected storage circuits ME_L is brought out of conduction with the plurality of storage circuits ME_H included in the storage layer MEML_H.

That is, the circuit layer SWCL selects one of the plurality of storage circuits ME_L included in the storage layer MEML_L and one of the plurality of storage circuits ME_H included in the storage layer MEML_H, whereby data retained in the region MA_L of the memory cell array in the storage circuit ME_L selected in the storage layer MEML_L can be read and written to the region MA_H of the memory cell array of the storage circuit ME_H selected in the storage layer MEML_H.

Although the structure example in which one piece of data of the region MA_L in the memory cell array of the storage circuit ME_L is read and written to the region MA_H in the memory cell array of the storage circuit ME_H is described above, one embodiment of the present invention is not limited thereto. The structure of the semiconductor device DEV in FIG. 3 can be changed; a plurality of pieces of data may be read from the storage circuit ME_L instead of one piece of data and written to the storage circuit ME_H.

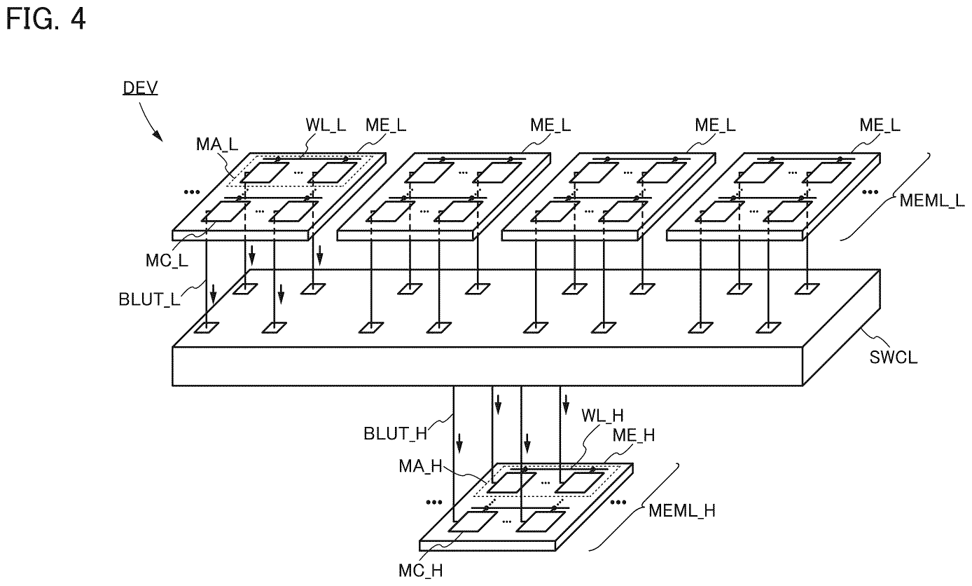

For example, in the semiconductor device DEV illustrated in FIG. 4, a plurality of wirings BLUT_L are electrically connected to the respective memory cells MC_L arranged in the memory cell array of the storage circuit ME_L, and the plurality of wirings BLUT_L are electrically connected to the circuit layer SWCL. In the semiconductor device DEV illustrated in FIG. 4, a plurality of wirings BLUT_H are electrically connected to the respective memory cells MC_H arranged in the memory cell array of the storage circuit ME_H, and the plurality of wirings BLUT_H are electrically connected to the circuit layer SWCL.

That is, the number of wirings of the wiring BLUT_L is equal to the number of memory cells MC_L arranged in the memory cell array of the storage circuit ME_L. The number of wirings of the wiring BLUT_H is equal to the number of memory cells MC_H arranged in the memory cell array of the storage circuit ME_H. Note that the number of rows of the memory cell array in the storage circuit ME_L is preferably equal to the number of rows of the memory cell array in the storage circuit ME_H, and the number of columns of the memory cell array in the storage circuit ME_L is preferably equal to the number of columns of the memory cell array in the storage circuit ME_H.

The wiring BLUT_L is a wiring that corresponds to the wiring BL_L in FIG. 3 and different from the wiring BL_L in FIG. 3 in being electrically connected to one of the plurality of memory cells MC_L included in the storage circuit ME_L. Similarly, the wiring BLUT_H is a wiring that corresponds to the wiring BL_H in FIG. 3 and different from the wiring BL_H in FIG. 3 in being electrically connected to one of the plurality of memory cells MC_H included in the storage circuit ME_H.

As in the semiconductor device DEV in FIG. 4, one wiring BLUT_L is electrically connected to each of the plurality of memory cells MC_L in the storage circuit ME_L, whereby a plurality of pieces of data retained in the memory cells MC_L arranged not in one row but in a plurality of rows (in all rows) can be transmitted to the circuit layer SWCL at the same time in the memory cell array of the storage circuit ME_L. Furthermore, one wiring BLUT_H is electrically connected to each of the plurality of memory cells MC_H in the storage circuit ME_H, whereby data transmitted from the circuit layer SWCL can be written to the memory cells MC_H arranged not in one row but in a plurality of rows (in all rows) at the same time in the memory cell array of the storage circuit ME_H.

Note that the storage circuit ME_L and the storage circuit ME_H described above may be not a storage circuit that retains digital data but a storage circuit that retains analog data. In this case, data that is transmitted between the storage circuit ME_L and the storage circuit ME_H through the circuit layer SWCL can be not digital data but analog data. In the case of analog data, the number of wirings connected between the storage circuit ME_L and the storage circuit ME_H can be smaller than that in the case of handling digital data; thus, the circuit area of the semiconductor device DEV can be further reduced.

### Structure Example of Circuit Layer SWCL

Next, a structure example of the circuit layer SWCL will be described.

### Direct Mapped Cache

First, the case where a direct mapped cache is employed as the storage structure of the storage layer MEML_L and the storage layer MEML_H will be described.

A direct mapped cache is a method in which when data retained in the storage circuit ME_L included in the storage layer MEML_L is written to the storage circuit ME_H in the storage layer MEML_H, the address of the storage circuit ME_H to which the data is written is determined on the basis of the address of the storage circuit ME_L in which the data is retained.

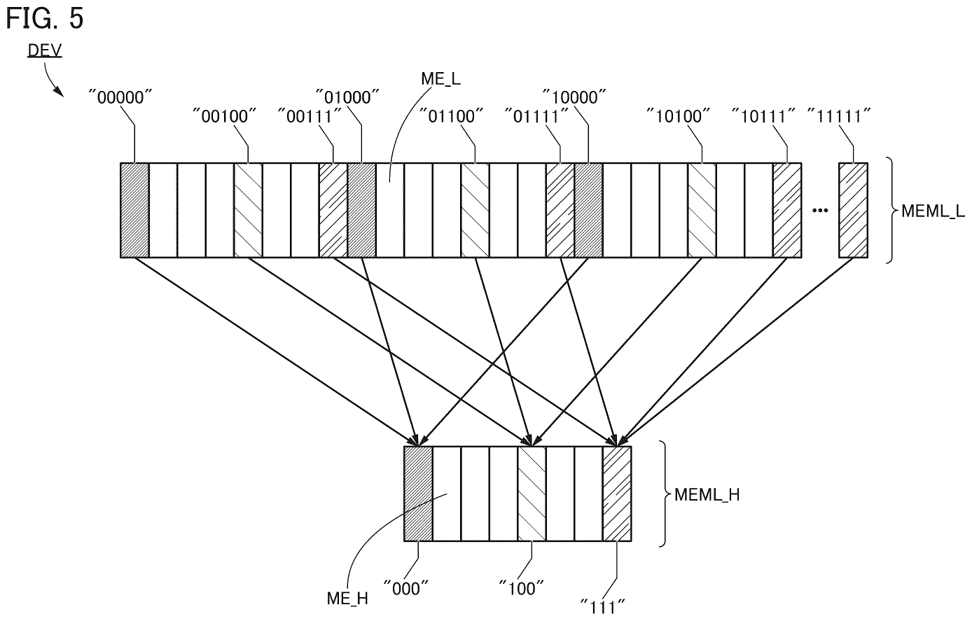

FIG. 5 illustrates an example in which a direct mapped cache is applied to the storage layer MEML_L and the storage layer MEML_H. In the semiconductor device DEV in FIG. 5, the storage layer MEML_L has a storage capacity of 2⁵=32 blocks, and the storage layer MEML_H has a storage capacity of 2³=8 blocks, for example. Note that in the storage layer MEML_L, one block is one storage circuit ME_L, and in the storage layer MEML_H, one block is one storage circuit ME_H. That is, the storage layer MEML_L includes 32 storage circuits ME_L, and the storage layer MEML_H includes 8 storage circuits ME_H.

A memory address from “00000” to “11111” is assigned to each of the 32 storage circuits ME_L in the storage layer MEML_L. Similarly, a memory address from “000” to “111” is assigned to each of the 8 storage circuits ME_H in the storage layer MEML_H.

For simple description, each of the storage circuit ME_L and the storage circuit ME_H includes a one-row matrix memory cell array. That is, in the case where data is read by the storage circuit ME_L, the data in one row is uniquely read from the storage circuit ME_L. In the case where data is written to the storage circuit ME_H, data is uniquely written to one row in the storage circuit ME_H.

Here, attention is focused on the storage circuit ME_L of a block whose lower three bits of the memory address are “000” among the 32 storage circuits ME_L in the storage layer MEML_L (although not completely illustrated in FIG. 5, four blocks exist in the storage layer MEML_L in FIG. 5). In the semiconductor device DEV in FIG. 5, data of any one of the storage circuits ME L of a block whose lower three bits of the memory address are “000” is transmitted to the storage circuit ME_H with a memory address of “000” in the storage layer MEML_H.

Similarly, attention is focused on the storage circuit ME_L of a block whose lower three bits of the memory address are “100” among the three storage circuits ME_L in the storage layer MEML_L. In the semiconductor device DEV in FIG. 5, data of any one of the storage circuits ME_L of a block whose lower three bits of the memory address are “100” is transmitted to the storage circuit ME_H with a memory address of “100” in the storage layer MEML_H.

Similarly, attention is focused on the storage circuit ME_L of a block whose lower three bits of the memory address are “111” among the 32 storage circuits ME_L in the storage layer MEML_L. In the semiconductor device DEV in FIG. 5, data of any one of the storage circuits ME_L of a block whose lower three bits of the memory address are “111” is transmitted to the storage circuit ME_H with a memory address of “111” in the storage layer MEML_H.

To summarize the above, when data read from the storage layer MEML_L is written to the storage layer MEML_H, the address of the storage circuit ME_H, to which data of the storage layer MEML_H is to be written, is limited to the value same as the lower three bits of the memory address of the storage layer MEML_L from which the data is to be read.

As described above, in the direct mapped cache, when data read from the storage layer MEML L is written to the storage layer MEML_H, the memory address of the storage circuit ME_H, to which data of the storage layer MEML_H is to be written, is determined on the basis of the memory address of the storage circuit ME_L in the storage layer MEML_L from which the data is to be read. That is, in the direct mapped cache, data written to the storage circuit ME_H is limited to data read from the storage circuit ME_L at a specific memory address. Thus, when the data in the storage circuit ME_L in the storage layer MEML_L is searched for from the plurality of storage circuits ME_H in the storage layer MEML_H, for example, the predetermined storage circuit ME_H can be found from the storage layer MEML_H using the memory address of the storage circuit ME_L where desired data is retained; thus, the use of a direct mapped cache can increase the data reading speed.

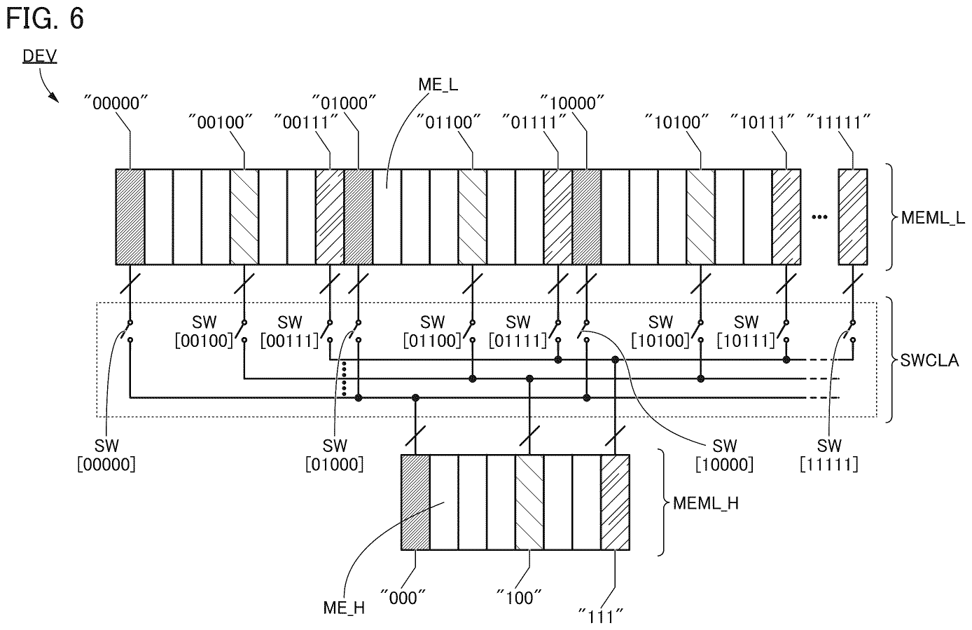

A structure example of the circuit layer SWCL in the case where a direct mapped cache is employed for the semiconductor device DEV is described. FIG. 6 is a circuit diagram in which a circuit structure example of the circuit layer SWCL is added to the semiconductor device DEV illustrated in FIG. 5. Note that in FIG. 6, the circuit layer SWCL illustrated in FIG. 1A and FIG. 1B is illustrated as a circuit layer SWCLA.

The circuit layer SWCLA includes a switch SW[00000] to a switch SW[11111]. Note that FIG. 6 selectively illustrates the switch SW[00000], a switch SW[00100], a switch SW[00111], a switch SW[01000], a switch SW[01100], a switch SW[01111], a switch SW[10000], a switch SW[10100], a switch SW[10111], and the switch SW[11111].

A first terminal of the switch SW[00000] is electrically connected to the storage circuit ME_L at the memory address “00000” in the storage layer MEML_L. A first terminal of the switch SW[01000] is electrically connected to the storage circuit ME_L at the memory address “01000” in the storage layer MEML_L. A first terminal of the switch SW[10000] is electrically connected to the storage circuit ME_L at the memory address “10000” in the storage layer MEML_L. Although not illustrated, a first terminal of the switch SW[11000] is electrically connected to the storage circuit ME_L at the memory address “11000” in the storage layer MEML_L. Second terminals of the switch SW[00000], the switch SW[01000], the switch SW[10000], and the switch SW[11000] are electrically connected to the storage circuit ME_H at the memory address “000” in the storage layer MEML_H.

One of the switch SW[00000], the switch SW[01000], the switch SW[10000], and the switch SW[11000] is turned on and the others are turned off, so that one of the memory addresses of the storage layer MEML_L, “00000”, “01000”, “10000”, and “11000” is selected. After that, the data retained in the storage circuit ME_L at the selected memory address is read, the data is transmitted to the storage circuit ME_H at the memory address “000” in the storage layer MEML_H, and the data is stored in the storage circuit ME_H at the memory address “000”.

Similarly, a first terminal of the switch SW[00100] is electrically connected to the storage circuit ME_L at the memory address “00100” in the storage layer MEML_L. A first terminal of the switch SW[01100] is electrically connected to the storage circuit ME_L at the memory address “01100” in the storage layer MEML_L. A first terminal of the switch SW[10100] is electrically connected to the storage circuit ME_L at the memory address “10100” in the storage layer MEML_L. Although not illustrated, a first terminal of the switch SW[11100] is electrically connected to the storage circuit ME_L at the memory address “11100” in the storage layer MEML_L. Second terminals of the switch SW[00100], the switch SW[01100], the switch SW[10100], and the switch SW[11100] are electrically connected to the storage circuit ME_H at the memory address “100” in the storage layer MEML_H.

One of the switch SW[00100], the switch SW[01100], the switch SW[10100], and the switch SW[11100] is turned on and the others are turned off, so that one of the memory addresses of the storage layer MEML_L, “00100”, “01100”, “10100”, and “11100” is selected. After that, the data retained in the storage circuit ME_L at the selected memory address is read, the data is transmitted to the storage circuit ME_H at the memory address “100” in the storage layer MEML_H, and the data is stored in the storage circuit ME_H at the memory address “100”.

Similarly, a first terminal of the switch SW[00111] is electrically connected to the storage circuit ME_L at the memory address “00111” in the storage layer MEML_L. A first terminal of the switch SW[01111] is electrically connected to the storage circuit ME_L at the memory address “01111” in the storage layer MEML_L. A first terminal of the switch SW[10111] is electrically connected to the storage circuit ME_L at the memory address “10111” in the storage layer MEML_L. A first terminal of the switch SW[11111] is electrically connected to the storage circuit ME_L at the memory address “11111” in the storage layer MEML_L. Second terminals of the switch SW[00111], the switch SW[01111], the switch SW[10111], and the switch SW[11111] are electrically connected to the storage circuit ME_H at the memory address “111” in the storage layer MEML_H.

One of the switch SW[00111], the switch SW[01111], the switch SW[10111], and the switch SW[11111] is turned on and the others are turned off, so that one of the memory addresses of the storage layer MEML_L, “00111”, “01111”, “10111”, and “11111” is selected. After that, the data retained in the storage circuit ME_L at the selected memory address is read, the data is transmitted to the storage circuit ME_H at the memory address “111” in the storage layer MEML_H, and the data is stored in the storage circuit ME_H at the memory address “111”.

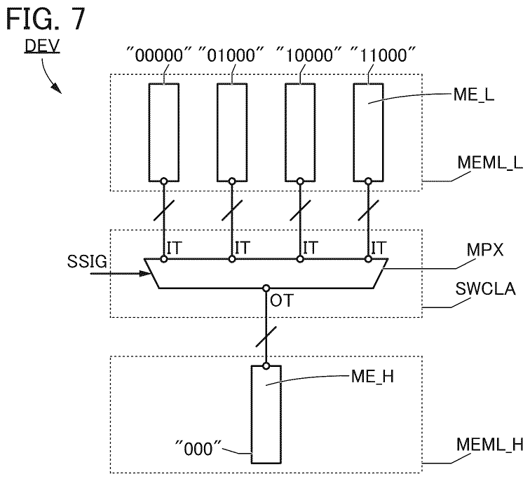

FIG. 7 illustrates a structure example of part of the semiconductor device DEV in FIG. 6 for simply describing the circuit layer SWCLA in FIG. 6. Note that the circuit layer SWCLA illustrated in FIG. 7 is different from the circuit layer SWCLA illustrated in FIG. 6 in including a selector MPX. FIG. 7 selectively illustrates the storage circuits ME_L at the memory addresses “00000”, “01000”, “10000”, and “11000” in the storage layer MEML_L and the storage circuit ME H at the memory address “000” in the storage layer MEML_H.

The selector MPX includes a plurality of input terminals IT and one output terminal OT, for example.

The plurality of input terminals IT of the selector MPX are electrically connected to the respective storage circuits ME_L in the storage layer MEML_L. Note that the memory addresses of the plurality of storage circuits ME_L electrically connected to the plurality of input terminals IT of the selector MPX have the same predetermined lower bits (in FIG. 7, the lower three bits of the memory address of each of the storage circuits ME_L are “000”). The output terminal OT of the selector MPX is electrically connected to the storage circuit ME_H at a memory address whose lower bits are the same as the predetermined lower bits of the memory address of the storage circuit ME_L (the memory address of the storage circuit ME_H is “000” in FIG. 7).

The selector MPX has a function of establishing electrical continuity between one of the plurality of input terminals IT of the selector MPX and the output terminal OT of the selector MPX in accordance with a signal SSIG input to the selector MPX, for example. The selector MPX also has a function of selecting one of the input signals input to the plurality of input terminals IT of the selector MPX in accordance with the signal SSIG input to the selector MPX, and outputting the input signal selected by the output terminal OT of the selector MPX, for example. The selector MPX also has a function of breaking electrical continuity between the other input terminals IT of the selector MPX and the output terminal OT of the selector MPX, for example.

Thus, the selector MPX is referred to as a multiplexer in some cases.

A sample-and-hold circuit may be provided between the output terminal OT of the selector MPX and the storage circuit ME_H. In the semiconductor device DEV, a sample-and-hold circuit is provided between the output terminal OT of the selector MPX and the storage circuit ME_H, whereby data of the output terminal OT of the selector MPX can be temporarily retained. That is, data to be written to the storage circuit ME_H can be prepared in advance, so that the operation speed of the semiconductor device DEV can be increased.

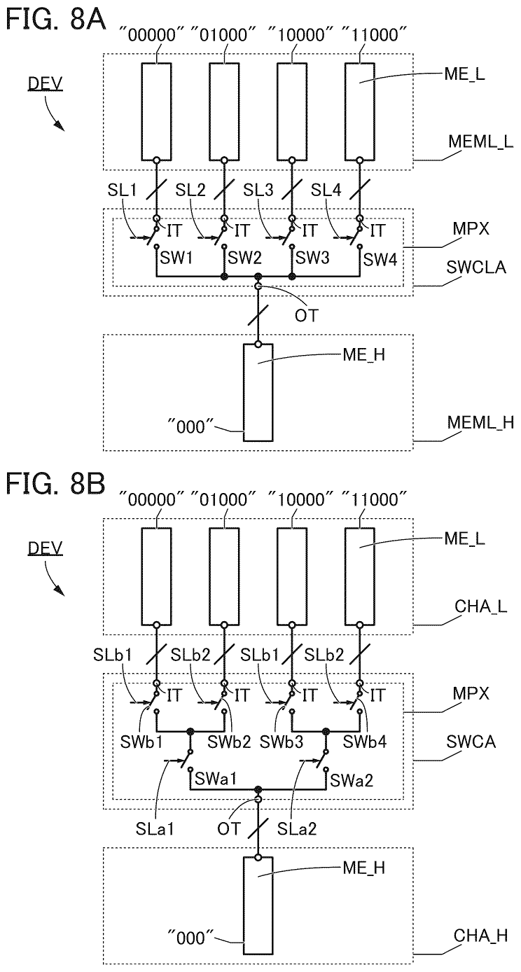

FIG. 8A and FIG. 8B are circuit diagrams each illustrating a specific structure example of the selector MPX.

Like the circuit layer SWCLA illustrated in FIG. 6, the selector MPX illustrated in FIG. 8A has a structure in which the first terminals of the switch SW1 to the switch SW4 are electrically connected to the respective storage circuits ME_L, and the second terminals of the switch SW1 to the switch SW4 are electrically connected to the storage circuit ME_H. A control terminal of the switch SW1 is electrically connected to a wiring SL1, a control terminal of the switch SW2 is electrically connected to a wiring SL2, a control terminal of the switch SW3 is electrically connected to a wiring SL3, and a control terminal of the switch SW4 is electrically connected to a wiring SL4.

As the switch SW1 to the switch SW4, an electrical switch (e.g., an analog switch or a transistor) can be used, for example. In the case where transistors are used as the switch SW1 to the switch SW4, for example, the transistors can be transistors including an oxide semiconductor (a metal oxide) in their channel formation regions (OS transistors). Note that the metal oxide will be described in detail in Embodiment 2 and Embodiment 3. The transistor may be a transistor including silicon in its channel formation region (Si transistor). As the silicon, amorphous silicon (referred to as hydrogenated amorphous silicon in some cases), microcrystalline silicon, polycrystalline silicon, single crystal silicon, or the like can be used, for example. Other than the electrical switch, a mechanical switch may be used.

Note that in this specification and the like, each of the switch SW1 to the switch SW4 is turned on when a high-level potential is input to its control terminal and is turned off when a low-level potential is input to the control terminal.

The wiring SL1 to the wiring SL4 each function as a wiring that transmits a signal (a variable potential) for switching between the conduction state and the non-conduction state of the switch SW1 to the switch SW4, for example. Note that signals transmitted to the wiring SL1 to the wiring SL4 correspond to the signal SSIG in FIG. 7. Note that each of the wiring SL1 to the wiring SL4 may function as a wiring that supplies not a signal (a variable potential) but a constant potential (e.g., a high-level potential, a low-level potential, a ground potential, or a negative potential).

In the selector MPX illustrated in FIG. 8A, for example, a high-level potential is supplied to one selected from the wiring SL1 to the wiring SL4 and a low-level potential is supplied to the others, whereby electrical continuity can be established between one of the plurality of input terminals IT of the selector MPX and the output terminal OT of the selector MPX. To break electrical continuity between all the plurality of input terminals IT of the selector MPX and the output terminal OT of the selector MPX, a low-level potential is supplied to each of the wiring SL1 to the wiring SL4, for example.

The selector MPX illustrated in FIG. 8B is configured using a tournament system with a plurality of switches. Note that the selector MPX in FIG. 8B includes a switch SWa1, a switch SWa2, a switch SWb1, a switch SWb2, a switch SWb3, and a switch SWb4, and the description of the switch SW1 to the switch SW4 illustrated in FIG. 8A can be referred to for the switches.

First terminals of the switch SWb1 to the switch SWb4 are electrically connected to the respective storage circuits ME_L. A first terminal of the switch SWa1 is electrically connected to a second terminal of the switch SWb1 and a second terminal of the switch SWb2. A first terminal of the switch SWa2 is electrically connected to a second terminal of the switch SWb3 and a second terminal of the switch SWb4. A second terminal of the switch SWal and a second terminal of the switch SWa2 are electrically connected to the storage circuit ME_H. A control terminal of the switch SWb1 and a control terminal of the switch SWb3 are electrically connected to a wiring SLb1, a control terminal of the switch SWb2 and a control terminal of the switch SWb4 are electrically connected to a wiring SLb2, a control terminal of the switch SWal is electrically connected to a wiring SLa1, and a control terminal of the switch SWa2 is electrically connected to a wiring SLa2.

For the wiring SLa1, the wiring SLa2, the wiring SLb1, and the wiring SLb2, the description of the wiring SL1 to the wiring SL4 illustrated in FIG. 8A can be referred to.

In particular, the signal supplied to the wiring SLa1 is preferably a signal whose logic is inverted from that of the signal supplied to the wiring SLa2. The signal supplied to the wiring SLb1 is preferably a signal whose logic is inverted from that of the signal supplied to the wiring SLb2. Thus, one of the switch SWa1 and the switch SWa2 can be turned on and the other can be turned off. One of the switch SWb1 and the switch SWb2 can be turned on and the other can be turned off. One of the switch SWb3 and the switch SWb4 can be turned on and the other can be turned off.

As described above, by supplying a predetermined signal to each of the wiring SLa1, the wiring SLa2, the wiring SLb1, and the wiring SLb2, electrical continuity can be established between one of the plurality of input terminals IT of the selector MPX and the output terminal OT of the selector MPX. To break electrical continuity between all the plurality of input terminals IT of the selector MPX and the output terminal OT of the selector MPX, a low-level potential is supplied to each of the wiring SLa1 to the wiring SLa2, for example.

Note that one embodiment of the present invention is not limited to the structure of the above-described semiconductor device DEV. One embodiment of the present invention may have a structure in which the above-described semiconductor device is modified.

For example, although the semiconductor device DEV described above has a structure in which the storage layer MEML_L includes 32 storage circuits ME_L and the storage layer MEML H includes 8 storage circuits ME_H, the number of storage circuits ME_L included in the storage layer MEML_L and the number of storage circuits ME_H included in the storage layer MEML_H are not particularly limited.

For another example, in the semiconductor device DEV described above, a block of the storage circuit ME_H to be the storage destination is determined by referring to the lower 3 bits of the memory address of the storage layer MEML_L; however, the memory address of the storage layer MEML_L to be referred to for may be the lower 1 bit, the lower 2 bits, or the lower 4 or more bits. The number of storage circuits ME_L provided in the storage layer MEML_L and the number of storage circuits ME_H provided in the storage layer MEML_H may be determined in accordance with the range of the referenced memory address.

### Set-Associative Cache

Next, the case where a set-associative cache is employed as the storage structures of the storage layer MEML_L and the storage layer MEML_H, which is different from the direct mapped cache, will be described.

A set-associative cache is a method in which when data retained in the storage circuit ME_L included in the storage layer MEML_L is written to the storage circuit ME_H in the storage layer MEML_H, data retained in the storage circuit ME_L included in the storage layer MEML_L is retained in one of the plurality of storage circuits ME_H specified on the basis of the address of the storage circuit ME_L.

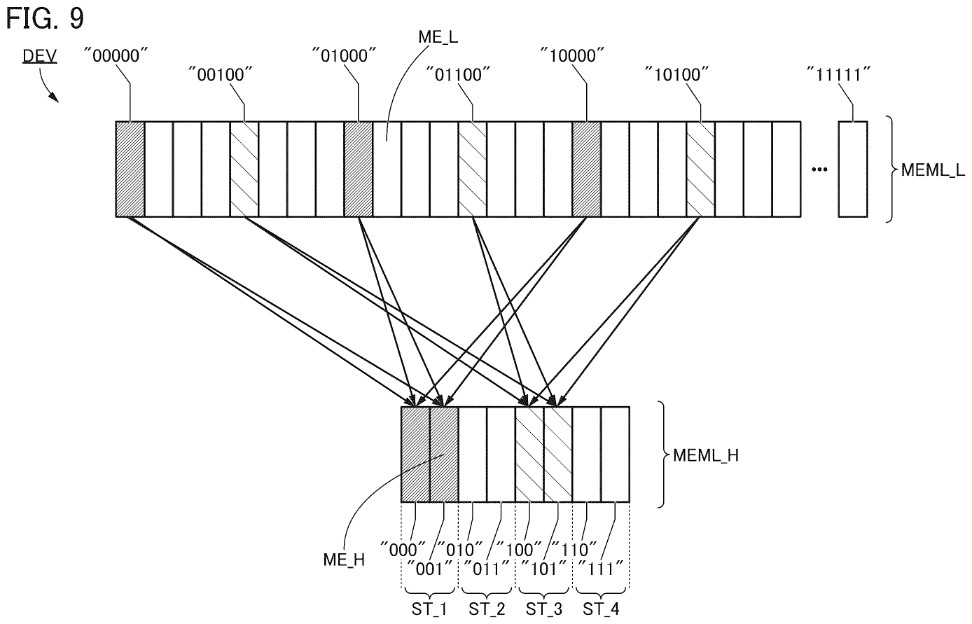

FIG. 9 illustrates an example of a set-associative cache applied to the storage layer MEML_L and the storage layer MEML_H. Like the semiconductor device DEV in FIG. 5, the semiconductor device DEV in FIG. 9 has a structure in which 32 storage circuits ME_L are included in the storage layer MEML_L and 8 storage circuits ME_H are included in the storage layer MEML_H. As in the semiconductor device DEV in FIG. 5, a memory address is also shown in the semiconductor device DEV in FIG. 9.

Note that in the storage layer MEML_H of the semiconductor device DEV in FIG. 9, blocks (the storage circuits ME_H) where the memory address is “000” or “001” are a set ST_1. Blocks (the storage circuits ME_H) where the memory address is “010” or “011” are a set ST_2. Blocks (the storage circuits ME_H) where the memory address is “100” or “101” are a set ST_3. Blocks (the storage circuits ME_H) where the memory address is “110” or “111” are a set ST 4.

As in the semiconductor device DEV in FIG. 5, each of the storage circuit ME_L and the storage circuit ME_H in the semiconductor device DEV in FIG. 9 includes a one-row matrix memory cell array. That is, in the case where data is read by the storage circuit ME_L, the data in one row is uniquely read from the storage circuit ME_L. In the case where data is written to the storage circuit ME_H, data is uniquely written to one row in the storage circuit ME_H.

Here, attention is focused on the storage circuit ME_L of a block whose lower three bits of the memory address are “000” among the 32 storage circuits ME_L in the storage layer MEML_L (although not completely illustrated in FIG. 9, four blocks exist in the storage layer MEML_L in FIG. 9). In the semiconductor device DEV in FIG. 9, data of any one of the storage circuits ME_L of a block whose lower three bits of the memory address are “000” is transmitted to any one of the storage circuits ME_H included in the set ST_1 in the storage layer MEML_H.

Similarly, attention is focused on the storage circuit ME_L of a block whose lower three bits of the memory address are “100” among the 32 storage circuits ME_L in the storage layer MEML_L (although not completely illustrated in FIG. 9, four blocks exist in the storage layer MEML_L in FIG. 9). In the semiconductor device DEV in FIG. 9, data of any one of the storage circuits ME_L of a block whose lower three bits of the memory address are “100” is transmitted to any one of the storage circuits ME_H included in the set ST_3 in the storage layer MEML_H.

That is, when data read from the storage layer MEML_L is written to the storage layer MEML_H by the set-associative cache, the memory address of the storage circuit ME_H to which data of the storage layer MEML_H is to be written is determined on the basis of the memory address of the storage circuit ME_L of the storage layer MEML_L from which the data is to be read as well as by the direct mapped cache; meanwhile, the storage circuit ME H to which the data is to be written can be selected from a plurality of blocks included in a predetermined set.

In particular, as illustrated in FIG. 9, a method in which a destination to which data read from the storage layer MEML_L is written is selected from two storage circuits ME_H is referred to as a two-way set-associative cache in some cases. A method in which the destination to which data read from the storage layer MEML_L is written is selected from N storage circuits ME_H (N is an integer greater than or equal to 2) is referred to as an N-way set-associative cache in some cases.

In the set-associative cache, as in the direct mapped cache, the memory address of the storage circuit ME_H, to which data of the storage layer MEML_H is to be written, is determined on the basis of the memory address of the storage circuit ME_L in the storage layer MEML_L from which the data is to be read. That is, in the set-associative cache, data written to the storage circuit ME H is limited to data read from the storage circuit ME_L at a specific memory address. Thus, when the data in the storage circuit ME_L in the storage layer MEML_L is searched for from the plurality of storage circuits ME_H in the storage layer MEML_H, for example, the predetermined storage circuit ME_H can be found from the storage layer MEML_H using the memory address of the storage circuit ME_L where desired data is retained; thus, the use of a set-associative cache can increase the data reading speed. Unlike in the direct mapped cache, the number of candidates (the number of blocks included in the set) for the storage circuit ME_H to which data read from the storage layer MEML_L is to be written is more than one; thus, time for searching for desired data (time required for reading) is sometimes longer than that in the direct mapped cache.

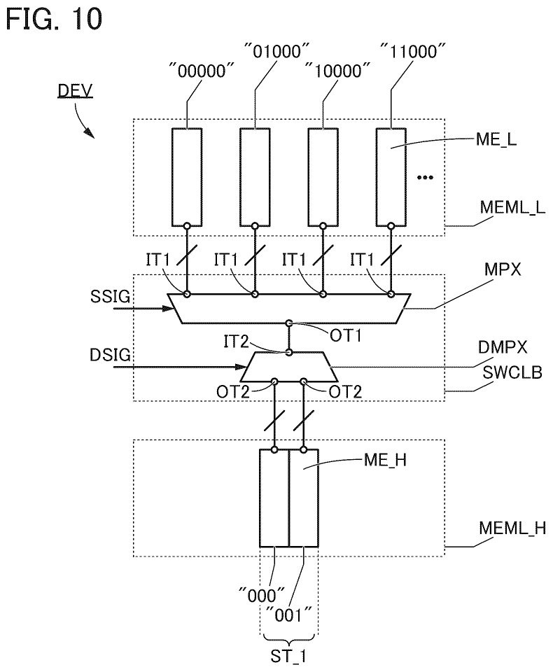

FIG. 10 illustrates a structure example of the circuit layer SWCL in the semiconductor device DEV in FIG. 9. Note that FIG. 10 illustrates the circuit layer SWCLB as the circuit layer SWCL. FIG. 10 also illustrates the storage layer MEML_L and the storage layer MEML_H as examples. FIG. 10 selectively illustrates the storage circuits ME_L whose memory addresses are “00000”, “01000”, “10000”, and “11000” in the storage layer MEML_L and the storage circuits ME_H (the set ST_1) whose memory addresses are “000” and “001” in the storage layer MEML_H.

The circuit layer SWCLB includes the selector MPX and a selector DMPX. The selector MPX includes a plurality of input terminals IT1 and one output terminal OT1, for example. The selector DMPX includes one input terminal IT2 and a plurality of output terminals OT2, for example. For the selector MPX, the description of the selector MPX in FIG. 7 can be referred to.

The plurality of input terminals IT1 of the selector MPX are electrically connected to the respective storage circuits ME_L in the storage layer MEML_L. Note that the memory addresses of the plurality of storage circuits ME_L electrically connected to the plurality of input terminals IT1 of the selector MPX have the same predetermined lower bits. The output terminal OT1 of the selector MPX is electrically connected to the input terminal IT2 of the selector DMPX. Each of the plurality of output terminals OT2 of the selector DMPX is electrically connected to the storage circuit ME_H at a predetermined memory address.

The selector DMPX has a function of establishing electrical continuity between the input terminal IT2 of the selector DMPX and one of the plurality of output terminals OT2 of the selector DMPX in accordance with the signal DSIG input to the selector DMPX, for example. The selector DMPX has a function of breaking electrical continuity between each of the other output terminals OT2 of the selector DMPX and the input terminal IT2 of the selector DMPX, for example.

Thus, the selector DMPX is referred to as a demultiplexer in some cases.

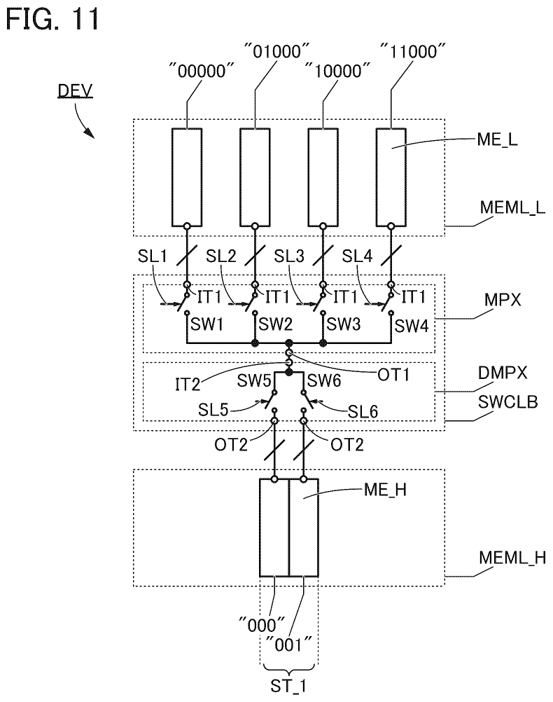

FIG. 11 is a circuit diagram illustrating a specific structure example of the selector MPX and the selector DMPX in FIG. 10.

Like the circuit layer SWCLA illustrated in FIG. 8, the selector DMPX illustrated in FIG. 11 has a structure in which the first terminals of the switch SW1 to the switch SW4 are electrically connected to the respective storage circuits ME_L, and the second terminals of the switch SW1 to the switch SW4 are electrically connected to first terminals of a switch SW5 and a switch SW6, and second terminals of the switch SW5 and switch SW6 are electrically connected to the respective storage circuits ME_H. The control terminal of the switch SW1 is electrically connected to the wiring SL1, the control terminal of the switch SW2 is electrically connected to the wiring SL2, the control terminal of the switch SW3 is electrically connected to the wiring SL3, and the control terminal of the switch SW4 is electrically connected to the wiring SL4. A control terminal of the switch SW5 is electrically connected to a wiring SL5, and the control terminal of the switch SW5 is electrically connected to the wiring SL5.

For the wiring SL1 to the wiring SL4, the description of the wiring SL1 to the wiring SL4 illustrated in FIG. 8A can be referred to.

The wiring SL5 and the wiring SL6 each function as a wiring that transmits a signal (a variable potential) for switching between the conduction state and the non-conduction state of the switch SW5 and the switch SW6, for example. Note that signals transmitted to the wiring SL5 and the wiring SL6 correspond to the signal DSIG in FIG. 10. Note that each of the wiring SL5 and the wiring SL6 may function as a wiring that supplies not a signal (a variable potential) but a constant potential (e.g., a high-level potential, a low-level potential, a ground potential, or a negative potential).

In the selector MPX illustrated in FIG. 11, for example, a high-level potential is supplied to one selected from the wiring SL1 to the wiring SL4 and a low-level potential is supplied to the others, whereby electrical continuity can be established between one of the plurality of input terminals IT1 of the selector MPX and the output terminal OT1 of the selector MPX. That is, the storage circuit ME_L included in the storage layer MEML_L can be selected in the above manner. In the selector DMPX illustrated in FIG. 11, for example, a high-level potential is supplied to one of the wiring SL5 and the wiring SL6 and a low-level potential is supplied to the other, so that electrical continuity can be established between the input terminal IT2 of the selector DMPX and one of the plurality of output terminals OT2 of the selector MPX. That is, the storage circuit ME H included in the storage layer MEML H can be selected in the above manner. Thus, electrical continuity is established between the storage circuit ME_L from which data is read and the storage circuit ME_H to which the data is written.

Note that like the selector MPX in FIG. 8B, one or both of the selector MPX and the selector DMPX in FIG. 11 may have a circuit configuration with a tournament system (not illustrated).

A sample-and-hold circuit may be provided between one of the plurality of output terminals OT2 of the selector DMPX and one of the plurality of storage circuits ME_H. In the semiconductor device DEV, a sample-and-hold circuit is provided between the output terminal OT2 of the selector DMPX and the storage circuit ME_H, whereby data of the output terminal OT2 of the selector DMPX can be temporarily retained. For example, in the semiconductor device DEV in FIG. 11, a sample-and-hold circuit is provided between the output terminal OT2 of the selector DMPX and the storage circuit ME_H, whereby data to be written to the storage circuits ME_H at the memory addresses “000” and “001” can be temporarily retained in advance. When the sample-and-hold circuit performs output operation at a time, writing data can be transmitted to the storage circuits ME_H at the memory addresses “000” and “001” at the same time. That is, the writing operations to the storage circuits ME_H at the memory addresses “000” and “001” can be synchronized. Thus, the plurality of storage circuits ME_H do not need to be individually operated, which can increase the operation speed of the semiconductor device DEV.

Note that one embodiment of the present invention is not limited to the structure of the above-described semiconductor device DEV. One embodiment of the present invention may have a structure in which the above-described semiconductor device DEV is modified.

For example, although the semiconductor device DEV described above has a structure in which the storage layer MEML_L includes 32 storage circuits ME_L and the storage layer MEML_H includes 8 storage circuits ME_H, the number of storage circuits ME_L included in the storage layer MEML_L and the number of storage circuits ME_H included in the storage layer MEML_H are not particularly limited.

For another example, in the semiconductor device DEV described above, a set in the storage layer MEML_H to be the storage destination is determined by referring to the lower 3 bits of the memory address of the storage layer MEML_L; however, the memory address of the storage layer MEML_L to be referred to for may be the lower 1 bit, the lower 2 bits, or the lower 4 or more bits. Alternatively, although the number of blocks in the set is two in the above-described two-way set-associative cache, the number of blocks in the set may be three or more. The number of storage circuits ME_L provided in the storage layer MEML_L and the number of storage circuits ME_H provided in the storage layer MEML_H may be determined in accordance with the range of the referenced memory address and the number of blocks in the set.

### Full-Associative Cache

Next, the case where a full-associative cache is employed for the storage structures of the storage layer MEML_L and the storage layer MEML_H, which is different from the direct mapped cache and the set-associative cache, will be described.

The full-associative cache refers to a method in which data read from one of the plurality of storage circuits ME_L included in the storage layer MEML_L is retained in one of the plurality of storage circuits ME_H in the storage layer MEML_H regardless of the memory address of the selected storage circuit ME_L. That is, there is no particular limitation on the data written to the storage circuit ME_H in the storage layer MEML_H by the full-associative cache.

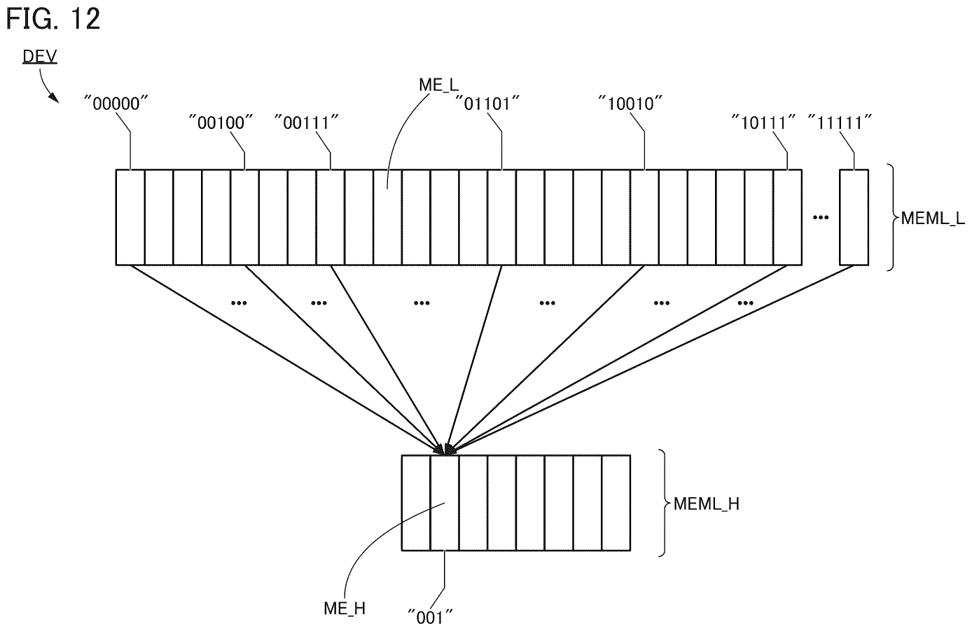

FIG. 12 illustrates an example of a full-associative cache applied to the storage layer MEML_L and the storage layer MEML_H. Like the semiconductor device DEV in FIG. 5, the semiconductor device DEV in FIG. 12 has a structure in which 32 storage circuits ME_L are included in the storage layer MEML_L and 8 storage circuits ME_H are included in the storage layer MEML H. As in the semiconductor device DEV in FIG. 5, a memory address is also shown in the semiconductor device DEV in FIG. 12.

Note that as in the description of the direct mapped cache and the set-associative cache, the number of storage circuits ME_L included in the storage layer MEML_L in the semiconductor device DEV may be other than 32. Similarly, the number of storage circuits ME_H included in the storage layer MEML_H may be other than 8.

As in the semiconductor device DEV in FIG. 5, each of the storage circuit ME_L and the storage circuit ME_H in the semiconductor device DEV in FIG. 12 includes a one-row matrix memory cell array. That is, in the case where data is read by the storage circuit ME_L, the data in one row is uniquely read from the storage circuit ME_L. In the case where data is written to the storage circuit ME_H, data is uniquely written to one row in the storage circuit ME_H.

Data to be written to one selected from the plurality of storage circuits ME_H in the storage layer MEML_H is data read from one selected from the plurality of storage circuits ME_L in the storage layer MEML_L. For example, the semiconductor device DEV in FIG. 12 shows an example in which data read from one selected from the storage circuits ME_L whose memory addresses are “00000” to “11111” in the storage layer MEML_L is written to the storage circuit ME_H whose memory address is “001” in the storage layer MEML_H.

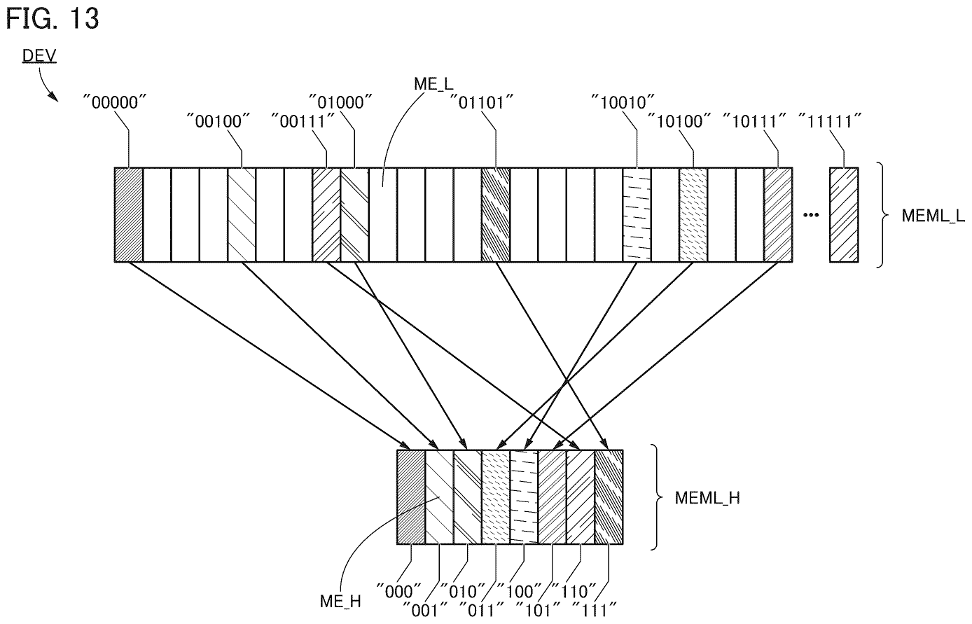

As illustrated in FIG. 12, one of the data retained in the storage circuits ME L whose memory addresses are “00000” to “11111” in the storage layer MEML_L may be stored in each of the storage circuits ME_H in the storage layer MEML_H of the semiconductor device DEV. A specific example is described with reference to FIG. 13. Data retained in the storage circuit ME_L whose memory address is “00000” in the storage layer MEML_L is written to the storage circuit ME_H whose memory address is “000” in the storage layer MEML_H. Data retained in the storage circuit ME_L whose memory address is “00100” in the storage layer MEML_L is written to the storage circuit ME_H whose memory address is “001” in the storage layer MEML_H. Data retained in the storage circuit ME_L whose memory address is “01000” in the storage layer MEML_L is written to the storage circuit ME_H whose memory address is “010” in the storage layer MEML_H. Data retained in the storage circuit ME_L whose memory address is “10100” in the storage layer MEML_L is written to the storage circuit ME_H whose memory address is “011” in the storage layer MEML_H. Data retained in the storage circuit ME_L whose memory address is “10010” in the storage layer MEML_L is written to the storage circuit ME_H whose memory address is “100” in the storage layer MEML_H. Data retained in the storage circuit ME_L whose memory address is “10100” in the storage layer MEML_L is written to the storage circuit ME_H whose memory address is “101” in the storage layer MEML_H. Data retained in the storage circuit ME_L whose memory address is “00111” in the storage layer MEML_L is written to the storage circuit ME_H whose memory address is “110” in the storage layer MEML_H. Data retained in the storage circuit ME_L whose memory address is “01101” in the storage layer MEML L is written to the storage circuit ME_H whose memory address is “111” in the storage layer MEML_H.

By the full-associative cache, for example, when an unoccupied block (a storage circuit ME_H in which data is not retained) exists in the storage layer MEML_H, data retained in one of the storage circuits ME_L whose memory addresses are “00000” to “11111” in the storage layer MEML_L can be stored in the unoccupied block. Thus, by the full-associative cache, data can be written preferentially to the storage circuit ME_H serving as an unoccupied block, so that the number of storage circuits ME_H serving as an unoccupied block (storage circuits ME_H in an idle state) can be reduced.

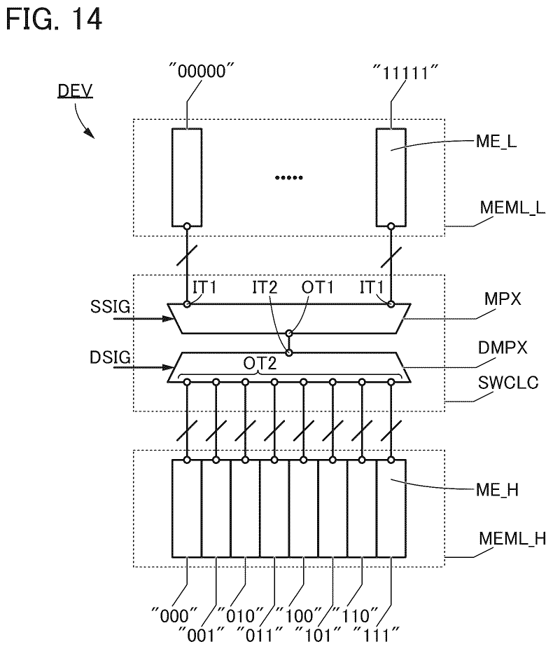

FIG. 14 illustrates a structure example of the circuit layer SWCL in the semiconductor device DEV in FIG. 13. Note that FIG. 14 illustrates a circuit layer SWCLC as the circuit layer SWCL. FIG. 14 also illustrates the storage layer MEML_L and the storage layer MEML_H.

The circuit layer SWCLC includes the selector MPX and a selector DMPX. The selector MPX includes a plurality of input terminals IT1 and one output terminal OT1, for example. The selector DMPX includes one input terminal IT2 and a plurality of output terminals OT2, for example. For the selector MPX, the description of the selector MPX in FIG. 7 can be referred to. For the selector DMPX, the description of the selector DMPX in FIG. 10 can be referred to.

The plurality of input terminals IT1 of the selector MPX are electrically connected to the respective storage circuits ME_L in the storage layer MEML_L. The output terminal OT2 of the selector MPX is electrically connected to the input terminal IT2 of the selector DMPX. The plurality of output terminals OT2 of the selector DMPX are electrically connected to the respective storage circuits ME_H in the storage layer MEML_H.

For the structure of the selector MPX, the description of the selectors MPX illustrated in FIG. 8A and FIG. 8B can be referred to. For the structure of the selector DMPX, the description of the selector DMPX illustrated in FIG. 11 can be referred to.

In the semiconductor device DEV illustrated in FIG. 14, a sample-and-hold circuit may be provided between one of the plurality of output terminals OT2 of the selector DMPX and one of the plurality of storage circuits ME_H, as in the semiconductor device DEV in FIG. 11 used for the description of the set-associative cache.

Note that one embodiment of the present invention in this embodiment is not limited to the structure of the above-described semiconductor device. One embodiment of the present invention may have a structure in which the above-described semiconductor device is modified.

For example, the above descriptions of the direct mapped cache, the set-associative cache, and the full-associative cache show examples in which each of the storage circuit ME_L and the storage circuit ME_H includes a one-row matrix memory cell array; alternatively, each of the storage circuit ME_L and the storage circuit ME_H may include a multi-row matrix memory cell array. In that case, data read from the i-th row (here, i is an integer greater than or equal to 1) of the memory cell array of the storage circuit ME_L is preferably written to the i-th row of the memory cell array of the storage circuit ME_H.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

### EMBODIMENT 2

In this embodiment, structure examples of the semiconductor device DEV described in the above embodiment and the storage circuits included in the storage layer MEML_L and the storage layer MEML_H will be described.

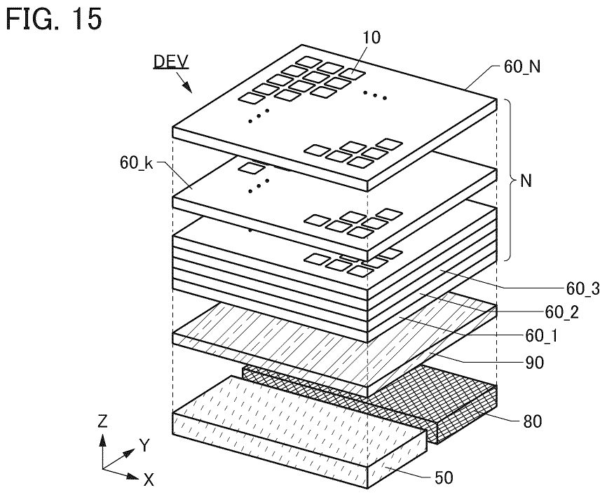

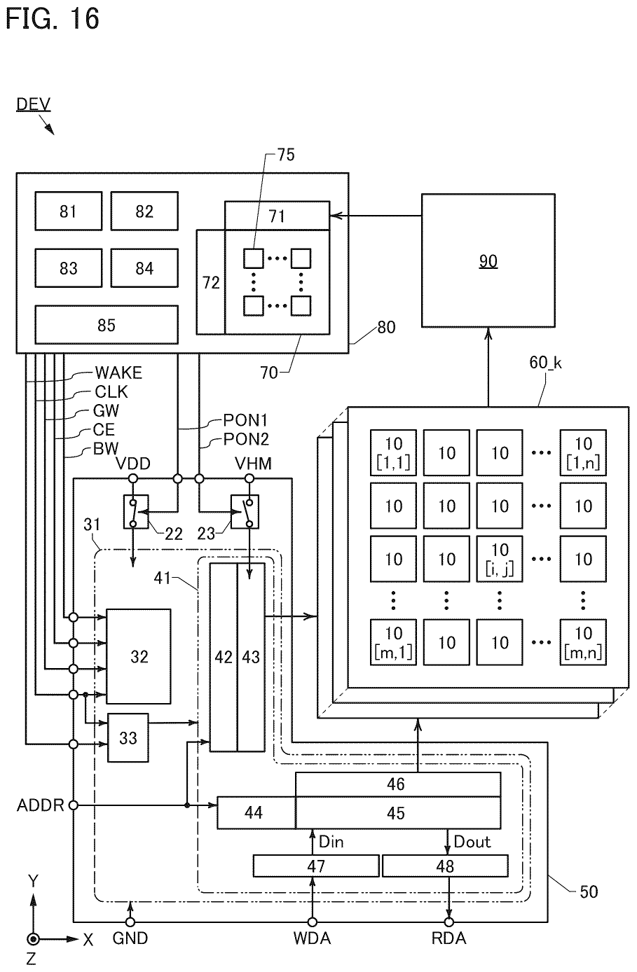

FIG. 15 is a schematic perspective view illustrating a structure example of the semiconductor device DEV. FIG. 16 is a block diagram illustrating a structure example of the semiconductor device DEV. The semiconductor device DEV includes a driver circuit region 50, a control processing region 80, a circuit layer 90, and N cell array layers 60 (Nis an integer greater than or equal to 1). One cell array layer 60 includes a plurality of memory cells 10 arranged in a matrix of m rows and n columns.

Note that FIG. 16 illustrates an example where a memory cell 10[1,1], a memory cell 10[m,1] (here, m is an integer greater than or equal to 1), a memory cell 10[1,n] (here, n is an integer greater than or equal to 1), a memory cell 10[m,n], and a memory cell 1[i,j] (here, i is an integer greater than or equal to 1 and less than or equal to m, and j is an integer greater than or equal to 1 and less than or equal to n) are provided in the cell array layer 60_k.

FIG. 16 illustrates an example in which a cell array 70, a driver circuit 71, a driver circuit 72, an ALU (Arithmetic logic unit) 81, an ALU controller 82, an instruction decoder 83, an interrupt controller 84, and a timing controller 85 are provided in the control processing region 80.

Note that the cell array layer 60_1 to the cell array layer 60_N correspond to the storage layer MEML_L described in Embodiment 1. The circuit layer 90 corresponds to the circuit layer SWCL described in Embodiment 1. The cell array 70 corresponds to the storage layer MEML_H described in Embodiment 1.

The driver circuit region 50 has a function of driving the memory cells 10 included in the cell array layer 60_1 to the cell array layer 60_N. For example, the driver circuit region 50 can execute an operation of writing data to the memory cell 10 or an operation of reading data from the memory cell 10.

The control processing region 80 corresponds to, for example, a processor that can be used in a computer. Note that the cell array 70, the driver circuit 71, and the driver circuit 72 function as a cache memory or a register provided in the processor. Specifically, for example, the driver circuit 71 functions as a column driver for the cell array 70, and the driver circuit 72 functions as a row driver for the cell array 70. In FIG. 16, the cell array 70 includes a plurality of memory cells 75 arranged in an array.

The N cell array layers 60 are provided over the circuit layer 90, for example. The circuit layer 90 is provided over the driver circuit region 50 and the control processing region 80, for example. In particular, providing the N cell array layers 60 over the driver circuit region 50 and the control processing region 80 can reduce the area occupied by the semiconductor device DEV. Furthermore, the cell array layer 60 can have high storage capacity per unit area.

Note that the driver circuit region 50 and the control processing region 80 may be provided over the same substrate. For example, the driver circuit region 50 and the control processing region 80 may be formed over a semiconductor substrate (e.g., a single crystal substrate containing silicon). Note that the structure of the semiconductor device DEV is not limited to that illustrated in FIG. 15. For example, the driver circuit region 50 may be provided over the control processing region 80. In that case, the driver circuit region 50 and the control processing region 80 may be placed over different substrates, and the driver circuit region 50 may be provided over the control processing region 80 by a technique of Cu-to-Cu (copper-to-copper) direct bonding or the like.

In this embodiment and the like, the first cell array layer 60 is referred to as the cell array layer 60_1, the second cell array layer 60 is referred to as the cell array layer 60_2, and the third cell array layer 60 is referred to as the cell array layer 60_3. The k-th cell array layer 60 (k is an integer greater than or equal to 1 and less than or equal to N) is referred to as the cell array layer 60_k, and the N-th cell array layer 60 is referred to as the cell array layer 60_N. Note that in this embodiment and the like, the simple term “cell array layer 60” is sometimes used in the case of describing a matter related to all the N cell array layers 60 or showing a matter common to the N cell array layers 60.

### Structure Example of Control Processing Region 80

In FIG. 16, the control processing region 80 includes, for example, the ALU 81, the ALU controller 82, the instruction decoder 83, the interrupt controller 84, and the timing controller 85. Note that the control processing region 80 illustrated in FIG. 16 is only an example in which its structure is simplified, and the control processing region 80 provided in the actual processor has a variety of structures depending on its application. For example, the control processing region 80 may have a configuration in which a configuration including the CPU illustrated in FIG. 16 or an arithmetic circuit is considered as one core, a plurality of the cores are included, and the cores operate in parallel, namely a configuration like that of a GPU. The number of bits that the CPU can process in an internal arithmetic circuit, a system bus, or the like can be 8, 16, 32, 64, 128, or 256 or more, for example.

An instruction that has been input to the control processing region 80 is input to the instruction decoder 83 and decoded. After being decoded, the instruction is input to the ALU controller 82, the interrupt controller 84, and the timing controller 85. The instruction may be input to the driver circuit 71 and the driver circuit 72 of the storage circuit provided in the control processing region 80.

The ALU controller 82, the interrupt controller 84, and the timing controller 85 conduct various controls in accordance with the decoded instruction. Specifically, the ALU controller 82 generates signals for controlling the operation of the ALU 81. While a program in the driver circuit region 50 is being executed, the interrupt controller 84 determines an interrupt request from an external input/output device or a peripheral circuit on the basis of its priority or a mask state, and processes the request. The storage circuit provided in the control processing region 80 can generate an address of the memory cell included in the cell array 70 on the basis of the decoded instruction, and can read/write data from/to the cell array 70 in accordance with the situation of the driver circuit region 50.

The timing controller 85 generates signals for controlling operation timings of the ALU 81, the ALU controller 82, the instruction decoder 83, the interrupt controller 84, and the storage circuit provided in the control processing region 80. For example, the timing controller 85 includes an internal clock generator for generating an internal clock signal on the basis of a reference clock signal, and supplies the internal clock signal to the above various circuits. Note that the clock signal generated by the timing controller 85 may be the above-described signal CLK.

The storage circuit provided in the control processing region 80 selects the operation of retaining data in the memory cell 75 in the cell array 70 in accordance with an instruction from the ALU 81. That is, the storage circuit selects whether data retention by a flip-flop is performed or data retention by a capacitor is performed in the memory cell included in the cell array 70. When data retention by the flip-flop is selected, a power supply voltage is supplied to the memory cell 75 in the cell array 70. When data retention by the capacitor is selected, the data is rewritten in the capacitor, and supply of the power supply voltage to the memory cell 75 in the cell array 70 can be stopped.

### Structure Example of Driver Circuit Region 50

The driver circuit region 50 in FIG. 16 includes a PSW 22 (power switch), a PSW 23, and a peripheral circuit 31. The peripheral circuit 31 includes a peripheral circuit 41, a control circuit 32, and a voltage generation circuit 33.

In the driver circuit region 50, each circuit, each signal, and each voltage can be appropriately selected as needed. Alternatively, another circuit or another signal may be added. A signal BW, a signal CE, a signal GW, the signal CLK, a signal WAKE, a signal ADDR, a signal WDA, a signal PON1, and a signal PON2 are input signals from the outside, and a signal RDA is an output signal to the outside. The signal CLK is a clock signal. Note that FIG. 16 illustrates an example in which the signal BW, the signal CE, the signal GW, the signal CLK, the signal WAKE, the signal PON1, and the signal PON2 are generated in the control processing region 80 and transmitted from the control processing region 80 to the driver circuit region 50.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PONI and the signal PON2 are power gating control signals. Note that the signal PON1 and the signal PON2 may be generated in the control circuit 32, instead of the control processing region 80.

The control circuit 32 is a logic circuit having a function of controlling the overall operation of the driver circuit region 50 and the cell array layer 60. For example, the control circuit performs a logical operation on the signal CE, the signal GW, and the signal BW to determine an operation mode (e.g., a writing operation or a reading operation) of the driver circuit region 50 and the cell array layer 60. The control circuit 32 generates a control signal for the peripheral circuit 41 so that the operation mode is executed.

The voltage generation circuit 33 has a function of generating a negative voltage. The signal WAKE has a function of controlling the input of the signal CLK to the voltage generation circuit 33. For example, when an H-level signal is supplied as the signal WAKE, the signal CLK is input to the voltage generation circuit 33, and the voltage generation circuit 33 generates a negative voltage.

The peripheral circuit 41 is a circuit for writing and reading data to/from the memory cells 10. The peripheral circuit 41 includes a row decoder 42, a column decoder 44, a row driver 43, a column driver 45, an input circuit 47, an output circuit 48, and a sense amplifier 46.

The row decoder 42 and the column decoder 44 have a function of decoding the signal ADDR. The row decoder 42 is a circuit for specifying a row to be accessed, and the column decoder 44 is a circuit for specifying a column to be accessed.

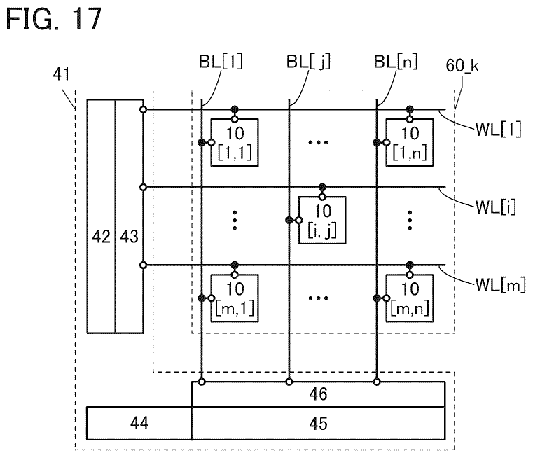

The row driver 43 has a function of selecting any one of word lines for writing and reading (e.g., any one of a wiring WL[1] to a wiring WL[m] illustrated in FIG. 17 described later) specified by the row decoder 42.

The column driver 45 has a function of writing data to the memory cells 10, a function of reading data from the memory cells 10, and a function of retaining the read data. The column driver 45 has a function of selecting write and read bit lines (e.g., a wiring BL[1] to a wiring BL[n] illustrated in FIG. 17 described later) specified by the column decoder 44.

The input circuit 47 has a function of retaining the signal WDA. Data retained by the input circuit 47 (the first data in the above embodiment) is output to the column driver 45. Data output from the input circuit 47 is data (Din) to be written to the memory cells 10. Data (Dout) read from the memory cells 10 by the column driver 45 is output to the output circuit 48. Note that in the above embodiment, the read data (Dout) is treated as arithmetic operation result data. The output circuit 48 has a function of retaining Dout. In addition, the output circuit 48 has a function of outputting Dout to the outside of the driver circuit region 50. Data output from the output circuit 48 is the signal RDA.

The PSW 22 has a function of controlling supply of VDD to the peripheral circuit 31. The PSW 23 has a function of controlling supply of VHM to the row driver 43. Here, in the driver circuit region 50, a high power supply voltage is VDD and a low power supply voltage is GND (a ground potential). In addition, VHM is a high power supply voltage used to set a word line at a high level and is higher than VDD. The on state and the off state of the PSW 22 are switched by the signal PON1, and the on state and the off state of the PSW 23 is switched by the signal PON2. The number of power domains to which VDD is supplied is one in the peripheral circuit 31 in FIG. 16 but can be more than one. In that case, a power switch is provided for each power domain.

Next, electrical connection between the peripheral circuit 41 and the cell array layer 60 is described.

FIG. 17 is a block diagram illustrating a structure example of the peripheral circuit 41 and the cell array layer 60_k. In FIG. 17, the row decoder 42 and the row driver 43 are electrically connected to each of the wiring WL[1] to the wiring WL[m], and the column decoder 44, the column driver 45, and the sense amplifier 46 are electrically connected to each of the wiring BL[1] to the wiring BL[n].

Note that the wiring WL[1] to the wiring WL[m] function as word lines. Each of the wiring WL[1] to the wiring WL[m] may be a plurality of wirings instead of one wiring. For example, the wiring WL may include a write word line and a read word line.

The wiring BL[1] to the wiring BL[n] function as bit lines. Each of the wiring BL[1] to the wiring BL[n] may be a plurality of wirings instead of one wiring. For example, the wiring BL may include a write bit line and a read bit line.

The memory cell 10[i,j] located at the i-th row and the j-th column is electrically connected to the wiring WL[i] and the wiring BL[j].

As illustrated in FIG. 17, the cell array layer 60_k is electrically connected to the peripheral circuit 41, whereby data writing to the storage layer 60_k and data reading from the cell array layer 60_k can be performed.

### Structure Examples of Cell Array Layer 60 and Cell Array 70

Next, a circuit configuration applicable to the cell array layer 60 or the cell array 70 is described.

### Structure Example 1

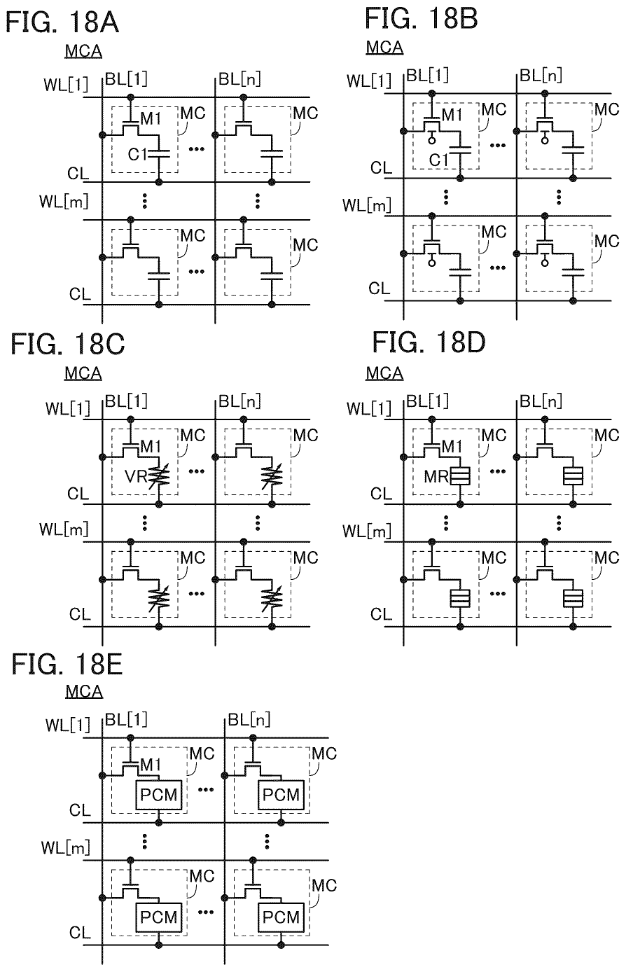

FIG. 18A illustrates a structure example in which a DRAM is used for the cell array layer 60 or the cell array 70 (hereinafter collectively referred to as a memory cell array MCA). Note that the DRAM can be used for one or more selected from the register 101, the first cache memory 102, the second cache memory 103, and the main memory 104 in the memory hierarchy 100 in FIG. 2, for example. In particular, the DRAM is preferably used for the main memory 104, for example.

FIG. 18A illustrates only the memory cells MC, in the memory cell array MCA including m rows and n columns, which are positioned in the first row and the first column, in the first row and the n-th column, in the m-th row and the first column, and in the m-th row and the n-th column. Thus, in FIG. 18A, the wiring WL in the first row is denoted by the wiring WL[1], the wiring WL in the m-th row is denoted by the wiring WL[m], the wiring BL in the first column is denoted by the wiring BL[1], and the wiring BL in the n-th row is denoted by the wiring BL[n].

Note that the memory cell MC corresponds to the memory cell 10 in the case where the memory cell array MCA is the cell array layer 60 or corresponds to the memory cell 75 in the case where the memory cell array MCA is the cell array 70.

In the memory cell array MCA in FIG. 18A, each of the memory cells MC includes a transistor M1 and a capacitor C1.

In the memory cell MC in the i-th row and the j-th column (i is an integer greater than or equal to 1 and less than or equal to m, and j is an integer greater than or equal to 1 and less than or equal to n), the first terminal of the transistor M1 is electrically connected to the wiring BL[j], the second terminal of the transistor M1 is electrically connected to the first terminal of the capacitor C1, and the gate of the transistor M1 is electrically connected to the wiring WL[i]. The second terminal of the capacitor C1 is electrically connected to a wiring CL.

The wiring CL functions as a wiring supplying a constant potential, for example. The constant potential can be, for example, a high-level potential, a low-level potential, a ground potential, or a negative potential. Note that the wiring CL may function as a wiring supplying a variable potential (e.g., a pulse potential).

Although the transistors M1 of the memory cell array MCA in FIG. 18A are n-channel transistors, but the transistors M1 can be p-channel transistors. Not only the transistors in the memory cell array MCA in FIG. 18A, but the n-channel transistors shown in this specification and the like can be replaced with p-channel transistors in some cases. Oppositely, the p-channel transistors shown in this specification and the like can be replaced with n-channel transistors in some cases.

As well as the transistors M1 included in the memory cell array MCA in FIG. 18A, the transistors described in this specification and the like can be Si transistors that contain silicon in their channel formation regions. As silicon, for example, hydrogenated amorphous silicon, microcrystalline silicon, polycrystalline silicon, or single crystal silicon can be given. The transistors described in this specification and the like can be OS transistors. The OS transistor is described later in this embodiment and Embodiment 3. As a transistor other than an OS transistor and a Si transistor, for example, a transistor containing germanium (Ge) or the like in a channel formation region, a transistor containing a compound semiconductor such as zinc selenide (ZnSe), cadmium sulfide (CdS), gallium arsenide (GaAs), indium phosphide (InP), gallium nitride (GaN), or silicon germanium (SiGe) in a channel formation region, a transistor containing a carbon nanotube in a channel formation region, or a transistor containing an organic semiconductor in a channel formation region can be used.

In particular, it is further preferable that a metal oxide included in a channel formation in the OS transistor contain one or more selected from indium, an element M (examples of the element M include aluminum, gallium, yttrium, tin, copper, vanadium, boron, titanium, iron, nickel, germanium, zirconium, molybdenum, lanthanum, cerium, neodymium, hafnium, tantalum, tungsten, magnesium, cobalt, and antimony), and zinc. The off-state current per micrometer of channel width of the OS transistor containing the metal oxide in the channel formation region can be lower than or equal to 10 aA (1×10⁻¹⁷ A), preferably lower than or equal to 1 aA (1×10⁻¹⁸ A), further preferably lower than or equal to 10 zA (1×10⁻²⁰ A), still further preferably lower than or equal to 1 zA (1×10⁻²¹ A), yet further preferably lower than or equal to 100 yA (1×10⁻²² A). Since the carrier concentration of the metal oxide in the OS transistor is low, the off-state current remains low even when the temperature of the OS transistor is changed. For example, even when the temperature of the OS transistor is 150 °C, the off-state current per micrometer of channel width can be 100 zA.

A DRAM using an OS transistor as the transistor M1 is sometimes referred to as a DOSRAM (Dynamic Oxide Semiconductor Random Access Memory).

Note that the capacitor C1 may be a ferroelectric capacitor including a pair of electrodes and a ferroelectric sandwiched between the pair of electrodes. In this case, the memory cell array MCA is referred to as an FeRAM (Ferroelectric Random Access Memory) in some cases.

In this case, the wiring CL functions not as a wiring supplying a constant potential but as a plate line polarizing a ferroelectric film of the ferroelectric capacitor or inverting the polarization of the ferroelectric film.

For example, writing operation of data to the capacitor C1, which is a ferroelectric capacitor, is performed in such a manner that the transistor M1 is turned on, a voltage corresponding to the data is supplied to the wiring BL and a predetermined potential is supplied to the wiring CL to polarize the ferroelectric film included in the capacitor C1. The reading operation of the data written from the capacitor C1 is performed in such a manner that the transistor M1 is turned on and then a pulse potential is supplied to the wiring CL. The level of the pulse potential supplied to the wiring CL may be the same as the level of the potential supplied to the wiring CL at the time of writing. As for reading of data retained in the capacitor C1, the retained data is determined to be “0” or “1” depending on whether polarization inversion occurs due to the pulse potential through the wiring CL or not. When polarization inversion occurs in the ferroelectric film of the capacitor C1, a current flows to the wiring BL through the transistor M1. That is, the amount of current flowing to the wiring BL is obtained with a reading circuit having the configuration of an integrator circuit (or a current-electric charge (IQ) converter circuit) or a current-voltage converter circuit, for example, whereby the data retained in the capacitor C1 can be read.

### Structure Example 2

The memory cell array MCA is not limited to the circuit diagram illustrated in FIG. 18A, and can have a structure in which the circuit diagram in FIG. 18A is appropriately changed. For example, as illustrated in FIG. 18B, the transistor M1 of the memory cell array MCA in FIG. 18A can include a back gate.

FIG. 18B does not illustrate the electrical connection of the back gate of the transistor M1, but depending on desired operations or characteristics of the transistor M1, the target to which the back gate of the transistor M1 is connected can be determined. The back gate of the transistor M1 can be electrically connected to, for example, the gate of the transistor M1. When the gate and the back gate of the transistor M1 are electrically connected to each other, the amount of current flowing through the transistor M1 in the on state can be increased. For example, the back gate of the transistor M1 can be provided with a wiring for electrically connecting to an external circuit, and the threshold voltage of the transistor M1 can be increased by supply of a potential to the back gate of the transistor M1 from the external circuit. With such a structure, the off-state current of the transistor M1 can be reduced owing to the external circuit.

The above-described OS transistor can be used as the transistor M1 including a back gate in the memory cell array MCA in FIG. 18B.

Although this structure example shows the structure in which the transistor M1 of the memory cell array MCA in FIG. 18A is provided with a back gate, a transistor in other structures can be provided with a back gate. In other words, a transistor described in this specification and the like can be a transistor including a back gate.

### Structure Example 3

FIG. 18C illustrates a structure example in which a ReRAM (Resistive Random Access Memory) is used for the memory cell array MCA). Note that the ReRAM can be used for one or more selected from the register 101, the first cache memory 102, the second cache memory 103, and the main memory 104 in the memory hierarchy 100 in FIG. 2, for example. In particular, the ReRAM is preferably used for the main memory 104, for example.

In the memory cell array MCA in FIG. 18C, the memory cell MC includes the transistor M1 and a variable resistor VR. The memory cell MC illustrated in FIG. 18C uses the variable resistor VR instead of the capacitor C1 in the memory cell MC in FIG. 18A.

### Structure Example 4

FIG. 18D illustrates a structure example in which an MRAM (Magnetic Random Access Memory) is used for the memory cell array MCA. Note that the MRAM can be used for one or more selected from the register 101, the first cache memory 102, the second cache memory 103, and the main memory 104 in the memory hierarchy 100 in FIG. 2, for example. In particular, the MRAM is preferably used for the main memory 104, for example.

In the memory cell array MCA in FIG. 18D, each of the memory cells MC includes the transistor M1 and a MTJ (Magnetic Tunnel Junction) element MR. The memory cell MC in FIG. 18D uses the MTJ elements MR instead of the capacitors C1 in the memory cell MC in FIG. 18A.

### Structure Example 5

FIG. 18E illustrates a structure example in which a PRAM (Phase change Random Access Memory) is used for the memory cell array MCA. Note that the PRAM can be used for one or more selected from the register 101, the first cache memory 102, the second cache memory 103, and the main memory 104 in the memory hierarchy 100 in FIG. 2, for example. In particular, the PRAM is preferably used for the main memory 104, for example.

In the memory cell array MCA in FIG. 18E, the memory cell MC includes the transistor M1 and a phase-change memory PCM. The memory cell MC illustrated in FIG. 18E uses the phase-change memories PCM instead of the capacitor C1 in the memory cell MC in FIG. 18A.

The phase-change memory PCM in a PRAM can be manufactured by replacing a dielectric material of the capacitor C1 used in a DRAM with a phase-change material in a manufacturing process. In other words, a PRAM can be manufactured with a DRAM manufacturing apparatus.

### Structure Example 6

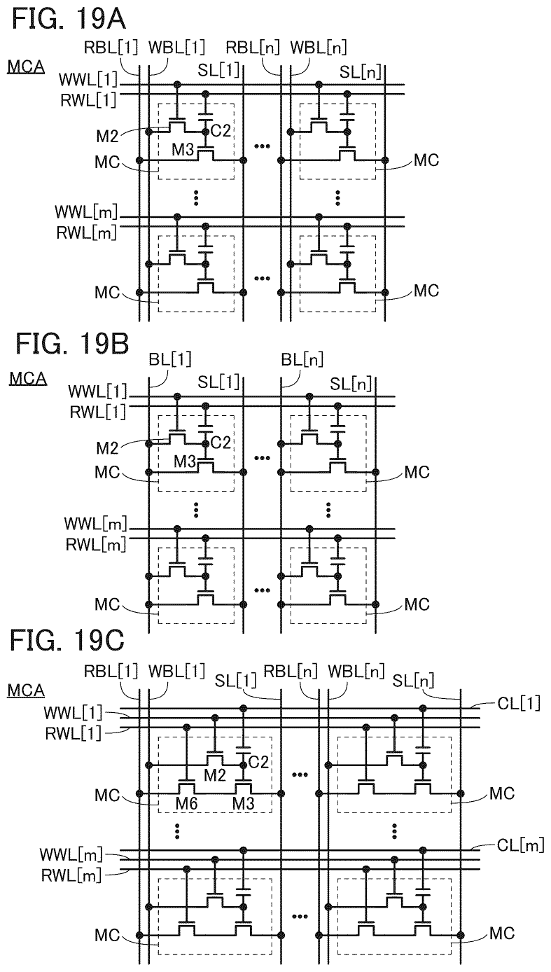

FIG. 19A illustrates an example of the memory cell array MCA including memory cells each including two transistors and one capacitor. Note that the memory cell array MCA illustrated in FIG. 19A can be used for one or more selected from the register 101, the first cache memory 102, the second cache memory 103, and the main memory 104 in the memory hierarchy 100 in FIG. 2, for example.

FIG. 19A illustrates only the memory cells MC, in the memory cell array MCA including m rows and n columns, which are positioned in the first row and the first column, in the first row and the n-th column, in the m-th row and the first column, and in the m-th row and the n-th column. Thus, in FIG. 19A, wirings positioned in the first column are denoted by a wiring RBL[1], a wiring WBL[1], and a wiring SL[1], wirings positioned in the m-th column are denoted by a wiring RBL[n], a wiring WBL[n], and a wiring SL[n], wirings positioned in the first row are denoted by the wiring WL[1] and a wiring RWL[1], and wirings positioned in the m-th row are denoted by a wiring WL[m] and a wiring RWL[m].

The memory cell MC includes a transistor M2, a transistor M3, and a capacitor C2.

As the transistor M2 and the transistor M3, transistors that can be used as the transistor M1 can be used, for example.

In particular, when an OS transistor is used as the transistor M2, a semiconductor device including the memory cells MC illustrated in FIG. 19A can be referred to as a NOSRAM (Nonvolatile Oxide Semiconductor Random Access Memory).

In the memory cell MC in the i-th row and the j-th column, a first terminal of the transistor M2 is electrically connected to a first terminal of the capacitor C2. A second terminal of the transistor M2 is electrically connected to a wiring WBL[j]. A gate of the transistor M2 is electrically connected to a wiring WWL[i]. A second terminal of the capacitor C2 is electrically connected to a wiring RWL[i]. A first terminal of the transistor M3 is electrically connected to a wiring RBL[j]. A second terminal of the transistor M3 is electrically connected to a wiring SL[j]. A gate of the transistor M3 is electrically connected to the first terminal of the capacitor C2. Note that in FIG. 19A, the wiring WWL[i], the wiring RWL[i], the wiring RBL[j], the wiring WBL[j], and the wiring SL[j] are not illustrated.

The wiring WBL[j] functions as a write bit line, the wiring RBL[j] functions as a read bit line, and each of the wiring WBL[j] and the wiring RBL[j] corresponds to the wiring BL illustrated in FIG. 17. The wiring WWL[i] functions as a write word line, the wiring RWL[i] functions as a read word line, and each of the wiring WWL[i] and the wiring RWL[i] corresponds to the wiring WL illustrated in FIG. 17.

In the time of data writing and data reading, a constant potential such as a high-level potential is preferably supplied to the wiring RWL[i]. In the time of data retention, a constant potential such as a low-level potential is preferably supplied to the wiring RWL[i].

The wiring SL[j] functions as a wiring supplying a predetermined potential when data is read from the memory cell MC.

When data is written to the memory cell MC in the i-th row and the j-th column, a high-level potential is supplied to the wiring WWL[i] to turn on the transistor M2, that is, electrical continuity is established between the wiring WBL[j] and the first terminal of the capacitor C2 of each memory cell MC. At this time, a high-level potential is preferably supplied to the wiring RWL[i]. Specifically, when the transistor M2 is in an on state, a potential corresponding to information stored in the wiring WBL[j] is supplied, whereby the potential is written to the first terminal of the capacitor C2 and the gate of the transistor M3. After that, a low-level potential is supplied to the wiring WL[i] to turn off the transistor M2, whereby the potential of the first terminal of the capacitor C2 and the potential of the gate of the transistor M3 are retained. Then, the potential of the wiring RWL[i] is changed from a high-level potential to a low-level potential, and the gate potential of the transistor M3 is lowered by capacitive coupling of the capacitor C2 to turn off the transistor M3.

In the case where data is read from the memory cell MC in the i-th row and the j-th column, a high-level potential is supplied to the wiring RWL[i] and a predetermined potential is supplied to the wiring SL[j]. The current flowing between a source and a drain of the transistor M3 and the potential of the first terminal of the transistor M3 are determined by the potential of the gate of the transistor M3 and the potential of the second terminal of the transistor M3. Thus, the potential of the wiring RBL[j] connected to the first terminal of the transistor M3 is read, so that the potential retained in the first terminal of the capacitor C2 (or the gate of the transistor M3) can be read. In other words, information written in this memory cell can be read from the potential retained in the first terminal of the capacitor C2 (or the gate of the transistor M3).

The memory cell MC illustrated in FIG. 17 is not limited to the memory cell MC illustrated in FIG. 19A. The circuit connection, the choice of a circuit, or the like for the memory cell MC in FIG. 19A can be changed in accordance with situations. For example, a transistor including a back gate can be used as each of the transistor M2 and the transistor M3.

In the memory cell array MCA in FIG. 19A, the wiring WBL[j] and the wiring RBL[j] may be combined into one wiring. The memory cell array MCA illustrated in FIG. 19B has a structure in which the wiring WBL[j] and the wiring RBL[j] are combined into the wiring BL[j] in the memory cell array MCA in FIG. 19A. When a plurality of wirings are combined into one wiring, the circuit area of the memory cell array MCA can be reduced.

The circuit configuration of the memory cell MC illustrated in FIG. 19A may be changed to that of the memory cell MC illustrated in FIG. 19C. The memory cell MC illustrated in FIG. 19C is different from the memory cell MC in FIG. 19A in including a transistor M6.

In the memory cell MC in the i-th row and the j-th column, the first terminal of the transistor M2 is electrically connected to the first terminal of the capacitor C2. The second terminal of the transistor M2 is electrically connected to the wiring WBL[j]. The gate of the transistor M2 is electrically connected to the wiring WWL[i]. The second terminal of the capacitor C2 is electrically connected to a wiring CL[i]. The first terminal of the transistor M3 is electrically connected to a first terminal of the transistor M6. The second terminal of the transistor M3 is electrically connected to the wiring SL[j]. The gate of the transistor M3 is electrically connected to the first terminal of the capacitor C2. A second terminal of the transistor M6 is electrically connected to the wiring RBL[j], and a gate of the transistor M6 is electrically connected to the wiring RWL[j]. Note that in FIG. 19C, the wiring WWL[i], the wiring RWL[i], the wiring CL[i], the wiring RBL[j], the wiring WBL[j], and the wiring SL[j] are not illustrated.

The wiring CL[i] functions as a wiring supplying a constant potential, for example. The constant potential can be, for example, a high-level potential, a low-level potential, a ground potential, or a negative potential. Note that the wiring CL[i] may function as a wiring supplying a variable potential (e.g., a pulse potential).

In the memory cell MC in FIG. 19C, the transistor M6 functions as a reading transistor. Note that as the transistor M6, a transistor that can be used as the transistor M2 or the transistor M3 can be used.

In the memory cell MC in FIG. 19A, the wiring RWL[i] functioning as a read word line is electrically connected to the second terminal of the capacitor C2; in the memory cell MC in FIG. 19C, the wiring CL[i] is electrically connected to the second terminal of the capacitor C2 as a wiring supplying a constant potential.

In the memory cell MC in FIG. 19A, the gate potential of the transistor M3 is changed by capacitive coupling due to the capacitor C2 to perform the reading operation; thus, a reading error might occur when the gate potential of the transistor M3 does not change correctly due to parasitic capacitance or the like. Meanwhile, in the memory cell MC in FIG. 19C, the gate potential of the transistor M3 is not changed by capacitive coupling due to the capacitor C2; thus, such a reading error does not occur.

### Structure Example 7

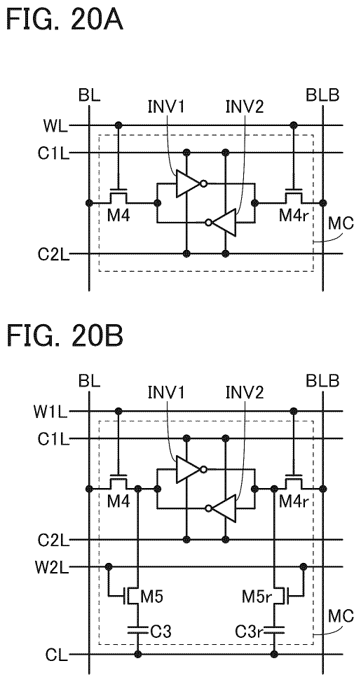

FIG. 20A illustrates an example of an SRAM that can be used for the memory cell MC of the memory cell array MCA. Note that the SRAM can be used for one or more selected from the register 101, the first cache memory 102, the second cache memory 103, and the main memory 104 in the memory hierarchy 100 in FIG. 2, for example. In particular, an SRAM is preferably used for the register 101, the first cache memory 102, and the second cache memory 103, for example.

The memory cell MC includes a transistor M4, a transistor M4r, a logic circuit INV1, and a logic circuit INV2.

As the transistor M4 and the transistor M4r, transistors that can be used as the transistor M1 can be used, for example.

The logic circuit INV1 and the logic circuit INV2 each have a function of generating and outputting an inverted signal of a signal input to the circuit. As the logic circuit INV1 and the logic circuit INV2, for example, inverter circuits can be used. In addition to the inverter circuit, a NAND circuit, a NOR circuit, an XOR circuit, a logic circuit including a combination thereof, or the like can be used.

A first terminal of the transistor M4 is electrically connected to the wiring BL, a second terminal of the transistor M4 is electrically connected to an input terminal of the logic circuit INV1 and an output terminal of the logic circuit INV2, and a gate of the transistor M4 is electrically connected to the wiring WL. A first terminal of the transistor M4r is electrically connected to a wiring BLB, a second terminal of the transistor M4r is electrically connected to an output terminal of the logic circuit INV1 and an input terminal of the logic circuit INV2, and a gate of the transistor M4r is electrically connected to the wiring WL.

Each high-power input terminal of the logic circuit INV1 and the logic circuit INV2 is electrically connected to a wiring CIL, and each low-power input terminal of the logic circuit INV1 and the logic circuit INV2 is electrically connected to a wiring C2L. The wiring CIL functions as a wiring for supplying a high-level potential, and the wiring C2L functions as a wiring for supplying a low-level potential. Note that the wiring C1L and the wiring C2L may be wirings for supplying a variable potential, instead of a fixed potential.

Data is written in the following manner: a high-level potential is supplied to the wiring WL to bring the transistor M4 into the on state, and electrical continuity is established between the wiring BL and the input terminal of the logic circuit INV1 and the output terminal of the logic circuit INV2. At this time, the transistor M4r is also turned on, and electrical continuity is established between the wiring BLB and the output terminal of the logic circuit INV1 and the input terminal of the logic circuit INV2. Thus, when data is written to the memory cell MC, a write data signal can be sent from each of the wiring BL and the wiring BLB. The write data signal input to the wiring BL is preferably an inverted signal of the signal input to the wiring BLB. The wiring BL and the wiring BLB correspond to the wiring BL illustrated in FIG. 17, and the wiring WL corresponds to the wiring WL illustrated in FIG. 17.

The memory cell MC illustrated in FIG. 17 is not limited to the memory cell MC illustrated in FIG. 20A. The circuit connection, the choice of a circuit, or the like for the memory cell MC in FIG. 20A can be changed in accordance with situations. For example, as illustrated in FIG. 20B, a transistor M5, a transistor M5r, a capacitor C3, and a capacitor C3r may be provided in the memory cell MC in FIG. 20A.

As the transistor M5 and the transistor M5r, transistors that can be used as the transistor M1 can be used, for example.

A first terminal of the transistor M5 is electrically connected to the second terminal of the transistor M4, the input terminal of the logic circuit INV1, and the output terminal of the logic circuit INV2. A second terminal of the transistor M5 is electrically connected to a first terminal of the capacitor C3. A gate of the transistor M5 is electrically connected to a wiring W2L. A first terminal of the transistor M5r is electrically connected to the second terminal of the transistor M4, the input terminal of the logic circuit INV1, and the output terminal of the logic circuit INV2. A second terminal of the transistor M5r is electrically connected to a first terminal of the capacitor C3r. A gate of the transistor M5r is electrically connected to the wiring W2L. Each second terminal of the capacitor C3 and the capacitor C3r is electrically connected to the wiring CL.

Note that a wiring WIL illustrated in the memory cell MC in FIG. 20B corresponds to the wiring WL in FIG. 20A. The wiring W2L functions as a second word line and switches the on state and the off state of each of the transistor M5 and the transistor M5r. The wiring WIL and the wiring W2L correspond to the wiring WL illustrated in FIG. 17.

The wiring CL functions as a wiring for supplying a constant potential to a second terminal of each of the capacitor C3 and the capacitor C3r. Note that the constant potential can be, for example, a high-level potential, a low-level potential, a ground potential, or a negative potential. The wiring CL may function as a wiring supplying a variable potential (e.g., a pulse potential).

By bringing the transistor M5 and the transistor M5r into the on state using the wiring W2L, electrical continuity is established between the second terminal of the transistor M4 and the first terminal of the capacitor C3, and electrical continuity is established between the second terminal of the transistor M4r and the first terminal of the capacitor C3r. This causes the potentials of the input terminal of the logic circuit INV1 and the output terminal of the logic circuit INV2 to be written to the first terminal of the capacitor C3, and causes the potentials of the output terminal of the logic circuit INV1 and the input terminal of the logic circuit INV2 to be written to the first terminal of the capacitor C3r. After that, by bringing the transistor M5 and the transistor M5r into the off state using the wiring W2L, the first terminals of the capacitor C3 and the capacitor C3r can be in a floating state, by which the potentials written to the first terminals of the capacitor C3 and the capacitor C3r can be retained. At this time, even when the voltage supplies by the wiring C1L and the wiring C2L is temporarily stopped to stop driving of the logic circuit INV1 and the logic circuit INV2, data can be retained by the transistor M5, the transistor M5r, the capacitor C3, and the capacitor C3r.

### Structure Example 1 of Semiconductor Device DEV

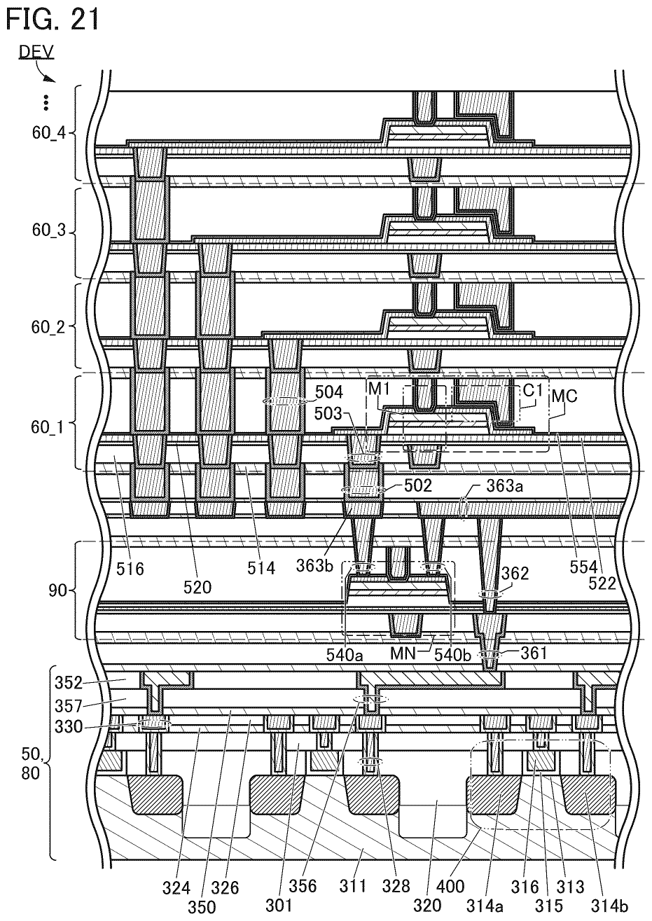

Next, FIG. 21 illustrates an example of the cross-sectional structure of the semiconductor device DEV of one embodiment of the present invention. The semiconductor device DEV illustrated in FIG. 21 includes the circuit layer 90 and a plurality of cell array layers 60 (corresponding to the storage layer MEML_L in FIG. 1 described in Embodiment 1) above the driver circuit region 50 and the control processing region 80. Note that the plurality of cell array layers 60 are positioned above the circuit layer 90.

FIG. 21 illustrates a transistor 400 included in the driver circuit layer 50 as an example. The transistor 400 is provided over a substrate 311 and includes a conductor 316 functioning as a gate, an insulator 315 functioning as a gate insulator, a semiconductor region 313 including part of the substrate 311, and a low-resistance region 314a and a low-resistance region 314b functioning as a source region and a drain region. The transistor 400 may be a p-channel transistor or an n-channel transistor. As the substrate 311, a semiconductor substrate (particularly, a single crystal substrate containing silicon as a material) can be used, for example.

Note that a single crystal substrate containing germanium as a material may be used as the substrate 311. Besides such a semiconductor substrate, for example, any of the following can be used: an SOI (Silicon On Insulator) substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, and paper and a base film each including a fibrous material. Examples of the glass substrate include a barium borosilicate glass substrate, an aluminoborosilicate glass substrate, and a soda lime glass substrate. Examples of materials for the flexible substrate, the attachment film, or the base film include plastics typified by polyethylene terephthalate (PET), polyethylene naphthalate (PEN), polyethersulfone (PES), and polytetrafluoroethylene (PTFE). Another example is a synthetic resin such as acrylic. Other examples are polypropylene, polyester, polyvinyl fluoride, and polyvinyl chloride. Other examples are polyamide, polyimide, aramid, an epoxy resin, an inorganic vapor-deposited film, and paper. Note that in the case where the manufacturing process of the semiconductor device DEV involves heat treatment, a highly heat-resistant material is preferably selected for the substrate.

In the transistor 400 illustrated in FIG. 21, the semiconductor region 313 (part of the substrate 311) where a channel is formed has a projecting shape. In addition, the conductor 316 is provided to cover the side surface and the top surface of the semiconductor region 313 with the insulator 315 therebetween. Note that the conductor 316 may be formed using a material for adjusting the work function. Such a transistor 400 is also referred to as a FIN-type transistor because of utilizing a projecting portion of a semiconductor substrate. Note that an insulator functioning as a mask for forming the projecting portion may be provided in contact with the upper portion of the projecting portion. Furthermore, although the case where the projecting portion is formed by processing part of the semiconductor substrate is described here, a semiconductor film having a projecting shape may be formed by processing an SOI (Silicon On Insulator) substrate.

Note that the transistor 400 illustrated in FIG. 21 is an example and the structure is not limited thereto; an appropriate transistor can be used in accordance with a circuit configuration or a driving method.

Wiring layers including an interlayer film, a wiring, and a plug may be provided between the structure bodies. A plurality of wiring layers can be provided in accordance with the design. Furthermore, in this specification and the like, a wiring and a plug may be a single component. That is, part of a conductor functions as a wiring in some cases and part of the conductor functions as a plug in other cases.

For example, an insulator 320, an insulator 301, an insulator 324, and an insulator 326 are stacked in this order over the transistor 400 as interlayer films. A conductor 328 or the like is embedded in the insulator 320 and the insulator 301. A conductor 330 or the like is embedded in the insulator 324 and the insulator 326. Note that the conductor 328 and the conductor 330 function as contact plugs or wirings.

As a material for each of plugs and wirings (the conductor 328 and the conductor 330), a single layer or stacked layers of one or more conductive materials selected from a metal material, an alloy material, a metal nitride material, and a metal oxide material can be used. It is preferable to use a high-melting-point material that has both heat resistance and conductivity, such as tungsten or molybdenum, and it is preferable to use tungsten. As the material, it is preferable to use a low-resistance conductive material such as aluminum or copper. The use of a low-resistance conductive material can reduce wiring resistance.

The insulator functioning as an interlayer film may function as a planarization film that covers an uneven shape thereunder. For example, the top surface of the insulator 301 may be planarized by planarization treatment using a chemical mechanical polishing (CMP) method or the like to improve planarity.

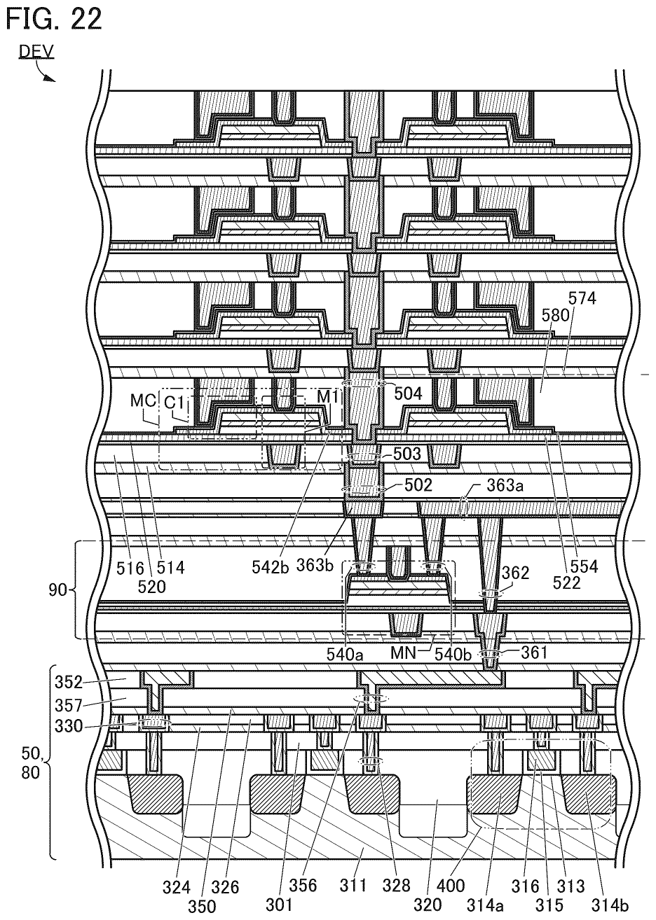

A wiring layer may be provided over the insulator 326 and the conductor 330. For example, in FIG. 22, an insulator 350, an insulator 357, and an insulator 352 are stacked sequentially over the insulator 326 and the conductor 330. A conductor 356 is formed in the insulator 350, the insulator 357, and the insulator 352. The conductor 356 functions as a contact plug or a wiring. The conductor 356 can be formed using any of the materials that can be used for the conductor 328 and the conductor 330.

The circuit layer 90 includes a transistor MN, for example. The transistor MN can be the transistor included in the circuit layer SWCL described in Embodiment 1, for example. For example, the transistor included in the circuit layer SWCL can be a transistor included in a switch included in the circuit layer SWCL.

As the transistor MN, a transistor that can be used as the transistor M1 can be used, for example.

In the semiconductor device DEV illustrated in FIG. 21, a conductor 361 and the like are provided over the conductor 356. A conductor 362 is embedded in the circuit layer 90, and a conductor 540a and a conductor 540b are provided over the pair of low-resistance regions of the transistor MN in the circuit layer 90. A conductor 363a and a conductor 363b are provided above the transistor MN. The conductor 361, the conductor 362, the conductor 363a, and the conductor 363b each function as a contact plug or a wiring.

Each of the plurality of cell array layers 60 includes a plurality of memory cells MC. Note that as the memory cell MC illustrated in FIG. 21, the memory cell MC in FIG. 18B is illustrated, for example. Thus, the transistor M1 and the capacitor C1 are illustrated in each of the memory cells MC illustrated in FIG. 21.

The conductor 502 is embedded in an interlayer film between the circuit layer 90 and the cell array layer 60_1. In each of the plurality of cell array layers 60, a conductor 503 is embedded in an insulator 514, an insulator 516, and an insulator 520 that are described later. Note that the conductor 503 may be embedded in part of the conductor 502. The conductor 502 and the conductor 503 function as a contact plug or a wiring. A conductor functioning as a contact plug or a wiring for electrically connecting to the memory cell MC in the upper cell array layer 60 is embedded in the plurality of cell array layers 60. In each of the plurality of cell array layers 60, a conductor 504 is embedded in the insulator 520, an insulator 522, a conductor 542b, an insulator 554, an insulator 580, and an insulator 574 that are described later. Note that the insulator 574 may be an insulating film formed with the same material as the insulator 514. The conductor 502, the conductor 503, and the conductor 504 function as a contact plug or a wiring.

In the semiconductor device DEV illustrated in FIG. 21, for example, the transistor MN in the circuit layer 90 is electrically connected to the transistor M1 included in the memory cell MC in the cell array layer 60_1 through the conductor 540a, the conductor 363b, the conductor 502, and the conductor 503. In particular, when the conductor 503 is in contact with a conductor 542a or the conductor 542b described later, the transistor MN and the transistor M1 are electrically connected to each other.

Although one transistor MN is provided on an electrical path between the transistor 400 included in the driver circuit region 50 and the control processing region 80 and the transistor M1 included in the memory cell MC of the cell array layer 60_1 in FIG. 21, a plurality of transistors MN may be provided on the electrical path depending on circumstances.

Although the semiconductor device DEV in FIG. 21 has a structure in which the plurality of cell array layers 60 are stacked sequentially from the bottom, the cell arrays included in the semiconductor device DEV may be formed in the stacking direction as illustrated in FIG. 22.

In the semiconductor device DEV in FIG. 22, the conductor 502 is embedded in the interlayer film between the circuit layer 90 and the cell array layer 60_1. In each of the plurality of cell array layers 60, the conductor 503 is embedded in the insulator 514 and the insulator 516 that are described later. Note that the conductor 503 may be embedded in part of the conductor 502. In each of the plurality of cell array layers 60, the conductor 504 is embedded in the insulator 520, the insulator 522, the conductor 542b, the insulator 554, the insulator 580, and the insulator 574 that are described later. Note that the insulator 574 may be an insulating film formed with the same material as the insulator 514. The conductor 502, the conductor 503, and the conductor 504 function as a contact plug or a wiring.

In the semiconductor device DEV illustrated in FIG. 22, for example, the transistor MN in the circuit layer 90 is electrically connected to the transistor M1 included in the corresponding memory cell MC in the plurality of cell array layers 60 through the conductor 540a, the conductor 363b, the conductor 502, the conductor 503, and the conductor 504. In particular, when the conductor 504 is in contact with the conductor 542b described later, the transistor MN and the transistor M1 are electrically connected to each other.

### Structure Example of Transistor

Next, structure examples of the transistor M1 and the transistor MN illustrated in FIG. 21 and FIG. 22 are described.

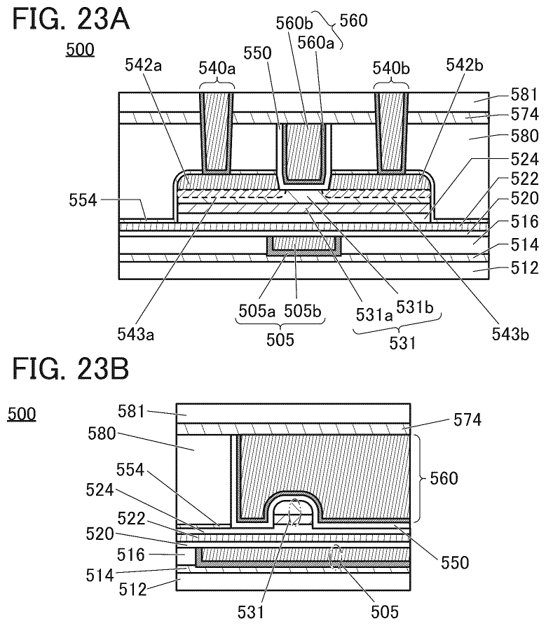

A transistor 500 illustrated in FIG. 23A and FIG. 23B is a transistor that can be used as the transistor M1 and the transistor MN of the semiconductor device DEV; in particular, FIG. 23A is a schematic cross-sectional view of the transistor 500 in the channel length direction, and FIG. 23B is a schematic cross-sectional view of the transistor 500 in the channel width direction. Note that in FIG. 23A and FIG. 23B, the transistor 500 is provided over the insulator 512.

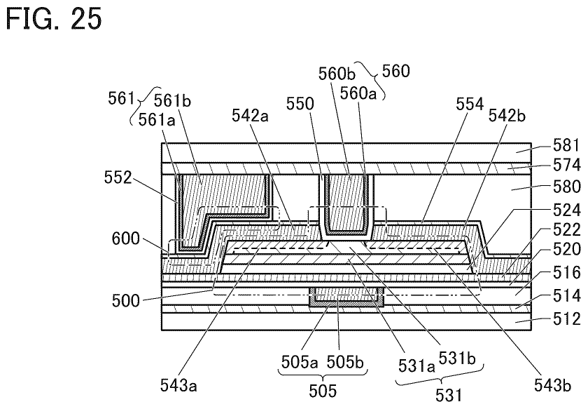

Note that the transistor 500 illustrated in FIG. 23A and FIG. 23B can be used as the transistor MN in the semiconductor device DEV, for example. As the transistor M1 in the semiconductor device DEV, for example, the structure of the transistor 500 in FIG. 25 described later, which is a modification example of FIG. 23A, can be used. In particular, the transistor M1 included in the cell array layer 60 preferably has the structure of the transistor 500 in FIG. 25 to be electrically connected to the conductor 504.

As illustrated in FIG. 23 A and FIG. 23B, the transistor 500 includes a metal oxide 531a, a metal oxide 531b, a conductor 505, the conductor 542a, the conductor 542b, the insulator 580, a conductor 560, the insulator 514, the insulator 516, the insulator 520, the insulator 522, an insulator 524, an insulator 550, the insulator 554, the insulator 574, the insulator 580, and an insulator 581, for example. Note that the transistor 500 does not necessarily include all the above components. For example, the transistor 500 may have a structure without the insulator 520.

The conductor 505 (a conductor 505a and a conductor 505b) and the insulator 516 are placed above a substrate (not illustrated). In particular, the conductor 505 is preferably provided to be embedded in the insulator 516. Specifically, the conductor 505a is preferably provided in contact with the bottom surface and the sidewall of the opening provided in the insulator 516. The conductor 505b is preferably provided to be embedded in a depression portion formed in the conductor 505a. Note that in the transistor 500 in FIG. 23A and FIG. 23B, a top surface of the conductor 505b is substantially level with a top surface of the conductor 505a and a top surface of the insulator 516.

The metal oxide 531 and the conductor 560 are located in a region overlapping with the conductor 505. The metal oxide 531b is placed over the metal oxide 531a. The conductor 542a and the conductor 542b are placed to be apart from each other over the metal oxide 531b. The insulator 580 is placed over the conductor 542a and the conductor 542b. Specifically, an opening portion is formed in the insulator 580 in a region between the conductor 542a and the conductor 542b. The conductor 560 is placed in the opening portion. The insulator 550 is provided between the conductor 560 and the metal oxide 531b, the conductor 542a, the conductor 542b, and the insulator 580. Here, as illustrated in FIG. 23A and FIG. 23B, preferably, the top surface of the conductor 560 is substantially level with the top surfaces of the insulator 550 and the insulator 580. Note that the conductor 505a and the conductor 505b may be collectively referred to as a conductor 505. The metal oxide 531a and the metal oxide 531b may be collectively referred to as a metal oxide 531. The conductor 542a and the conductor 542b may be collectively referred to as a conductor 542.

As illustrated in FIG. 23A, a region 543a is sometimes formed as a low-resistance region at and near the interface between the metal oxide 531b and the conductor 542a. Similarly, a region 543b is sometimes formed as a low-resistance region at and near the interface between the metal oxide 531b and the conductor 542b. In that case, the region 543a functions as one of a source region and a drain region, and the region 543b functions as the other of the source region and the drain region. A channel formation region is formed in a region between the region 543a and the region 543b.

When the conductor 542a (the conductor 542b) is provided to be in contact with the metal oxide 531, the oxygen concentration in the region 543a (the region 543b) sometimes decreases. In addition, a metal compound layer that contains the metal contained in the conductor 542a (the conductor 542b) and the component of the metal oxide 531 is sometimes formed in the region 543a (the region 543b). In such a case, the carrier concentration of the region 543a (the region 543b) increases, and the region 543a (the region 543b) becomes a low-resistance region.

In the transistor 500 illustrated in FIG. 23A and FIG. 23B, the side surfaces of the conductor 542a and the conductor 542b on the conductor 560 side are substantially perpendicular. Note that the transistor 500 illustrated in FIG. 23A and FIG. 23B is not limited thereto, and the angle formed between the side surfaces and bottom surfaces of the conductor 542a and the conductor 542 b may be greater than or equal to 10° and less than or equal to 80°, preferably greater than or equal to 30° and less than or equal to 60°. The side surfaces of the conductor 542 a and the conductor 542b that face each other may have a plurality of surfaces.

In the transistor 500, two layers of the metal oxide 531a and the metal oxide 531b are stacked in and around a region where a channel is formed (hereinafter also referred to as a channel formation region); however, the present invention is not limited thereto. For example, a single-layer structure of the metal oxide 531b or a stacked-layer structure of three or more layers may be employed. Furthermore, each of the metal oxide 531a and the metal oxide 531b may have a stacked-layer structure of two or more layers.

Here, the conductor 560 functions as a first gate electrode (sometimes referred to as a top gate electrode or a front gate electrode) of the transistor, and the conductor 542a and the conductor 542b function as a source electrode and a drain electrode. As described above, the conductor 560 is formed to be embedded in the opening of the insulator 580 and the region sandwiched between the conductor 542a and the conductor 542b. Here, the positions of the conductor 560, the conductor 542a, and the conductor 542b are selected in a self-aligned manner with respect to the opening of the insulator 580. In other words, in the transistor 500, the first gate electrode can be placed between the source electrode and the drain electrode in a self-aligned manner. Therefore, the conductor 560 can be formed without an alignment margin, resulting in a reduction in the area occupied by the transistor 500. Accordingly, the display apparatus can have high resolution. In addition, the display apparatus can have a narrow bezel.

The conductor 505 sometimes functions as a second gate electrode (sometimes referred to as a bottom gate electrode or a back gate electrode). In that case, the threshold voltage Vth of the transistor 500 can be controlled by changing a potential applied to the conductor 505 independently of a potential applied to the conductor 560. In particular, by applying a negative potential to the conductor 505, Vth of the transistor 500 can be made higher and the off-state current can be made low. Thus, a drain current at the time when a potential applied to the conductor 560 is 0 V can be lower in the case where a negative potential is applied to the conductor 505 than in the case where a negative potential is not applied to the conductor 505.

The conductor 505 is preferably provided to be larger than the channel formation region in the metal oxide 531. In particular, it is preferable that the conductor 505 extend, as a wiring, beyond an end portion of the metal oxide 531 that intersects with the channel width direction, as illustrated in FIG. 23B. In other words, the conductor 505 and the conductor 560 preferably overlap with each other with the insulator positioned therebetween, in a region outside the side surface of the metal oxide 531 in the channel width direction.

As illustrated in FIG. 23A, the conductor 560 preferably includes a conductor 560a provided inside the insulator 550 and a conductor 560b provided to be embedded inside the conductor 560a. Although the conductor 560 having a stacked-layer structure of two layers is illustrated in FIG. 23A and FIG. 23B, the present invention is not limited thereto. For example, the conductor 560 may have a single-layer structure or a stacked-layer structure of three or more layers.

As illustrated in FIG. 23A and FIG. 23B, the transistor 500 preferably includes the insulator 512 placed over the substrate (not illustrated); the insulator 514 placed over the insulator 512; the conductor 516 placed over the insulator 514; the conductor 505 placed to be embedded in the insulator 516; the insulator 520 placed over the insulator 516 and the conductor 505; the insulator 522 placed over the insulator 520; and the insulator 524 placed over the insulator 522. The metal oxide 531a is preferably placed over the insulator 524.

As illustrated in FIG. 23A and FIG. 23B, the insulator 554 is preferably placed between the insulator 580 and the insulator 522, the insulator 524, the metal oxide 531a, the metal oxide 531b, the conductor 542a, and the conductor 542b. Here, as illustrated in FIG. 23A and FIG. 23B, the insulator 554 is preferably in contact with the side surface of the insulator 550, the top surface and side surface of the conductor 542a, the top surface and side surface of the conductor 542b, the side surfaces and the top surfaces of the metal oxide 531a, the metal oxide 531b, and the insulator 524, and the top surface of the insulator 522.

The insulator 574 and the insulator 581 functioning as interlayer films are preferably placed over the transistor 500. Here, the insulator 574 is preferably placed in contact with the top surfaces of the conductor 560, the insulator 550, and the insulator 580.

A conductor 540 (a conductor 540a and a conductor 540b) that is electrically connected to the transistor 500 and functions as a plug is preferably provided. Thus, the conductor 540 is provided in contact with the inner wall of an opening in the insulator 554, the insulator 580, the insulator 574, and the insulator 581. In particular, a structure may be employed in which a first conductor of the conductor 540 is provided in contact with the inner wall and a second conductor of the conductor 540 is provided on the side surface of the first conductor. Here, the top surface of the conductor 540 and the top surface of the insulator 581 can be substantially level with each other.

Specifically, for example, a first conductor of the conductor 540a is provided in contact with the inner wall of one of two openings in the insulator 581, the insulator 574, the insulator 580, and the insulator 554, and a second conductor of the conductor 540a is formed in contact with the side surface thereof. Note that the conductor 542a is located on part of the bottom portion of the opening, and the conductor 540a is in contact with the conductor 542a. Similarly, for example, a first conductor of the conductor 540b is provided in contact with the inner wall of the other of the two openings in the insulator 581, the insulator 574, the insulator 580, and the insulator 554, and a second conductor of the conductor 540b is formed in contact with the side surface thereof. Note that the conductor 542b is located on part of the bottom portion of the opening, and the conductor 540b is in contact with the conductor 542b.

Although the transistor 500 has a structure in which the first conductor of the conductor 540 and the second conductor of the conductor 540 are stacked, the present invention is not limited thereto. For example, the conductor 540 may have a single-layer structure or a stacked-layer structure of three or more layers. In the case where a component has a stacked-layer structure, layers may be distinguished by ordinal numbers given corresponding to the formation order.

As illustrated in FIG. 23B, the side surface of the metal oxide 531 is placed to be covered with the conductor 560 in a region where the metal oxide 531b does not overlap with the conductor 542, that is, the channel formation region of the metal oxide 531. Accordingly, electric fields of the conductor 560 functioning as the first gate electrode are likely to act on the side surface of the metal oxide 531. Consequently, the channel formation region of the metal oxide 531 can be electrically surrounded by the electric field of the conductor 560. Thus, the on-state current of the transistor 500 can be increased and the frequency characteristics can be improved.

The structure of the transistor included in the semiconductor device of one embodiment of the present invention is not limited to that of the transistor 500 illustrated in FIG. 23A. For example, in the transistor provided in the semiconductor device DEV in FIG. 23A, the conductor 542a and the conductor 542b may be formed not only over the metal oxide 531b but also on the side surface of the metal oxide 531a, the side surface of the insulator 524, and the top surface of the insulator 522 (see FIG. 25).

### Materials For Transistor

Next, materials that can be used for the transistor 500 are described.

### Metal Oxide (oxide Semiconductor)

In the transistor 500, a metal oxide functioning as an oxide semiconductor (hereinafter, also referred to as an oxide semiconductor) is preferably used as the metal oxide 531 including the channel formation region (the metal oxide 531a and the metal oxide 531b). For example, it is preferable to use a metal oxide having a band gap of 2 eV or more, preferably 2.5 eV or more, further preferably 3.0 eV or more as the metal oxide to be the channel formation region of the metal oxide 531.

The metal oxide preferably contains at least indium or zinc. In particular, indium and zinc are preferably contained. In addition to them, an element M is preferably contained. As the element M, one or more selected from aluminum, gallium, yttrium, tin, copper, vanadium, boron, titanium, iron, nickel, germanium, zirconium, molybdenum, lanthanum, cerium, neodymium, hafnium, tantalum, tungsten, magnesium, cobalt, and antimony can be used. In particular, the element M is preferably one or more of aluminum, gallium, yttrium, and tin. The element M further preferably contains one or both of gallium and tin.

As described above, the metal oxide 531 includes the metal oxide 531a and the metal oxide 531b over the metal oxide 531a. When the metal oxide 531a is provided under the metal oxide 531b, it is possible to inhibit diffusion of impurities into the metal oxide 531b from the components formed below the metal oxide 531a.

The metal oxide 531 preferably has a stacked-layer structure of a plurality of oxide layers that differ in the atomic ratio of metal atoms. For example, in the case where the metal oxide 531 contains at least indium (In) and the element M, the proportion of the number of atoms of the element M contained in the metal oxide 531a to the number of atoms of all elements that constitute the metal oxide 531a is preferably higher than the proportion of the number of atoms of the element M contained in the metal oxide 531b to the number of atoms of all elements that constitute the metal oxide 531b. In addition, the atomic ratio of the element M to In in the metal oxide 531a is preferably greater than the atomic ratio of the element M to In in the metal oxide 531b.

The energy of the conduction band minimum of the metal oxide 531a is preferably higher than the energy of the conduction band minimum of the metal oxide 531b. In other words, the electron affinity of the metal oxide 531a is preferably smaller than the electron affinity of the metal oxide 531b.

Here, the energy level of the conduction band minimum gently changes at junction portions between the metal oxide 531a and the metal oxide 531b. In other words, at junction portions between the metal oxide 531a and the metal oxide 531b, the energy level of the conduction band minimum continuously changes or the energy levels are continuously connected. This can be achieved by decreasing the density of defect states in a mixed layer formed at the interface between the metal oxide 531a and the metal oxide 531b.

Specifically, when the metal oxide 531a and the metal oxide 531b contain the same element (as a main component) in addition to oxygen, a mixed layer with a low density of defect states can be formed. For example, an In—Ga—Zn oxide (indium-gallium-zinc oxide), a Ga—Zn oxide, or gallium oxide can be used as the metal oxide 531a, in the case where the metal oxide 531b is an In—Ga—Zn oxide.

Specifically, as the metal oxide 531 a, a metal oxide with In: Ga:Zn=1:3:4 [atomic ratio], 1:3:2 [atomic ratio], or 1:1:0.5 [atomic ratio] can be used. As the metal oxide 531b, a metal oxide with In:Ga:Zn=1:1:1 [atomic ratio], 4:2:3 [atomic ratio], or 3:1:2 [atomic ratio] can be used.

In this case, the metal oxide 531b serves as a main carrier path. When the metal oxide 531a has the above structure, the density of defect states at the interface between the metal oxide 531a and the metal oxide 531b can be made low. Thus, the influence of interface scattering on carrier conduction is small, and the transistor 500 can have a high on-state current and high frequency characteristics.

When the conductor 542 is provided in contact with the metal oxide 531, the oxygen concentration of the metal oxide 531 in the vicinity of the conductor 542 sometimes decreases. In addition, a metal compound layer that contains the metal contained in the conductor 542 and the component of the metal oxide 531 is sometimes formed in the metal oxide 531 in the vicinity of the conductor 542. In such cases, the carrier density of the region in the metal oxide 531 in the vicinity of the conductor 542 increases, and the region becomes a low-resistance region.

The metal oxide 531b in a region that does not overlap with the conductor 542 sometimes has a smaller thickness than the metal oxide 531b in a region that overlaps with the conductor 542. The thin region is formed when part of the top surface of the metal oxide 531b is removed at the time of forming the conductor 542a and the conductor 542b. When a conductive film to be the conductor 542 is formed, a low-resistance region is sometimes formed on the top surface of the metal oxide 531b in the vicinity of the interface with the conductive film. Removing the low-resistance region positioned between the conductor 542a and the conductor 542b on the top surface of the metal oxide 531b in the above manner can prevent formation of the channel in the region.

### Conductor

For the conductors, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing two or more of the above metal elements. As the conductor, for example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, or an oxide containing lanthanum and nickel. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen. As the conductor, a semiconductor having high electrical conductivity, typified by polycrystalline silicon containing an impurity element (e.g., phosphorus), or silicide (e.g., nickel silicide) may be used.

A plurality of conductors formed using any of the above materials may be stacked. For example, a stacked-layer structure combining a material containing the above metal element and a conductive material containing oxygen may be employed. In addition, a stacked-layer structure combining a material containing the above metal element and a conductive material containing nitrogen may be employed. Furthermore, a stacked-layer structure combining a material containing the above metal element, a conductive material containing oxygen, and a conductive material containing nitrogen may be employed.

For the conductor 505a which functions as the second gate electrode, it is preferable to use a conductive material having a function of inhibiting diffusion of impurities such as a hydrogen atom, a hydrogen molecule, a water molecule, a nitrogen atom, a nitrogen molecule, a nitrogen oxide molecule (e.g., N₂O, NO, or NO₂), and a copper atom. Alternatively, it is preferable to use a conductive material having a function of inhibiting diffusion of oxygen (e.g., one or both of an oxygen atom and an oxygen molecule).

When a conductive material having a function of inhibiting diffusion of hydrogen is used for the conductor 505a, impurities such as hydrogen contained in the conductor 505b can be inhibited from diffusing into the metal oxide 531 through the insulator 524. When a conductive material having a function of inhibiting diffusion of oxygen is used for the conductor 505a, the conductivity of the conductor 505b can be inhibited from being lowered because of oxidation. Examples of the conductive material having a function of inhibiting diffusion of oxygen include titanium, titanium nitride, tantalum, tantalum nitride, ruthenium, and ruthenium oxide. Thus, the conductor 505a is a single layer or stacked layers of the above conductive materials. For example, titanium nitride is used for the conductor 505a.

For the conductor 505b, a conductive material containing tungsten, copper, or aluminum as its main component is preferably used. For example, tungsten is used for the conductor 505b.

For the conductor 542 functioning as a source electrode or a drain electrode (the conductor 542a and the conductor 542b), it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing two or more of the above metal elements. As the conductor 542, for example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, or an oxide containing lanthanum and nickel. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen.

For the conductor 560a which functions as the first gate electrode, it is preferable to use a conductor having a function of inhibiting diffusion of impurities such as a hydrogen atom, a hydrogen molecule, a water molecule, a nitrogen atom, a nitrogen molecule, a nitrogen oxide molecule (e.g., N₂O, NO, or NO₂), and a copper atom. Alternatively, it is preferable to use a conductive material having a function of inhibiting diffusion of oxygen (e.g., one or both of an oxygen atom and an oxygen molecule).

When the conductor 560a has a function of inhibiting diffusion of oxygen, it is possible to inhibit a reduction in conductivity of the conductor 560b due to oxidation caused by oxygen contained in the insulator 550. Examples of the conductive material having a function of inhibiting diffusion of oxygen include tantalum, tantalum nitride, titanium, titanium nitride, ruthenium, and ruthenium oxide. When the conductive material containing oxygen is provided as the conductor 560a, oxygen released from the conductive material is easily supplied to the channel formation region.

For the conductor 560b, a conductive material containing tungsten, copper, or aluminum as its main component is preferably used. Furthermore, the conductor 560 also functions as a wiring and thus is preferably a conductor having high conductivity. For example, a conductive material containing tungsten, copper, or aluminum as its main component can be used. Moreover, the conductor 560b may have a stacked-layer structure, for example, a stacked-layer structure of the above conductive material and titanium or titanium nitride.

Alternatively, for the conductor 560, indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used, for example. For the conductor, indium gallium zinc oxide containing nitrogen may be used, for example. With the use of such a material, hydrogen contained in the metal oxide where the channel is formed can be captured in some cases. Alternatively, hydrogen entering from an external insulator or the like can be captured in other cases.

Although the conductor 560 has a two-layer structure in FIG. 23A and FIG. 23B, the conductor 560 may have a single-layer structure or a stacked-layer structure of three or more layers.

For the conductor 540a and the conductor 540b which function as plugs, a conductive material containing tungsten, copper, or aluminum as its main component is preferably used. The conductor 540a and the conductor 540b may have a stacked-layer structure.

In the case where the conductor 540 has a stacked-layer structure, the aforementioned conductor having a function of inhibiting diffusion of impurities such as water and hydrogen is preferably used as the conductor in contact with the conductor 542, the insulator 554, the insulator 580, the insulator 574, and the insulator 581. For example, tantalum, tantalum nitride, titanium, titanium nitride, ruthenium, or ruthenium oxide is preferably used for the conductor. The conductive material having a function of inhibiting diffusion of impurities such as water and hydrogen can be used as a single-layer structure or a stacked-layer structure. The use of the conductive material can inhibit oxygen added to the insulator 580 from being absorbed by the conductor 540a and the conductor 540b. Moreover, impurities such as water or hydrogen can be inhibited from entering the metal oxide 531 through the conductor 540a and the conductor 540b from a layer above the insulator 581.

Similarly, for each of the conductor 361, the conductor 362, the conductor 363a, the conductor 363b, the conductor 502, the conductor 503, and the conductor 504 which function as a contact plug or a wiring, any of the materials usable for the conductor 540a or the conductor 540b can be used.

### Insulator

Examples of the insulator include an insulating oxide, an insulating nitride, an insulating oxynitride, an insulating nitride oxide, an insulating metal oxide, an insulating metal oxynitride, and an insulating metal nitride oxide.

The insulator 514 preferably functions as a barrier insulating film that inhibits the entry of impurities such as water and hydrogen to the transistor 500 from the substrate side. Accordingly, it is preferable to use, for the insulator 514, an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom (an insulating material through which the impurities are unlikely to pass). Alternatively, it is preferable to use an insulating material having a function of inhibiting diffusion of oxygen (e.g., one or both of an oxygen atom and an oxygen molecule) (an insulating material through which the oxygen is unlikely to pass).

An insulator having a function of inhibiting the passage of oxygen and impurities such as water and hydrogen can be formed to have a single layer or a stacked layer including an insulator containing one or more selected from boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum, for example. Specific examples of the insulator having a function of inhibiting the passage of oxygen and impurities such as water and hydrogen include metal oxides such as aluminum oxide, magnesium oxide, gallium oxide, germanium oxide, yttrium oxide, zirconium oxide, lanthanum oxide, neodymium oxide, hafnium oxide, and tantalum oxide. Other examples of the insulator having a function of inhibiting the passage of oxygen and impurities such as water and hydrogen include oxides containing aluminum and hafnium (hafnium aluminate). Other examples of the insulator having a function of inhibiting the passage of oxygen and impurities such as water and hydrogen include metal nitrides such as aluminum nitride, aluminum titanium nitride, titanium nitride, silicon nitride oxide, and silicon nitride.

In particular, aluminum oxide or silicon nitride is preferably used for the insulator 514. Accordingly, it is possible to inhibit diffusion of impurities such as water and hydrogen to the transistor 500 side from the substrate side through the insulator 514. Alternatively, it is possible to inhibit diffusion of oxygen contained in the insulator 524 and the like to the substrate side through the insulator 514.

The insulator 520, the insulator 522, and the insulator 524 have a function of a second gate insulator.

Here, oxygen preferably has been released by heating from the second gate insulator in contact with the metal oxide 531. In this specification and the like, oxygen that is released by heating is referred to as excess oxygen in some cases. For example, silicon oxide or silicon oxynitride can be used as appropriate for the insulator 524 serving as the second gate insulator. When an insulator containing oxygen is provided in contact with the metal oxide 531, oxygen vacancies in the metal oxide 531 can be reduced, leading to improved reliability of the transistor 500.

Specifically, an oxide material that releases part of oxygen by heating is preferably used for the insulator 524. An oxide that releases oxygen by heating is an oxide film in which the amount of released oxygen converted into oxygen atoms is greater than or equal to 1.0×10¹⁸ atoms/cm³, preferably greater than or equal to 1.0×10¹⁹atoms/cm³ , further preferably greater than or equal to 2.0×10¹⁹ atoms/cm³ or greater than or equal to 3.0×10²⁰ atoms/cm³ in thermal desorption Spectrometry analysis method (TDS). Note that the temperature of the film surface in the TDS analysis is preferably within the range of 100 °C to 700 °C or 100 °C to 400 °C.

Like the insulator 514, the insulator 522 preferably functions as a barrier insulating film that inhibits the entry of impurities such as water and hydrogen to the transistor 500 from the substrate side. For example, the insulator 522 preferably has a lower hydrogen permeability than the insulator 524.

Furthermore, it is preferable that the insulator 522 have a function of inhibiting diffusion of oxygen (e.g., one or both of an oxygen atom and an oxygen molecule) (it is preferable that the oxygen be less likely to pass through the insulator 522). For example, the insulator 522 preferably has a lower oxygen permeability than the insulator 524. The insulator 522 preferably has a function of inhibiting diffusion of oxygen, in which case oxygen contained in the metal oxide 531 is less likely to diffuse to the substrate side. Moreover, the conductor 505 can be inhibited from reacting with oxygen contained in the insulator 524 and the metal oxide 531.

As the insulator 522, an insulator containing an oxide of one or both of aluminum and hafnium, which is an insulating material, is preferably used. Examples of the insulator containing an oxide of one or both of aluminum and hafnium include aluminum oxide, hafnium oxide, and an oxide containing aluminum and hafnium (hafnium aluminate). In the case where the insulator 522 is formed using such a material, the insulator 522 functions as a layer inhibiting release of oxygen from the metal oxide 531 and entry of impurities such as hydrogen into the metal oxide 531 from the periphery of the transistor 500.

Alternatively, aluminum oxide, bismuth oxide, germanium oxide, niobium oxide, silicon oxide, titanium oxide, tungsten oxide, yttrium oxide, or zirconium oxide may be added to these insulators, for example. Alternatively, these insulators may be subjected to nitriding treatment. A stack of the insulator and silicon oxide, silicon oxynitride, or silicon nitride may be used.

The insulator 522 may be a single layer or a stacked layer using an insulator containing what is called a high-k material, such as aluminum oxide, hafnium oxide, tantalum oxide, zirconium oxide, lead zirconate titanate (PZT), strontium titanate (SrTiO₃), or (Ba, Sr)TiO₃ (BST). Alternatively, for the insulator 522, as an insulator having a high relative permittivity, an oxide containing aluminum and hafnium, an oxynitride containing aluminum and hafnium, an oxide containing silicon and hafnium, an oxynitride containing silicon and hafnium, or a nitride containing silicon and hafnium may be used. With further miniaturization and higher integration of a transistor, a problem such as generation of a leakage current may arise because of a thinned gate insulator. When a high-k material is used for the insulator functioning as a gate insulator, a gate potential at the time of the operation of the transistor can be reduced while the physical thickness is maintained.

It is preferable that the insulator 520 be thermally stable. For example, silicon oxide and silicon oxynitride are preferable because of their thermal stability. Furthermore, the combination of an insulator that is a high-k material and silicon oxide or silicon oxynitride enables the insulator 520 to have a stacked-layer structure that has thermal stability and high relative permittivity. The insulator 520 may be formed using any of the materials that can be used for the insulator 524.

Note that the insulator 520, the insulator 522, and the insulator 524 may each have a stacked-layer structure of two or more layers. In that case, the stacked layers are not necessarily formed of the same material and may be formed of different materials.

The permittivity of each of the insulator 512, the insulator 516, the insulator 580, and the insulator 581 functioning as an interlayer film is preferably lower than that of the insulator 514. When a material with a low permittivity is used for an interlayer film, the parasitic capacitance generated between wirings can be reduced. The concentration of impurities such as water and hydrogen in the insulator 516, the insulator 580, and the insulator 581 is preferably reduced.

For the insulator 512, the insulator 516, the insulator 580, and the insulator 581, for example, silicon oxide, silicon oxynitride, silicon nitride oxide, or silicon nitride can be used. For the insulator 512, the insulator 516, the insulator 580, and the insulator 581, for example, silicon oxide to which fluorine is added, silicon oxide to which carbon is added, silicon oxide to which carbon and nitrogen are added, or porous silicon oxide can be used. In particular, silicon oxide and silicon oxynitride, which are thermally stable, are preferable. In particular, materials such as silicon oxide, silicon oxynitride, and porous silicon oxide are preferably used, in which case a region containing oxygen to be released by heating can be easily formed. A resin can be used for the insulator 512, the insulator 516, the insulator 580, and the insulator 581. A material usable for the insulator 512, the insulator 516, the insulator 580, and the insulator 581 may be an appropriate combination of the above-described materials.

Like the insulator 514 and the insulator 522, the insulator 554 and the insulator 574 preferably have a function of inhibiting diffusion of impurities such as water and hydrogen (e.g., hydrogen atoms, hydrogen molecules, or both). In other words, each of the insulator 554 and the insulator 574 preferably serves as a barrier insulating film that inhibits the entry of the impurities into the transistor 500. Moreover, the insulator 554 and the insulator 574 preferably have a function of inhibiting diffusion of oxygen (e.g., one or both of an oxygen atom and an oxygen molecule). For example, the insulator 554 and the insulator 574 preferably have a lower oxygen permeability than the insulator 524, the insulator 550, and the insulator 580. In other words, the insulator 554 and the insulator 574 preferably have a function of inhibiting oxygen released from the metal oxide 531 from diffusing to the outside of the insulator 554 or in the upward direction above the insulator 580. Thus, for the insulator 554 and the insulator 574, a material that can be used for the insulator 514 or the insulator 524 can be used.

In this manner, the insulator 524, the metal oxide 531, and the insulator 550 are surrounded by the insulator 522, the insulator 554, and the insulator 574, whereby the entry of impurities such as water and hydrogen into the transistor 500 from the outside can be inhibited. Furthermore, outward diffusion of oxygen from the inside of the transistor 500 can be inhibited.

The insulator 550 functions as a first gate insulator. The insulator 550 is preferably positioned in contact with the top surface of the metal oxide 531b. For the insulator 550, silicon oxide, silicon oxynitride, silicon nitride oxide, silicon nitride, silicon oxide to which fluorine is added, silicon oxide to which carbon is added, silicon oxide to which carbon and nitrogen are added, or porous silicon oxide can be used. In particular, silicon oxide and silicon oxynitride, which are thermally stable, are preferable.

As in the insulator 524, the concentration of impurities such as water and hydrogen in the insulator 550 is preferably reduced. The thickness of the insulator 550 is preferably greater than or equal to 1 nm and less than or equal to 20 nm.

An insulator may be provided between the insulator 550 and the insulator 580, the insulator 554, the conductor 542, and the metal oxide 531b. For example, aluminum oxide or hafnium oxide is preferably used for the insulator. Providing the insulator can inhibit release of oxygen from the metal oxide 531b, excessive supply of oxygen to the metal oxide 531b, and oxidation of the conductor 542.

A metal oxide may be provided between the insulator 550 and the conductor 560. The metal oxide preferably inhibits diffusion of oxygen from the insulator 550 to the conductor 560. Accordingly, oxidation of the conductor 560 due to oxygen in the insulator 550 can be inhibited.

The metal oxide has a function of part of the gate insulator in some cases. Therefore, when silicon oxide or silicon oxynitride is used for the insulator 550, a metal oxide that is a high-k material with a high relative permittivity is preferably used as the metal oxide. When the gate insulator has a stacked-layer structure of the insulator 550 and the metal oxide, the stacked-layer structure can be thermally stable and have a high relative permittivity. Accordingly, a gate potential applied during the operation of the transistor can be reduced while the physical thickness of the gate insulator is maintained. In addition, the equivalent oxide thickness (EOT) of the insulator functioning as the gate insulator can be reduced.

Specifically, as the metal oxide, a metal oxide containing one kind or two or more kinds selected from hafnium, aluminum, gallium, yttrium, zirconium, tungsten, titanium, tantalum, nickel, germanium, and magnesium can be used, for example. It is particularly preferable to use, as the metal oxide, any of aluminum oxide, hafnium oxide, and an oxide containing aluminum and hafnium (hafnium aluminate), which are insulators each contain an oxide of one or both of aluminum and hafnium.

A barrier insulating film that inhibits diffusion of impurities such as water, hydrogen, and oxygen may be provided between the conductor 540 and the insulator 580, the insulator 574, and the insulator 581. Thus, impurities such as water and hydrogen in the insulator 580 can be inhibited from entering the metal oxide 531 through the conductor 540a and the conductor 540b. Furthermore, oxygen contained in the insulator 580 can be inhibited from being absorbed by the conductor 540a and the conductor 540b.

Although not illustrated, a conductor functioning as a wiring may be placed in contact with the top surface of the conductor 540a and the top surface of the conductor 540b. For the conductor functioning as a wiring, a conductive material containing tungsten, copper, or aluminum as its main component is preferably used. Furthermore, the conductor may have a stacked-layer structure and may be a stack of titanium or titanium nitride and the above conductive material, for example. The conductor may be formed to be embedded in an opening provided in an insulator.

### Structure Example of Capacitor

Next, a structure example of the capacitor C1 illustrated in FIG. 21 and FIG. 22 is described.

FIG. 25 illustrates a structure example of a capacitor 600 as the capacitor C1. Note that FIG. 25 also illustrates a structure example of the transistor 500 in addition to the structure example of the capacitor 600.

In FIG. 25, an opening of the insulator 580 is provided over the insulator 554 in a region overlapping with the conductor 542a functioning as a source electrode or a drain electrode of the transistor 500. Note that the region may overlap with part of the insulator 524 and part of the metal oxide 531.

An insulator 552 is formed over the insulator 580 which corresponds to the side surface of the opening and over the insulator 554 which corresponds to the bottom surface of the opening. A conductor 561a and a conductor 561b are formed in this order over the insulator 552. Note that in this specification and the like, the conductor 561a and the conductor 561b are collectively referred to as a conductor 561 in some cases.

The conductor 542a functions as one of the pair of electrodes of the capacitor 600. The conductor 561 functions as the other of the pair of electrodes of the capacitor 600. The insulator 552 functions as a dielectric of the capacitor 600.

The conductor 561 preferably extends as a wiring in the channel width direction, for example. That is, the conductor 561 may include a region not overlapping with the conductor 542a and overlapping with the insulator 554 and the insulator 522 in the channel width direction.

A material that is usable for the conductor 560a can be used for conductor 561a, for example. A material that is usable for the conductor 560b can be used for the conductor 561b, for example.

A material with a high dielectric constant is preferably used for the insulator 552. For example, the insulator 522 may be a single layer or stacked layers of an insulator containing a high-k material that is usable for the insulator 552. The insulator 552 may contain silicon oxide or silicon oxynitride that is thermally stable.

### Modification Example of Transistor 500

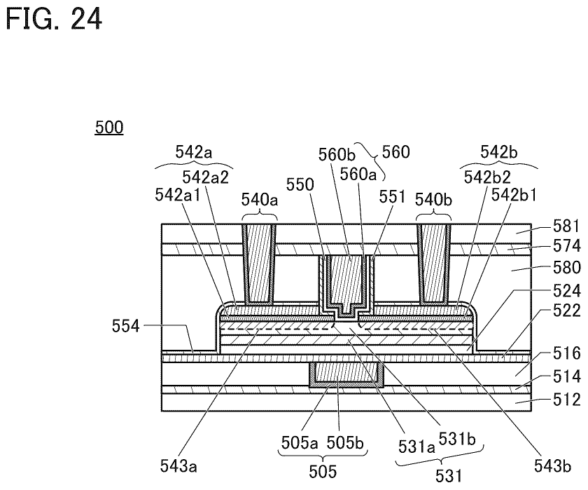

Note that the structure of the transistor included in the semiconductor device of one embodiment of the present invention is not limited to that of the transistor 500 illustrated in FIG. 23A and FIG. 23B. For example, the transistor 500 in FIG. 24 may be used as the transistor for the semiconductor device of one embodiment of the present invention. The transistor 500 in FIG. 24 is a modification example of the transistor 500 in FIG. 23A and FIG. 23B and different from the transistor 500 in FIG. 23A and FIG. 23B in that an insulator 551 is provided and the conductor 542a (a conductor 542a1 and a conductor 542a2) and the conductor 542b (a conductor 542b1 and a conductor 542b2) have a stacked-layer structure.

The conductor 542a has a stacked-layer structure of the conductor 542a1 and the conductor 542a2 over the conductor 542a1, and the conductor 542b has a stacked-layer structure of the conductor 542b1 and the conductor 542b2 over the conductor 542b1. The conductor 542a1 and the conductor 542b1 which are in contact with the metal oxide 531b are preferably conductors that are less likely to be oxidized, such as a metal nitride. Thus, excessive oxidation of the conductor 542a and the conductor 542b due to oxygen included in the metal oxide 531b can be prevented. Moreover, the conductor 542a2 and the conductor 542b2 are preferably conductors having higher conductivity than the conductor 542a1 and the conductor 542b1, such as a metal layer. Thus, the conductor 542a and the conductor 542b can function as wirings or electrodes having high conductivity. In this manner, a semiconductor device in which the conductor 542a and the conductor 542b that function as wirings or electrodes are provided in contact with the top surface of the metal oxide 531 functioning as an active layer can be provided.

As the conductor 542a1 and the conductor 542b1, a metal nitride is preferably used; for example, a nitride including tantalum, a nitride including titanium, a nitride including molybdenum, a nitride including tungsten, a nitride including tantalum and aluminum, or a nitride including titanium and aluminum is preferably used. In one embodiment of the present invention, a nitride including tantalum is particularly preferable. As another example, ruthenium, ruthenium oxide, ruthenium nitride, an oxide including strontium and ruthenium, or an oxide including lanthanum and nickel may be used. These materials are preferable because they are each a conductive material that is less likely to be oxidized or a material that maintains the conductivity even after absorbing oxygen.

The conductor 542a2 and the conductor 542b2 preferably have higher conductivity than the conductor 542a1 and the conductor 542b1. For example, the thicknesses of the conductor 542a2 and the conductor 542b2 are preferably larger than the thicknesses of the conductor 542a1 and the conductor 542b1. For the conductor 542a2 and the conductor 542b2, a conductor that can be used for the conductor 560b can be used. The above structure can reduce the resistance of the conductor 542a2 and the conductor 542b2.

For example, tantalum nitride or titanium nitride can be used for the conductor 542a1 and the conductor 542b1, and tungsten can be used for the conductor 542a2 and the conductor 542b2.

As illustrated in FIG. 24, in a cross-sectional view of the transistor 500 in the channel length direction, the distance between the conductor 542al and the conductor 542b1 is smaller than the distance between the conductor 542a2 and the conductor 542b2. With such a structure, the distance between the source and the drain can be shortened, and the channel length can be accordingly shortened. Thus, the frequency characteristics of the transistor 500 can be improved. In this manner, miniaturization of the semiconductor device enables the semiconductor device to have a higher operating speed.

The insulator 551 is preferably an insulator that is less likely to be oxidized, such as a nitride. The insulator 551 is formed in contact with a side surface of the conductor 542a2 and a side surface of the conductor 542b2 and has a function of protecting the conductor 542a2 and the conductor 542b2. The insulator 551 is exposed to an oxidized atmosphere, and thus is preferably an inorganic insulator that is less likely to be oxidized. Since the insulator 551 is in contact with the conductor 542a2 and the conductor 542b2, the insulator 551 is preferably an inorganic insulator that is less likely to oxidize the conductor 542a2 and the conductor 542b2. Therefore, for the insulator 551, an insulating material having a barrier property against oxygen is preferably used. For example, silicon nitride can be used for the insulator 551.

In the transistor 500 in FIG. 24, with a first mask, an opening is formed in the insulator 554, the insulator 580, the insulator 574, and the insulator 581 to form the conductor 542a2 and the conductor 542b2. The insulator 551 is formed in contact with a side wall of the opening. After that, the conductor 542a1 and the conductor 542b1 are formed with a second mask, whereby the transistor 500 is formed. Here, the opening overlaps with a region between the conductor 542a2 and the conductor 542b2. The conductor 542a1 and the conductor 542b1 are formed to partly extend in the opening. Thus, in the opening, the insulator 551 is in contact with the top surface of the conductors 542a1, the top surface of the conductor 542b1, a side surface of the conductor 542a2, and a side surface of the conductor 542b2. The insulator 550 is in contact with the top surface of the metal oxide 531 in a region between the conductor 542a1 and the conductor 542b1.

Heat treatment in an atmosphere containing oxygen is preferably performed after the formation of the conductor 542a1 and the conductor 542b1 and before the deposition of the insulator 550. Thus, oxygen can be supplied to the metal oxide 531a and the metal oxide 531b to reduce oxygen vacancies. Furthermore, since the insulator 551 is formed in contact with the side surface of the conductor 542a2 and the side surface of the conductor 542b2, excessive oxidation of the conductor 542a2 and the conductor 542b2 can be prevented. Accordingly, the transistor can have favorable electrical characteristics and higher reliability. In addition, variations in electrical characteristics of transistors formed over the same substrate can be reduced.

In the transistor 500, the insulator 524 may be formed into an island shape, as illustrated in FIG. 24. Here, the insulator 524 may be formed such that its side end portion is substantially aligned with a side end portion of the oxide 531.

In the transistor 500, the insulator 522 may be in contact with the insulator 516 and the conductor 505, as illustrated in FIG. 24. In other words, the insulator 520 illustrated in FIG. 23A and FIG. 23B may be omitted.

### Structure Example 2 of Semiconductor Device DEV

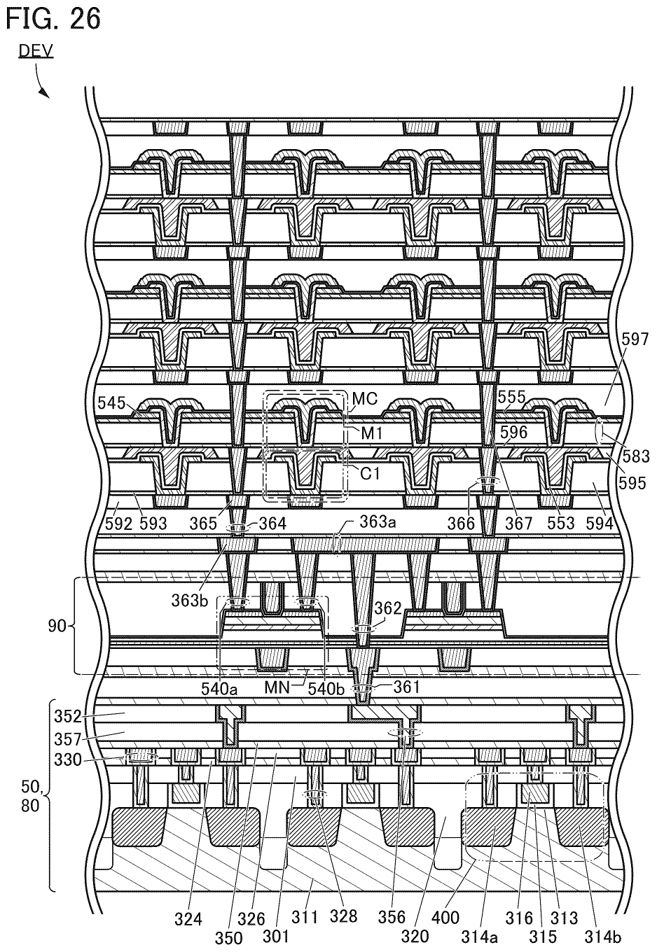

Next, FIG. 26 illustrates an example of the cross-sectional structure of the semiconductor device DEV of one embodiment of the present invention, which is different from those in FIG. 21 and FIG. 22. The semiconductor device DEV illustrated in FIG. 26 is a modification example of the semiconductor device DEV in FIG. 22 and is different from the semiconductor device DEV in FIG. 22 in that the capacitor Cl is provided below the transistor M1 in each of the memory cells MC provided in the plurality of cell array layers 60.

Note that in order to reduce repeated description, the description of the substrate 311, the driver circuit region 50, the control processing region 80, and the circuit layer 90 is omitted in this structure example.

In FIG. 26, each of the plurality of cell array layers 60 includes a plurality of memory cells MC different from the memory cell MC illustrated in FIG. 22. Note that as the memory cell MC illustrated in FIG. 26, the memory cell MC in FIG. 18A is illustrated, for example. Thus, the transistor M1 and the capacitor C1 are illustrated in each of the memory cells MC illustrated in FIG. 26.

Furthermore, a conductor 364 is embedded in an interlayer film between the circuit layer 90 and the cell array layer 60_1. In each of the plurality of cell array layers 60, a conductor 365 is embedded in an insulator 592 described later. Furthermore, in each of the plurality of cell array layers 60, a conductor 366 is embedded in an insulator 593, an insulator 594, an insulator 553, and an insulator 595 that are described later. In each of the plurality of cell array layers 60, a conductor 367 is embedded in an insulator 596, an insulator 583, a conductor 545, the insulator 555, and an insulator 597 that are described later. The conductor 364, the conductor 365, the conductor 366, and the conductor 367 function as a contact plug or a wiring.

For the conductor 364, the conductor 365, the conductor 366, and the conductor 367, any of the above-described materials usable for the conductor 502, the conductor 503, or the conductor 504 can be used, for example.

In the semiconductor device DEV illustrated in FIG. 26, for example, the transistor MN in the circuit layer 90 is electrically connected to the transistor M1 included in the corresponding memory cell MC in the plurality of cell array layers 60 through the conductor 540a, the conductor 363b, the conductor 364, the conductor 365, the conductor 366, and the conductor 367. In particular, when the conductor 504 is in contact with the conductor 542b described later, the transistor MN and the transistor M1 are electrically connected to each other.

Although one transistor MN is provided on an electrical path between the transistor 400 included in the driver circuit region 50 and the control processing region 80 and the transistor M1 included in the memory cell MC of the cell array layer 60_1 in FIG. 26, a plurality of transistors MN may be provided on the electrical path depending on circumstances.

### Structure Example of Memory Cell MC

Next, a structure example of the memory cell MC included in the plurality of cell array layers 60 of the semiconductor device DEV in FIG. 26 is described.

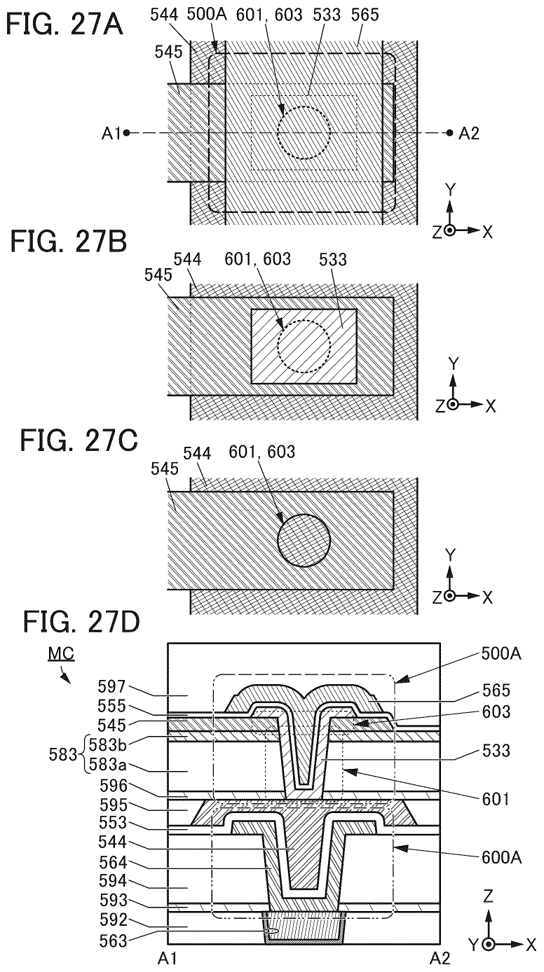

FIG. 27A is a plan view illustrating a structure example of the memory cell MC included in each of the plurality of cell array layers 60 of the semiconductor device DEV and the periphery thereof. Note that in FIG. 27A to FIG. 27D, the transistor 500A corresponds to the transistor M1 in FIG. 26, and a capacitor 600A corresponds to the capacitor 600A in FIG. 26. FIG. 27D is a cross-sectional view taken along dashed-dotted line A1-A2 in FIG. 27A. Note that in FIG. 27A, some components of the transistor M1, such as an insulator, are not illustrated. Also in the other plan views of the transistor, some components such as an insulator are not illustrated.

The capacitor 600A includes the insulator 592, the insulator 593, the insulator 594, the insulator 553, the insulator 595, a conductor 563, a conductor 564, and the conductor 544, for example.

The conductor 563 is embedded in the insulator 592. The conductor 563 can be the wiring CL extending in the Y direction, for example.

For the insulator 592, the material usable for the insulator 512, the insulator 516, the insulator 580, or the insulator 581 described above can be used, for example. In particular, a material with a low dielectric constant is preferably used for the insulator 592; for example, silicon oxide, silicon oxynitride, silicon nitride oxide, or silicon nitride is further preferably used.

For the conductor 563, any of the above-described materials usable for the conductor 505 or the conductor 365 can be used, for example.

The insulator 593 and the insulator 594 are formed in this order over the insulator 592 and the conductor 563, for example. An opening is provided in a region of the insulator 593 and a region of the insulator 594 which overlap with the conductor 563. The conductor 564 is formed on the bottom surface (over the conductor 563) and the side surface of the opening. Note that in FIG. 27, the conductor 564 is formed also on the top surface of the insulator 594. The insulator 553 is formed over the insulator 594 and the conductor 564. Furthermore, the conductor 544 is formed to cover a region of the insulator 553 that overlaps with the conductor 564. The insulator 595 is formed over the conductor 544 and the insulator 553. Note that the top surface of the insulator 595 and the top surface of the conductor 544 are preferably substantially level with each other. Thus, the insulator 595 and the conductor 544 are preferably planarized by planarization treatment using a chemical mechanical polishing (CMP) method or the like, for example.

The conductor 564 corresponds to one of a pair of terminals of the capacitor 600A, for example. The conductor 544 corresponds to the other of the pair of terminals of the capacitor 600A, for example.

The conductor 564 and the conductor 544 are preferably conductors used in the transistor 500 illustrated in FIG. 23A to FIG. 25 or the capacitor 600 illustrated in FIG. 25, for example. For the conductor 564 and the conductor 544, it is preferable to use, for example, tantalum nitride, titanium nitride, a nitride containing titanium and aluminum, a nitride containing tantalum and aluminum, ruthenium oxide, ruthenium nitride, an oxide containing strontium and ruthenium, or an oxide containing lanthanum and nickel. The materials listed above are preferable because they are each a conductive material that is not easily oxidized or a material that maintains the conductivity even after absorbing oxygen.

The insulator 553 functions as a dielectric sandwiched between the pair of terminals of the capacitor 600A, for example. Thus, the above-described material usable for the insulator 552 is preferably used for the insulator 553.

For the insulator 594 and the insulator 595, the material usable for the insulator 512, the insulator 516, the insulator 580, or the insulator 581 described above can be used, for example. In particular, a material with a low dielectric constant is preferably used for the insulator 594 and the insulator 595; for example, silicon oxide, silicon oxynitride, silicon nitride oxide, or silicon nitride is further preferably used.

The transistor 500A is provided above the conductor 544 and the insulator 595 of the capacitor 600A.

In the transistor 500A, the channel length direction is not substantially parallel to the substrate 311 but along the side surface of a later-described opening provided in the insulator 583.

The transistor 500A includes, for example, the conductor 544 functioning as one of a source electrode and a drain electrode, the conductor 545 functioning as the other of the source electrode and the drain electrode, a metal oxide 533, the insulator 555, and a conductor 565 functioning as a gate electrode. In the example in FIG. 27A, the conductor 545 extends in the direction perpendicular to the conductor 544 and the conductor 565. Note that as described above, the conductor 544 also functions as the other of the pair of electrodes of the capacitor 600A.

For the conductor 544 and the conductor 545, for example, the material that can be used for the conductor 542 included in the transistor 500 can be used. For the conductor 565, for example, the material that can be used for the conductor 560 included in the transistor 500 can be used.

For the metal oxide 533, for example, the material that can be used for the metal oxide 531 included in the transistor 500 can be used.

In FIG. 27A and FIG. 27D, the direction in which the conductor 545 extends is referred to as the X direction. The direction perpendicular to the X direction and parallel to the top surface of the conductor 563, for example, is referred to as the Y direction, and the direction perpendicular to the top surface of the conductor 563 is referred to as the Z direction. The definition of the X direction, the Y direction, and the Z direction applies to the following drawings in some cases and does not apply in other drawings. The X direction, the Y direction, and the Z direction can be perpendicular to each other. In the description of a plan view in this specification and the like, the X direction may be referred to as the right side or the left side and the Y direction may be referred to as the upper side or the lower side. The right side may be rephrased as the X direction, the left side may be referred to as the −X direction, the upper side may be referred to as the Y direction, and the lower side may be referred to as the −Y direction in some cases.

The conductor 544 functions as one of the source electrode and the drain electrode of the transistor 500A. The conductor 545 functions as the other of the source electrode and the drain electrode of the transistor 500A. The insulator 555 functions as a gate insulating layer of the transistor 500A. The conductor 565 functions as the gate electrode of the transistor 500A.

In the metal oxide 533 between the source electrode and the drain electrode, the whole region overlapping with the gate electrode with the gate insulating layer therebetween functions as the channel formation region. In the metal oxide 533, a region in contact with the source electrode functions as a source region, and a region in contact with the drain electrode functions as a drain region.

The insulator 596 is provided over the insulator 595 and the conductor 544. The insulator 596 can have a function of an interlayer insulating layer. The interlayer insulating layer here can be a barrier insulating film that inhibits diffusion of impurities such as water and hydrogen (e.g., one or both of a hydrogen atom and a hydrogen molecule). Thus, for the insulator 596, a material usable for the insulator 514 or the insulator 522 can be used.

The insulator 583 (the insulator 583a and the insulator 583b) is provided over the insulator 596, and the conductor 545 is provided over the insulator 583. The insulator 583 can have a function of an interlayer insulating layer. The interlayer insulating layer here can be an interlayer film for separation of the source electrode and the gate electrode of the transistor 500A. The insulator 597 functions as an interlayer film for providing a circuit element or a wiring above the transistor 500A.

For the insulator 583, for example, the material that can be used for any of the insulator 514, the insulator 516, the insulator 522, the insulator 524, the insulator 550, the insulator 554, the insulator 574, the insulator 580, and the insulator 581 included in the transistor 500 can be used.

Specifically, an oxide or an oxynitride is preferably used as the insulator 583a, for example. The insulator 583a is preferably formed using a film from which oxygen is released by heating. As the insulator 583a, silicon oxide or silicon oxynitride can be suitably used, for example. Oxygen release from the insulator 583a enables oxygen supply from the insulator 583a to the metal oxide 533. When oxygen is supplied from the insulator 583a to the metal oxide 533, in particular, the channel formation region of the metal oxide 533, oxygen vacancies in the metal oxide 533 and hydrogen that enters the oxygen vacancies can be reduced. Consequently, the transistor 500A with favorable electrical characteristics and high reliability can be obtained.

Specifically, silicon nitride, silicon nitride oxide, or aluminum oxide can be suitably used for the insulator 583b, for example. The insulator 583b preferably includes a region containing more nitrogen than the insulator 583a, for example. A material containing more nitrogen than the insulator 583a can be used for the insulator 583b. A nitride or a nitride oxide is preferably used for the insulator 583b. For example, silicon nitride or silicon nitride oxide can be suitably used for the insulator 583b. When silicon nitride or silicon nitride oxide is used for the insulator 583b, the insulator 583b can serve as a blocking layer that inhibits release of oxygen from the insulator 583a. When silicon nitride or silicon nitride oxide is used for the insulator 583b, the insulator 583b can serve as a blocking layer that inhibits diffusion of hydrogen into the metal oxide 533 through the insulator 583.

The insulator 596 and the insulator 583 each include an opening 601 reaching the conductor 544. The conductor 545 includes an opening 603 reaching the opening 601. That is, the opening 603 includes a region overlapping with the opening 601.

FIG. 27A illustrates, as the components of the transistor 500A, the conductor 544, the conductor 545, the metal oxide 533, the conductor 565, the opening 601 and the opening 603. FIG. 23B illustrates a structure example in which the conductor 565 is omitted from the components illustrated in FIG. 27A. In other words, FIG. 27B illustrates the conductor 544, the conductor 545, the metal oxide 533, the opening 601, and the opening 603. FIG. 27C illustrates a structure example in which the metal oxide 533 is further omitted from the components illustrated in FIG. 27B. In other words, FIG. 27C illustrates the conductor 544, the conductor 545, the opening 601, and the opening 603.

As illustrated in FIG. 27C and FIG. 27D, the conductor 545 includes the opening 603 in a region overlapping with the conductor 544. As illustrated in FIG. 27C, the conductor 545 can be formed to entirely surround the periphery of the opening 601 in a plan view. It is preferable that the conductor 545 not be provided in the opening 601. In other words, it is preferable that the conductor 545 be not in contact with the side surface of the insulator 583 on the opening 601 side.

FIG. 27A to FIG. 27C illustrate an example in which each of the opening 601 and the opening 603 is circular in a plan view. In the case where the planar shapes of the opening 601 and the opening 603 are circular, the processing accuracy of forming each of the opening 601 and the opening 603 is increased, forming the opening 601 and the opening 603 having minute sizes. Note that in this specification and the like, a circular shape is not limited to a perfect circular shape. For example, the planar shapes of the opening 601 and the opening 603 may be elliptical or a shape including a curve. Alternatively, a polygonal shape may be employed.

FIG. 27D illustrates an example in which the end portion of the conductor 545 on the opening 603 side is aligned with or substantially aligned with the end portion of the insulator 583 on the opening 601 side. In other words, the planar shape of the opening 603 is the same or substantially the same as the planar shape of the opening 601. Note that in this specification and the like, the end portion of the conductor 545 on the opening 603 side refers to the end portion of the bottom surface of the conductor 545 on the opening 603 side. The bottom surface of the conductor 545 refers to the surface on the insulator 583 side. The end portion of the insulator 583 on the opening 601 side refers to the end portion of the top surface of the insulator 583 on the opening 601 side. The top surface of the insulator 583 refers to the surface on the conductor 545 side. The planar shape of the opening 603 refers to the planar shape of the end portion of the bottom surface of the conductor 545 on the opening 603 side. The planar shape of the opening 601 refers to the planar shape of the end portion of the top surface of the insulator 583 on the opening 601 side.

In the case where end portions are aligned or substantially aligned with each other, the end portions can also be said to match or substantially match. In the case where end portions match or substantially match and the case where planar shapes are the same or substantially the same, it can be said that outlines of stacked layers at least partly overlap with each other in a plan view. For example, the case of processing the upper layer and the lower layer with use of the same mask pattern or mask patterns that are partly the same is included. Note that, in some cases, the outlines do not completely overlap with each other and the upper layer is positioned inward from the lower layer or the upper layer is positioned outward from the lower layer; such cases are also represented by the expression “end portions substantially match” or the expression “planar shapes are substantially the same”.

The opening 601 can be formed using a resist mask used for the formation of the opening 603, for example. Specifically, first, the insulator 596 over the conductor 544 and the insulator 595, the insulator 583 over the insulator 596, a conductive film to be the conductor 545 over the insulator 583, and a resist mask over the conductive film are formed. Then, the opening 603 is formed in the conductive film using the resist mask and then the opening 601 is formed in the insulator 596 and the insulator 583 using the resist mask, whereby the end portion of the opening 601 and the end portion of the opening 603 can be aligned or substantially aligned with each other. With such a structure, the process can be simplified.

The metal oxide 533 is provided to include a region positioned inside the opening 601 and the opening 603 to cover the opening 601 and the opening 603. The metal oxide 533 has a shape along the top surface and the side surface of the conductor 545, the side surface of the insulator 583, the side surface of the insulator 596 and the top surface of the conductor 544. The metal oxide 533 includes, for example, a region in contact with the top surface and the side surface of the conductor 545, the side surface of the insulator 583, and the top surface of the conductor 544.

The metal oxide 533 preferably covers the end portion of the conductor 545 on the opening 603 side. For example, FIG. 27D illustrates a structure in which the end portion of the metal oxide 533 is positioned over the conductor 545. The end portion of the metal oxide 533 can also be said to be in contact with the top surface of the conductor 545.

Although the metal oxide 533 has a single-layer structure in FIG. 27D, for example, one embodiment of the present invention is not limited thereto. The metal oxide 533 may have a stacked-layer structure of two or more layers.

The insulator 555 functioning as the gate insulating layer of the transistor 500A is provided to cover the opening 601 and the opening 603 and include a region positioned in the opening 601 and the opening 603. The insulator 555 is provided over the metal oxide 533, over the conductor 545, and over the insulator 583. The insulator 555 can include a region in contact with the top surface and the side surface of the metal oxide 533, the top surface and the side surface of the conductor 545, the top surface of the insulator 583, and the top surface of the insulator 596. The insulator 555 has a shape along the top surface of the insulator 596, the top surface of the insulator 583, the top surface and the side surface of the conductor 545, and the top surface and the side surface of the metal oxide 533.

The conductor 565 functioning as the gate electrode of the transistor 500A can be provided over the insulator 555 and can include a region in contact with the top surface of the insulator 555. The conductor 565 includes a region overlapping with the metal oxide 533 with the insulator 555 therebetween. The conductor 565 has a shape along the shape of the top surface of the insulator 555.

For example, as illustrated in FIG. 27D, the conductor 565 includes a region overlapping with the metal oxide 533 with the insulator 555 therebetween in the opening 601 and the opening 603. In the example illustrated in FIG. 27D, the conductor 565 includes a region overlapping with the conductor 544 and the conductor 545 with the insulator 555 and the metal oxide 533 therebetween. The conductor 565 covers the entire metal oxide 533. With such a structure, a gate electric field can be applied to the entire metal oxide 533, which allows the transistor 500A to have better electrical characteristics, for example, the on-state current of the transistor can be increased.

The transistor 500A is what is called a top-gate transistor including a gate electrode above the metal oxide 533. Furthermore, since the bottom surface of the metal oxide 533 includes a region in contact with the source electrode and the drain electrode, the transistor 500A can be referred to as a TGBC (Top Gate Bottom Contact) transistor.

The transistor 500A can be employed as, in addition to the transistor included in the memory cell MC, one or more selected from a transistor included in the circuit layer 90, a transistor included in the driver circuit region 50, and a transistor included in the control processing region 80, for example.

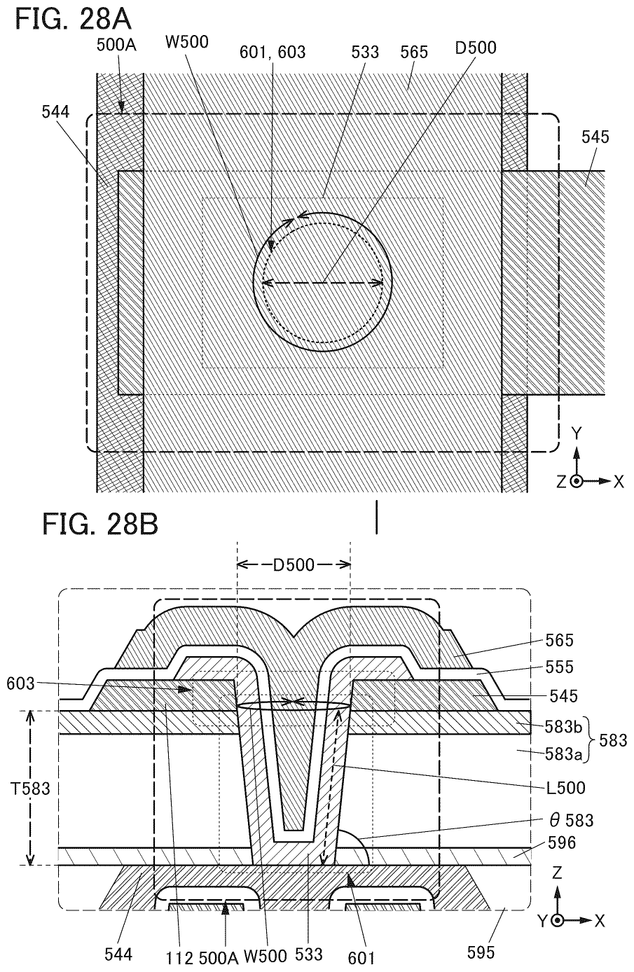

Here, the channel length and channel width of the transistor 500A are described with reference to FIG. 28A and FIG. 28B. FIG. 28A is an enlarged view of the plan view of FIG. 27A illustrating the structure example of the transistor 500A and the vicinity thereof. FIG. 28B is an enlarged view of the cross-sectional view of FIG. 27D illustrating the structure example of the transistor 500A and the vicinity thereof.

In the metal oxide 533, a region in contact with the conductor 544 functions as one of the source region and the drain region, a region in contact with the conductor 545 functions as the other of the source region and the drain region, and a region between the source region and the drain region functions as the channel formation region.

The channel length of the transistor 500A is a distance between the source region and the drain region. In FIG. 28B, a channel length L500 of the transistor 500A is indicated by a dashed double-headed arrow. In the cross-sectional view, the channel length L500 is a distance between the end portion of the region where the metal oxide 533 is in contact with the conductor 544 and the end portion of the region where the metal oxide 533 is in contact with the conductor 545.

Here, the channel length L500 of the transistor 500A corresponds to the length of the side surface of the insulator 583 on the opening 601 side when seen from the XZ plane. In other words, the channel length L500 is determined depending on a thickness T583 of the insulator 583 and an angle θ583 formed by the side surface of the insulator 583 on the opening 601 side and the formation surface of the insulator 583 (here, the top surface of the conductor 544), and is not affected by the performance of a light-exposure apparatus used for manufacturing the transistor. Thus, the channel length L500 can be a value smaller than that of the resolution limit of the light-exposure apparatus, which enables the transistor to have a minute size. For example, the channel length L500 is preferably larger than or equal to 0.010 μm and smaller than 3.0 μm, further preferably larger than or equal to 0.050 μm and smaller than 3.0 μm, still further preferably larger than or equal to 0.10 μm and smaller than 3.0 μm, yet still further preferably larger than or equal to 0.15 μm and smaller than 3.0 μm, yet still further preferably larger than or equal to 0.20 μm and smaller than 3.0 μm, yet still further preferably larger than or equal to 0.20 μm and smaller than 2.5 μm, yet still further preferably larger than or equal to 0.20 μm and smaller than 2.0 μm, yet still further preferably larger than or equal to 0.20 μm and smaller than 1.5 μm, yet still further preferably larger than or equal to 0.30 μm and smaller than 1.5 μm, yet still further preferably larger than or equal to 0.30 μm and smaller than or equal to 1.2 μm, yet still further preferably larger than or equal to 0.40 μm and smaller than or equal to 1.2 μm, yet still further preferably larger than or equal to 0.40 μm and smaller than or equal to 1.0 μm, yet still further preferably larger than or equal to 0.50 μm and smaller than or equal to 1.0 μm. In FIG. 28B, the thickness T583 of the insulator 583 is indicated by a dashed-dotted double-headed arrow.

When the transistor 500A is used as the transistor included in the memory cell MC of the semiconductor device DEV, the transistor included in the memory cell MC can be miniaturized, so that the memory cell MC can be miniaturized. Thus, the size of the semiconductor device DEV can be reduced. Furthermore, a reduction in the channel length L500 can increase the on-state current of the transistor 500A. Thus, with the use of the transistor 500A as the transistor included in the semiconductor device DEV such as the transistor included in the memory cell MC, the semiconductor device DEV can be driven at high speed.

The channel length L500 can be controlled by adjustment of the thickness T583 of the insulator 596 and the insulator 583 and the angle θ583.

The thickness T583 of the insulator 596 and the insulator 583 is preferably greater than or equal to 0.010 μm and less than 3.0 μm, further preferably greater than or equal to 0.050 μm and less than 3.0 μm, further preferably greater than or equal to 0.10 μm and less than 3.0 μm, still further preferably greater than or equal to 0.15 μm and less than 3.0 μm, yet still further preferably greater than or equal to 0.20 μm and less than 3.0 μm, yet still further preferably greater than or equal to 0.20 μm and less than 2.5 μm, yet still further preferably greater than or equal to 0.20 μm and less than 2.0 μm, yet still further preferably greater than or equal to 0.20 μm and less than 1.5 μm, yet still further preferably greater than or equal to 0.30 μm and less than 1.5 μm, yet still further preferably greater than or equal to 0.30 μm and less than or equal to 1.2 μm, yet still further preferably greater than or equal to 0.40 μm and less than or equal to 1.2 μm, yet still further preferably greater than or equal to 0.40 μm and less than or equal to 1.0 μm, yet still further preferably greater than or equal to 0.50 μm and less than or equal to 1.0 μm.

The side surfaces of the insulator 596 and the insulator 583 on the opening 601 side preferably each have a tapered shape. The angle θ583 formed by the side surfaces of the insulator 596 and the insulator 583 on the opening 601 side and the formation surface of the insulator 596 (here, the top surface of the conductor 544) is preferably less than 90°. By reducing the angle θ583, the coverage with a layer provided over the insulator 583 (e.g., the metal oxide 533) can be improved. However, reducing the angle θ583 might reduce the contact area between the metal oxide 533 and the conductor 544 to increase the contact resistance between the metal oxide 533 and the conductor 544. The angle θ583 is preferably greater than or equal to 45° and less than 90°, further preferably greater than or equal to 50°and less than 90°, further preferably greater than or equal to 55° and less than 90°, further preferably greater than or equal to 60° and less than 90°, further preferably greater than or equal to 60° and less than or equal to 85°, still further preferably greater than or equal to 65° and less than or equal to 85°, yet further preferably greater than or equal to 65° and less than or equal to 80°, yet still further preferably greater than or equal to 70° and less than or equal to 80°. When the angle θ583 is within the above range, the coverage with the layer formed over the conductor 544 and the insulator 583 (e.g., the metal oxide 533) can be improved, which can inhibit defects such as step disconnection or a void from being generated in the layer. In addition, the contact resistance between the metal oxide 533 and the conductor 544 can be reduced.

In this specification and the like, step disconnection refers to a phenomenon in which a layer, a film, or an electrode is split because of the shape of the formation surface (e.g., a step).

Although FIG. 28B illustrates the structure in which the side surfaces of the insulator 596 and the insulator 583 on the opening 601 side are linear in the cross-sectional view, one embodiment of the present invention is not limited thereto. In the cross-sectional view, the side surfaces of the insulator 596 and the insulator 583 on the opening 601 side may be curved, or the side surfaces may include both a linear region and a curved region.

The channel width of the transistor 500A is a width of the source region or a width of the drain region in the direction orthogonal to the channel length direction. In other words, the channel width is the width of the region where the metal oxide 533 is in contact with the conductor 544 or the width of the region where the metal oxide 533 is in contact with the conductor 545 in the direction orthogonal to the channel length direction. Here, the channel width of the transistor 500A is described as the width of the region where the metal oxide 533 and the conductor 545 are in contact with each other in the direction orthogonal to the channel length direction. In FIG. 28A and FIG. 28B, a channel width W500 of the transistor 500A is indicated by a solid double-headed arrow. In the plan view, the channel width W500 is the length of the end portion of the bottom surface of the conductor 545 on the opening 603 side.

The channel width W500 is determined by the planar shape of the opening 603. In FIG. 28A and FIG. 28B, the width D500 of the opening 603 is indicated by a dashed-two dotted double-headed arrow. In the plan view, the width D500 refers to the short side of the smallest rectangle that is circumscribed around the opening 603. In the case where the opening 603 is formed by a photolithography method, the width D500 of the opening 603 is larger than or equal to the resolution limit of a light-exposure apparatus. For example, the width D500 is preferably larger than or equal to 0.20 μm and smaller than 5.0 μm, further preferably larger than or equal to 0.20 μm and smaller than 4.5 μm, still further preferably larger than or equal to 0.20 μm and smaller than 4.0 μm, yet still further preferably larger than or equal to 0.20 μm and smaller than 3.5 μm, yet still further preferably larger than or equal to 0.20 μm and smaller than 3.0 μm, yet still further preferably larger than or equal to 0.20 μm and smaller than 2.5 μm, yet still further preferably larger than or equal to 0.20 μm and smaller than 2.0 μm, yet still further preferably larger than or equal to 0.20 μm and smaller than 1.5 μm, yet still further preferably larger than or equal to 0.30 μm and smaller than 1.5 μm, yet still further preferably larger than or equal to 0.30 μm and smaller than or equal to 1.2 μm, yet still further preferably larger than or equal to 0.40 μm and smaller than or equal to 1.2 μm, yet still further preferably larger than or equal to 0.40 μm and smaller than or equal to 1.0 μm, yet still further preferably larger than or equal to 0.50 μm and smaller than or equal to 1.0 μm. Note that when the planar shape of the opening 603 is circular, the width D500 corresponds to the diameter of the opening 603, and the channel width W500 can be equal to the length of the periphery of the opening 603 in a plan view and calculated to be “D500×π”.

Since the size of the transistor 500A is small, by using the transistor 500A for the cell array layer 60, a semiconductor device with high memory density can be provided. Since the operation speed of the transistor 500A is high, by using the transistor 500A for a semiconductor device, a semiconductor device with high driving speed can be provided. Since the electrical characteristics of the transistor 500A are stable, by using the transistor 500A for a semiconductor device, a semiconductor device with high reliability can be provided. Since the amount of the off-state current of the transistor 500A is small, by using the transistor 500A for a semiconductor device, a semiconductor device with low power consumption can be provided.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

### EMBODIMENT 3

In this embodiment, a transistor whose channel formation region includes an oxide semiconductor (OS transistor) is described. In the description of the OS transistor, comparison with a transistor whose channel formation region includes silicon (also referred to as Si transistor) is also described briefly.

### OS Transistor

An oxide semiconductor having a low carrier concentration is preferably used for the OS transistor. For example, the carrier concentration in a channel formation region of an oxide semiconductor is lower than or equal to 1×10¹⁸ cm⁻³, preferably lower than 1×10¹⁷ cm⁻³, further preferably lower than 1×10¹⁶ cm⁻³, still further preferably lower than 1×10¹³ cm⁻³, yet still further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor has a low density of defect states and accordingly has a low density of trap states in some cases. Charge trapped by the trap states in the oxide semiconductor takes a long time to disappear and might behave like fixed charge. A transistor whose channel formation region is formed in an oxide semiconductor having a high density of trap states has unstable electrical characteristics in some cases.

Accordingly, in order to obtain stable electrical characteristics of the transistor, reducing the concentration of impurities in the oxide semiconductor is effective. In order to reduce the impurity concentration in the oxide semiconductor, the impurity concentration in a film that is adjacent to the oxide semiconductor is preferably reduced. As examples of the impurity, hydrogen, nitrogen, and the like are given. Note that an impurity in an oxide semiconductor refers to, for example, elements other than the main components of the oxide semiconductor. For example, an element with a concentration lower than 0.1 atomic % is regarded as an impurity.

When impurities and oxygen vacancies are in a channel formation region of an oxide semiconductor in an OS transistor, electrical characteristics of the OS transistor easily vary and the reliability thereof might worsen. In the OS transistor, a defect that is an oxygen vacancy in the oxide semiconductor into which hydrogen enters (hereinafter sometimes referred to as VₒH) may be formed and may generate an electron serving as a carrier. When VₒH is formed in the channel formation region, the donor concentration in the channel formation region increases in some cases. As the donor concentration in the channel formation region increases, the threshold voltage might vary. Accordingly, when the channel formation region in the oxide semiconductor includes oxygen vacancies, the transistor tends to have normally-on characteristics (a state where a channel exists and a current flows through the transistor even when no voltage is supplied to the gate electrode). Therefore, the impurities, oxygen vacancies, and VₒH are preferably reduced as much as possible in the channel formation region in the oxide semiconductor.

The band gap of the oxide semiconductor is preferably larger than the band gap of silicon (typically 1.1 eV), further preferably larger than or equal to 2 eV, still further preferably larger than or equal to 2.5 eV, yet still further preferably larger than or equal to 3.0 eV. With use of an oxide semiconductor having a larger band gap than silicon, the off-state current (also referred to as off-leakage current or Ioff) of the transistor can be reduced.

In a Si transistor, a short-channel effect (also referred to as SCE) appears as miniaturization of the transistor proceeds. Thus, it is difficult to miniaturize the Si transistor. One factor that causes the short-channel effect is a small band gap of silicon. By contrast, the OS transistor includes an oxide semiconductor that is a semiconductor material having a wide band gap, and thus can suppress the short-channel effect. In other words, a short-channel effect does not appear or hardly appears in an OS transistor.

The short-channel effect refers to degradation of electrical characteristics which becomes obvious along with miniaturization of a transistor (a decrease in channel length). Specific examples of the short-channel effect include a decrease in threshold voltage, an increase in subthreshold swing value (sometimes also referred to as S value), an increase in leakage current, and the like. Here, the S value means the amount of change in gate voltage in the subthreshold region when the drain voltage keeps constant and the drain current changes by one order of magnitude.

The characteristic length is widely used as an indicator of resistance to a short-channel effect. The characteristic length is an indicator of curving of potential in a channel formation region. When the characteristic length is shorter, the potential rises more sharply, which means that the resistance to a short-channel effect is high.

The OS transistor is an accumulation-type transistor and the Si transistor is an inversion-type transistor. Accordingly, an OS transistor has a shorter characteristic length between a source region and a channel formation region and a shorter characteristic length between a drain region and the channel formation region than a Si transistor. Therefore, an OS transistor has higher resistance to a short-channel effect than a Si transistor. That is, in the case where a transistor with a short channel length is to be manufactured, an OS transistor is more suitable than a Si transistor.

Even in the case where the carrier concentration in the oxide semiconductor is reduced until the channel formation region becomes an i-type or substantially i-type region, the conduction band minimum of the channel formation region in a short-channel transistor decreases because of the Conduction-Band-Lowering (CBL) effect; thus, the energy difference between the conduction band minimum of the source region or the drain region and that of the channel formation region might decrease to greater than or equal to 0.1 eV and less than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n-type region and the source region and the drain region become n⁺-type regions.

An OS transistor having the above structure enables a semiconductor device to have favorable electrical characteristics even when the semiconductor device is miniaturized or highly integrated. For example, the semiconductor device can have favorable electrical characteristics even when the OS transistor has a gate length less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. In contrast, it is sometimes difficult for a Si transistor to have a gate length less than or equal to 20 nm or less than or equal to 15 nm because of appearance of a short-channel effect. Therefore, an OS transistor can be suitably used as a transistor having a short channel length as compared with a Si transistor. Note that the gate length refers to the length of a gate electrode in a direction in which carriers move inside a channel formation region during an operation of the transistor and to the width of a bottom surface of the gate electrode in a plan view of the transistor.

Miniaturization of an OS transistor can improve the high frequency characteristics of the transistor. Specifically, the cutoff frequency of the transistor can be improved. When the gate length of the OS transistor is within the above range, the cutoff frequency of the transistor can be greater than or equal to 50 GHz, preferably greater than or equal to 100 GHz, further preferably greater than or equal to 150 GHz at room temperature, for example.

As described above, an OS transistor has an effect superior to that of a Si transistor, such as a low off-state current and capability of having a short channel length.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

### EMBODIMENT 4

In this embodiment, electronic components, electronic devices, a large computer, space equipment, and a data center (also referred to as DC) in which the semiconductor device described in the above embodiment can be used will be described. Electronic components, electronic devices, a large computer, space equipment, and a data center in which the semiconductor device of one embodiment of the present invention is used are effective in improving performance, e.g., reducing power consumption.

### Electronic Component

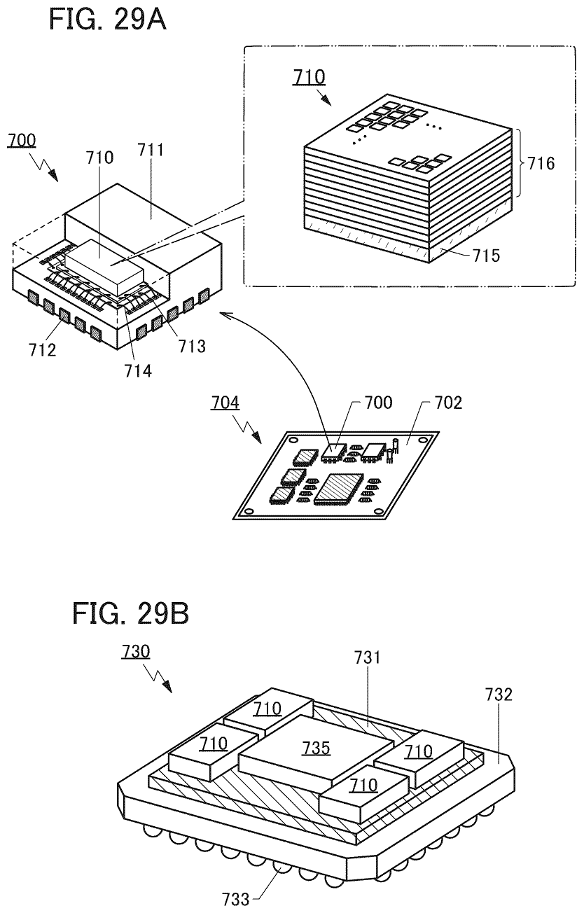

FIG. 29A is a perspective view of a substrate (a circuit board 704) on which an electronic component 700 is mounted. The electronic component 700 illustrated in FIG. 29A includes a semiconductor device 710 in a mold 711. Some components are omitted in FIG. 29A to show the inside of the electronic component 700. The electronic component 700 includes a land 712 outside the mold 711. The land 712 is electrically connected to an electrode pad 713, and the electrode pad 713 is electrically connected to the semiconductor device 710 through a wire 714. The electronic component 700 is mounted on a printed circuit board 702, for example. A plurality of such electronic components are combined and electrically connected to each other on the printed circuit board 702, which forms the circuit board 704.

The semiconductor device 710 includes a driver circuit layer 715 and a storage layer 716. The storage layer 716 has a structure in which a plurality of memory cell arrays are stacked. A stacked-layer structure of the driver circuit layer 715 and the storage layer 716 can be a monolithic stacked-layer structure. In the monolithic stacked-layer structure, layers can be connected to each other without using a through electrode technique such as TSV (Through Silicon Via) or a bonding technique such as Cu-to-Cu direct bonding. The monolithic stacked-layer structure of the driver circuit layer 715 and the storage layer 716 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is employed; thus, the number of connection pins can be increased. An increase in the number of connection pins enables parallel operations, which can increase the bandwidth of the memory (also referred to as a memory bandwidth).

It is preferable that the plurality of memory cell arrays included in the storage layer 716 be formed using OS transistors and be monolithically stacked. Monolithically stacking the plurality of memory cell arrays can improve one or both of a memory bandwidth and a memory access latency. Note that a bandwidth refers to a data transfer volume per unit time, and an access latency refers to time from access to start of data transmission. In the case where the storage layer 716 is formed using Si transistors, it is difficult to obtain the monolithic stacked-layer structure as compared with the case where the storage layer 716 is formed using OS transistors. Thus, an OS transistor is superior to a Si transistor in the monolithic stacked-layer structure.

The semiconductor device 710 may be referred to as a die. In this specification and the like, a die refers to each of chip pieces obtained by dividing a circuit pattern formed on a circular substrate (also referred to as a wafer) or the like into dice in the manufacturing process of a semiconductor chip, for example. Examples of a semiconductor material that can be used for a die include silicon (Si), silicon carbide (SiC), and gallium nitride (GaN). A die obtained from a silicon substrate (also referred to as a silicon wafer) may be referred to as a silicon die, for example.

FIG. 29B is a perspective view of an electronic component 730. The electronic component 730 is an example of a SiP (System in Package) or an MCM (Multi Chip Module). In the electronic component 730, an interposer 731 is provided over a package substrate 732 (printed circuit board), and a semiconductor device 735 and a plurality of the semiconductor devices 710 are provided over the interposer 731.

The electronic component 730 that includes the semiconductor device 710 as a high bandwidth memory (HBM) is illustrated as an example. The semiconductor device 735 can be used for an integrated circuit such as a CPU, a GPU, or an FPGA (Field Programmable Gate Array), for example.

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the package substrate 732. Accordingly, the interposer is referred to as a “redistribution substrate” or an “intermediate substrate” in some cases. Furthermore, a through electrode is provided in the interposer 731 and the through electrode is used to electrically connect an integrated circuit and the package substrate 732 in some cases. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP or an MCM that includes a silicon interposer, a decrease in reliability due to a difference in the coefficient of expansion between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected to each other using a silicon interposer, TSV, and the like, a space for the width of the terminal pitches and the like is needed. Thus, in the case where the size of the electronic component 730 is to be reduced, the width of the terminal pitches causes a problem, which sometimes makes it difficult to provide a large number of wirings for a wide memory bandwidth. For this reason, the above-described monolithic stacked-layer structure using OS transistors is suitable. A composite structure combining memory cell arrays stacked using TSV and monolithically stacked memory cell arrays may be employed.

In addition, a heat sink (a radiator plate) may be provided to overlap with the electronic component 730. In the case of providing a heat sink, the heights of integrated circuits provided on the interposer 731 are preferably equal to each other. For example, in the electronic component 730 described in this embodiment, the heights of the semiconductor devices 710 and the semiconductor device 735 are preferably equal to each other.

To mount the electronic component 730 on another substrate, an electrode 733 may be provided on a bottom portion of the package substrate 732. FIG. 29B illustrates an example in which the electrode 733 is formed of a solder ball. Solder balls are provided in a matrix on the bottom portion of the package substrate 732, so that BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by any of various mounting methods not limited to BGA and PGA. Examples of a mounting method include an SPGA (Staggered Pin Grid Array), an LGA (Land Grid Array), a QFP (Quad Flat Package), a QFJ (Quad Flat J-leaded package), and a QFN (Quad Flat Non-leaded package).

### Electronic Device

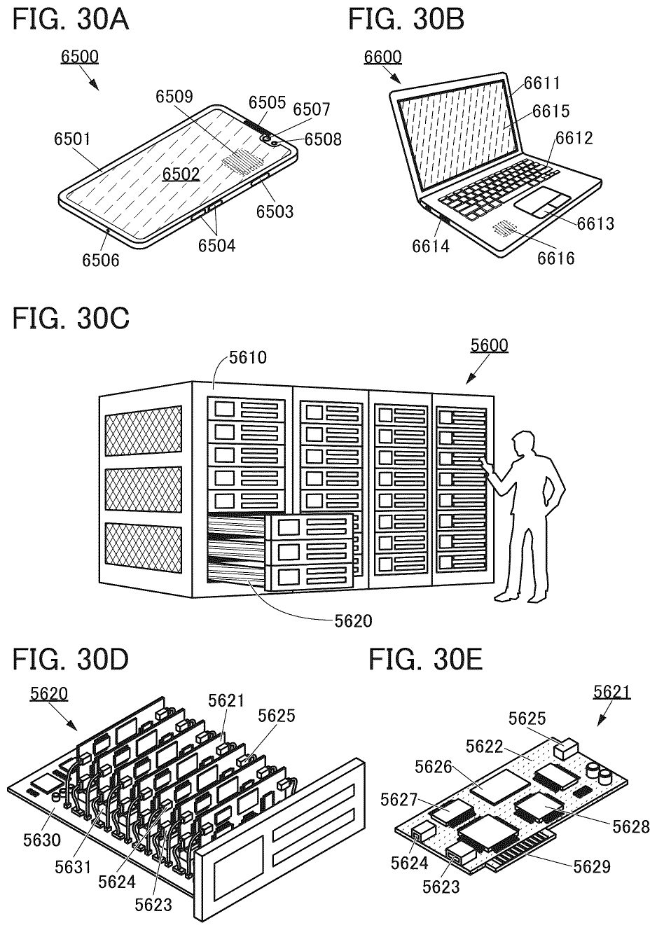

FIG. 30A is a perspective view of an electronic device 6500. The electronic device 6500 illustrated in FIG. 30A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, a control device 6509, and the like. One or more selected from a CPU, a GPU, and a storage device are provided as the control device 6509, for example. The semiconductor device of one embodiment of the present invention can be used for the display portion 6502, the control device 6509, and the like.

An electronic device 6600 illustrated in FIG. 30B is an information terminal that can be used as a notebook personal computer. The electronic device 6600 includes a housing 6611, a keyboard 6612, a pointing device 6613, an external connection port 6614, a display portion 6615, a control device 6616, and the like. One or more selected from a CPU, a GPU, and a storage device are provided as the control device 6616, for example. The semiconductor device of one embodiment of the present invention can be used for the display portion 6615, the control device 6616, and the like. Note that the semiconductor device of one embodiment of the present invention is preferably used for the control device 6509 and the control device 6616, in which case power consumption can be reduced.

### Large Computer

FIG. 30C is a perspective view of a large computer 5600. In the large computer 5600 illustrated in FIG. 30C, a plurality of rack mount computers 5620 are stored in a rack 5610. Note that the large computer 5600 may be referred to as a supercomputer.

The computer 5620 can have a structure in a perspective view of FIG. 30D, for example. In FIG. 30D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 30E is an example of a processing board provided with a CPU, a GPU, a storage device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Although FIG. 30E illustrates semiconductor devices other than the semiconductor device 5626, the semiconductor device 5627, and the semiconductor device 5628, the following description of the semiconductor device 5626, the semiconductor device 5627, and the semiconductor device 5628 is referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. For another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not shown) for inputting and outputting signals, and when the terminal is inserted in a socket (not shown) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a storage device. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### Space Equipment

The semiconductor device of one embodiment of the present invention can be suitably used as space equipment such as equipment that processes and stores information.

The semiconductor device of one embodiment of the present invention can include an OS transistor. A change in electrical characteristics of the OS transistor due to radiation irradiation is small. That is, the OS transistor is highly resistant to radiation and thus can be suitably used in an environment where radiation can enter. For example, the OS transistor can be suitably used in outer space.

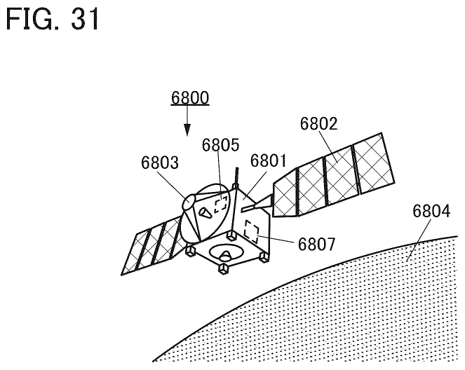

FIG. 31 illustrates an artificial satellite 6800 as an example of space equipment. The artificial satellite 6800 includes a body 6801, a solar panel 6802, an antenna 6803, a secondary battery 6805, and a control device 6807. FIG. 31 illustrates a planet 6804 in outer space, for example. Note that outer space refers to, for example, space at an altitude greater than or equal to 100 km, and outer space in this specification may also include thermosphere, mesosphere, and stratosphere.

Although not illustrated in FIG. 31, a battery management system (also referred to as BMS) or a battery control circuit may be provided in the secondary battery 6805. The battery management system or the battery control circuit preferably includes an OS transistor, in which case power consumption is low and high reliability is achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for an operation of the artificial satellite 6800 is generated. However, for example, in the situation where the solar panel is not irradiated with sunlight or the amount of sunlight with which the solar panel is irradiated is small, the amount of generated electric power is small. Accordingly, electric power required for an operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can constitute a satellite positioning system.

The control device 6807 has a function of controlling the artificial satellite 6800. One or more selected from a CPU, a GPU, and a storage device are used as the control device 6807, for example. Note that the OS transistor of one embodiment of the present invention is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited thereto. The semiconductor device of one embodiment of the present invention can be suitably used for space equipment such as a spacecraft, a space capsule, or a space probe, for example.

As described above, an OS transistor has excellent effects of achieving a wide memory bandwidth and being highly resistant to radiation as compared with a Si transistor.

### Data Center

The semiconductor device of one embodiment of the present invention can be suitably used for a storage system in a data center, for example. Long-term management of data, such as guarantee of data immutability, is required for the data center. The long-term management of data needs an increase in building size owing to installation of storages and servers for storing an enormous amount of data, stable electric power for data retention, cooling equipment necessary for data retention, and the like.

With the use of the semiconductor device of one embodiment of the present invention for the storage system used in the data center, electric power required for data retention can be reduced and a semiconductor device retaining data can be downsized. Thus, downsizing of the storage system, downsizing of the power supply for retaining data, downscaling of the cooling equipment, and the like can be achieved, for example. This can reduce the space of the data center.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention enables a data center that operates stably even in a high-temperature environment. Thus, the reliability of the data center can be increased.

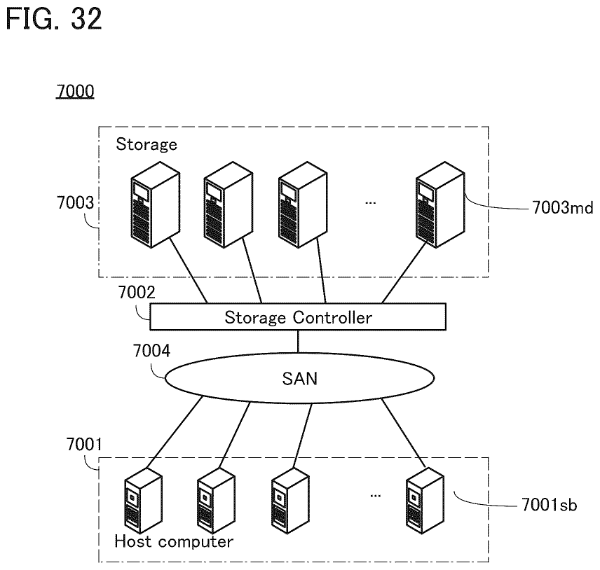

FIG. 32 illustrates a storage system that can be used in a data center. A storage system 7000 illustrated in FIG. 32 includes a plurality of servers 7001sb as a host 7001 (indicated as “Host Computer” in the diagram). The storage system 7000 includes a plurality of storage devices 7003md as a storage 7003 (indicated as “Storage” in the diagram). In the illustrated mode, the host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is still considerably longer than the data access speed of a DRAM that can be used as a cache memory in a storage. In the storage system, in order to solve the problem of low access speed of the storage 7003, a cache memory is usually provided in the storage to shorten the time taken for storing and outputting data.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downsizing is possible by stacking memory cell arrays.

The use of the semiconductor device of one embodiment of the present invention for one or more selected from an electronic component, an electronic device, a large computer, space equipment, and a data center will produce an effect of reducing power consumption. While the demand for energy will increase with increasing performance and integration degree of semiconductor devices, the use of the semiconductor device of one embodiment of the present invention can thus reduce the emission amount of greenhouse gas typified by carbon dioxide (CO₂). The semiconductor device of one embodiment of the present invention can be effectively used as one of the global warming countermeasures because of its low power consumption.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

### EMBODIMENT 5

In this embodiment, a structure example of a display apparatus for which the stacked-layer structure described in the above embodiment is used and an electronic device including the display apparatus will be described.

### Structure Example of Display Apparatus

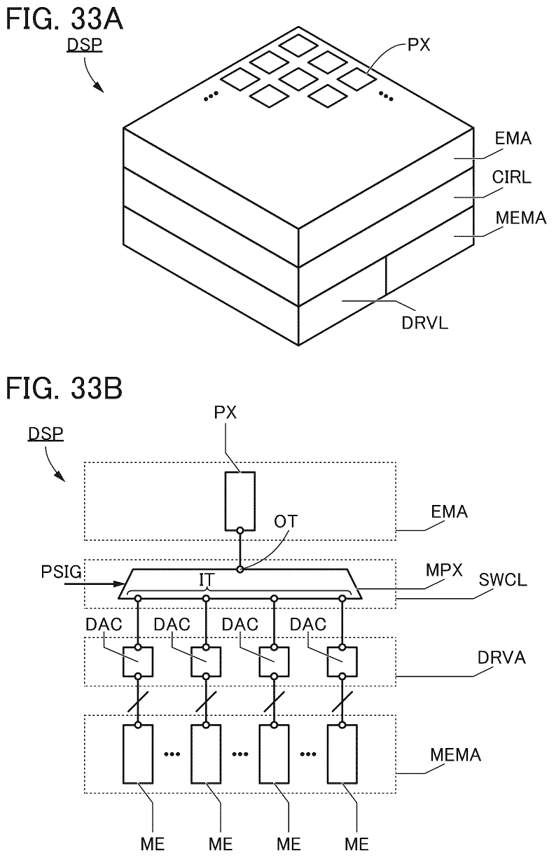

FIG. 33A is a schematic perspective view illustrating a structure example of the display apparatus DSP employing the stacked-layer structure, and FIG. 33B is a block diagram of the display apparatus DSP.

The display apparatus DSP includes a storage circuit region MEMA, a driver circuit region DRVA, the circuit layer SWCL, and a display region EMA. Note that the storage circuit region MEMA and the driver circuit region DRVA are positioned below the circuit layer SWCL, and the display region EMA is positioned above the circuit layer SWCL. That is, in the display apparatus DSP, the storage circuit region MEMA, the driver circuit region DRVA, the circuit layer SWCL, and the display region EMA are stacked in this order from the bottom.

The storage circuit region MEMA includes a plurality of storage circuits ME, for example. For the storage circuit ME, the storage circuit ME in Embodiment 1 can be referred to. Thus, the storage circuit region MEMA may include a storage circuit ME including, for example, DRAM, DOSRAM (registered trademark), NOSRAM (registered trademark), SRAM, FeRAM, ReRAM, MRAM, or PRAM. FIG. 33B illustrates an example in which the storage circuits ME are storage circuits that store digital data, and each of the storage circuits ME is configured to transmit one-bit or multi-bit data to the circuit layer SWCL. The storage circuit ME stores image data to be transmitted to a pixel circuit PX described later.

For example, the storage circuit ME has a function of reading 8-bit (1-byte) image data and transmitting the image data to the driver circuit region DRVA described later. Note that data that can be processed by the storage circuit ME is not limited to 8-bit data, and data that is less than 8 bits, such as 1-bit data, 2-bit data, or 4-bit data, may be processed, for example. Data that exceeds 8 bits, such as 16-bit data, 32-bit data, 64-bit data, 128-bit data, or 256-bit data, may be processed, for example.

The driver circuit region DRVA includes a plurality of digital-analog converter circuits DAC, for example. The digital-analog converter circuit DAC has a function of converting image data, which is digital data, read from the storage circuit ME into analog data. The driver circuit region DRVA has a function of transmitting the converted analog data to the circuit layer SWCL.

The circuit layer SWCL includes the selector MPX, for example. For the selector MPX, the description of the selector MPX in Embodiment 1 can be referred to.

The display region EMA includes, for example, a plurality of pixel circuits PX. In particular, the pixel circuits PX are preferably arranged in an array in the display region EMA.

The plurality of input terminals IT of the selector MPX are electrically connected to the respective digital-analog converter circuits DAC in the driver circuit region DRVA. The output terminal OT of the selector MPX is electrically connected to one of the plurality of pixel circuits PX included in the display region EMA.

The selector MPX has a function of establishing electrical continuity between one of the plurality of input terminals IT of the selector MPX and the output terminal OT of the selector MPX in accordance with a signal PSIG input to the selector MPX, for example. The selector MPX also has a function of breaking electrical continuity between the other input terminals IT of the selector MPX and the output terminal OT of the selector MPX, for example.

By constituting the display apparatus DSP in the above manner, the display apparatus DSP can select image data retained in each of the plurality of storage circuits ME in the storage circuit region MEMA and display the selected image data on one of the plurality of pixel circuits PX in the display region EMA.

Next, a configuration example of the pixel PX is described.

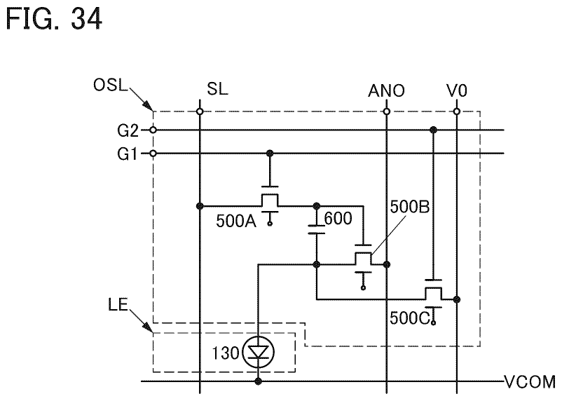

FIG. 34 illustrates a circuit layer OSL that can be included in the pixel circuit PX and a light-emitting layer LE connected to the circuit layer OSL. Note that in FIG. 34, the light-emitting layer LE includes a light-emitting device 130. FIG. 34 is a diagram illustrating connection of circuit elements included in the circuit layer OSL included in the pixel circuit PX.

The circuit layer OSL includes the transistor 500A, a transistor 500B, a transistor 500C, and the capacitor 600. Note that as each of the transistor 500A, the transistor 500B, and the transistor 500C, for example, the transistor that can be used as the transistor M1 described in Embodiment 1 can be used. In particular, each of the transistor 500A, the transistor 500B, and the transistor 500C is preferably an OS transistor. Note that FIG. 34 illustrates OS transistors each including a back gate electrode as the transistor 500A, the transistor 500B, and the transistor 500C. In that case, a structure in which the back gate electrode is supplied with the same signal as a gate electrode or a structure in which the back gate electrode is supplied with a signal different from that of the gate electrode can be employed. Although each of the transistor 500A, the transistor 500B, and the transistor 500C illustrated in FIG. 34 includes a back gate electrode, each of the transistor 500A, the transistor 500B, and the transistor 500C does not necessarily include a back gate electrode.

The transistor 500B includes a gate electrode electrically connected to the transistor 500A, a first electrode electrically connected to the light-emitting device 130, and a second electrode electrically connected to a wiring ANO. The wiring ANO is a wiring for supplying a potential for supplying current to the light-emitting device 130.

The transistor 500A includes a first terminal electrically connected to the gate electrode of the transistor 500B, a second terminal electrically connected to the wiring SL functioning as a source line, and a gate electrode having a function of controlling switching of the on state and the off state on the basis of the potential of a wiring G1 functioning as a gate line.

Since the wiring SL functions as a source line in the pixel circuit PX, the image data transmitted to the wiring SL is image data output from the selector MPX of the circuit layer SWCL.

The transistor 500C includes a first terminal electrically connected to a wiring VO, a second terminal electrically connected to the light-emitting device 130, and a gate electrode having a function of controlling switching of the on state and the off state on the basis of the potential of a wiring G2 functioning as a gate line. The wiring V0 is a wiring for supplying a reference potential and a wiring for outputting a current flowing through the circuit layer OSL to the driver circuit region DRVA.

The capacitor 600 includes a conductive film electrically connected to the gate electrode of the transistor 500B and a conductive film electrically connected to a second electrode of the transistor 500C.

The light-emitting device 130 includes a first electrode electrically connected to the first electrode of the transistor 500B and a second electrode electrically connected to a wiring VCOM. The wiring VCOM is a wiring for supplying a potential for supplying current to the light-emitting device 130.

Accordingly, the intensity of light emitted from the light-emitting device 130 can be controlled in accordance with an image signal supplied to the gate electrode of the transistor 500B. Furthermore, variations in the gate-source voltage of the transistor 500B can be inhibited by the reference potential of the wiring VO supplied through the transistor 500C.

A current value that can be used for setting of pixel parameters can be output from the wiring V0. Specifically, the wiring VO can function as a monitor line for outputting a current flowing through the transistor 500B or a current flowing through the light-emitting device 130 to the outside. A current output to the wiring VO is converted into a voltage by, for example, a source follower circuit and is output to the outside. Alternatively, for example, a current output to the wiring V0 can be converted to a digital signal by an analog-digital converter circuit and output to a circuit for performing dimming and toning processing. Note that the above-described source follower circuit, analog-digital converter circuit, and circuit for performing dimming and toning processing may be included in the driver circuit region DRVA, for example.

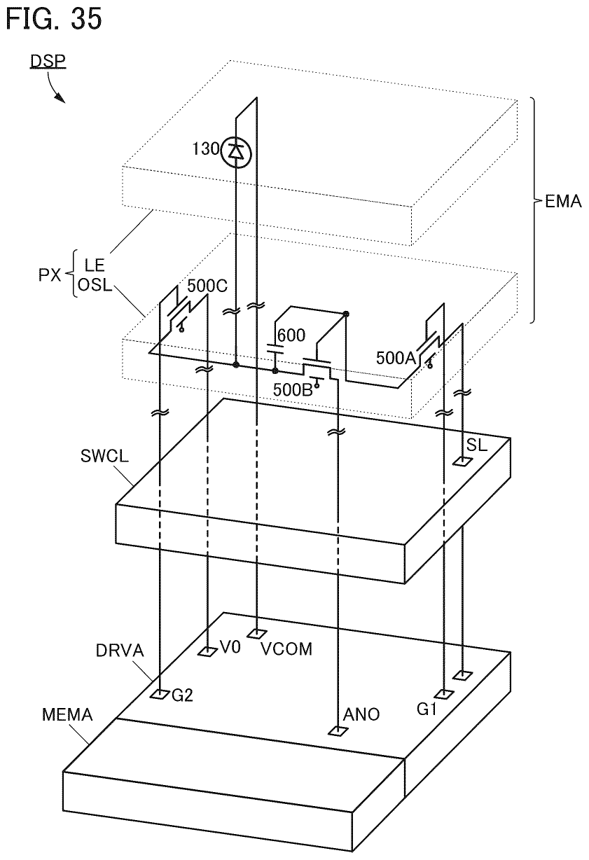

FIG. 35 schematically illustrates the vertical relation between the driver circuit region DRVA, the storage circuit region MEMA, the circuit layer SWCL, the circuit layer OSL including a plurality of transistors included in the pixel circuit PX, and the light-emitting layer LE including the light-emitting device 130. Note that the display region EMA of the display apparatus DSP illustrated in FIG. 35 includes the circuit layer OSL and the light-emitting layer LE, for example.

Note that in the structure illustrated as an example in FIG. 35, the wirings electrically connecting the circuit layer OSL and the driver circuit region DRVA can be shortened, so that wiring resistance of the wirings can be reduced. Thus, data can be written at high speed, which enables high-speed driving of the display apparatus DSP. Therefore, even when the number of pixel circuits PX included in the display apparatus DSP is large, a sufficiently long frame period can be ensured and thus the pixel density of the display apparatus DSP can be increased. In addition, the increased pixel density of the display apparatus DSP can increase the resolution of an image displayed by the display apparatus DSP. For example, the pixel density of the display apparatus DSP can be greater than or equal to 500 ppi, preferably greater than or equal to 1000 ppi, further preferably greater than or equal to 3000 ppi, still further preferably greater than or equal to 5000 ppi, still further preferably greater than or equal to 6000 ppi. Thus, the display apparatus DSP can be, for example, a display apparatus for XR (Extended Reality or Cross Reality) such as AR (augmented reality) or VR (virtual reality), and is preferably used in an electronic device with a short distance between a user and a display portion such as an HMD (head-mounted display).

### Structure Example of Electronic Device

Next, examples of electronic devices in which the above-described display apparatus DSP can be used are described.

The electronic device includes the display apparatus and one or more selected from an antenna, a battery, a housing, a camera, a speaker, a microphone, a touch sensor, and an operation button, for example.

The electronic device may include a secondary battery, and it is preferable that the secondary battery be capable of being charged by contactless power transmission.

Examples of the secondary battery include a lithium ion secondary battery (e.g., a lithium polymer battery using a gel electrolyte (lithium ion polymer battery)), a nickel-hydride battery, a nickel-cadmium battery, an organic radical battery, a lead-acid battery, an air secondary battery, a nickel-zinc battery, or a silver-zinc battery.

The electronic device may include an antenna. When a signal is received by the antenna, the electronic device can display a video, data, or the like on a display portion. When the electronic device includes the antenna and a secondary battery, the antenna may be used for contactless power transmission.

A display region in an electronic device can display a video with a definition of, for example, full high definition, 4K2K, 8K4K, 16K8K, or higher.

Examples of the electronic devices include electronic devices with relatively large screens, such as a television device, a laptop personal computer, a monitor device, digital signage, a pachinko machine, and a game machine. Examples of the electronic devices further include a digital camera, a digital video camera, a digital photo frame, a mobile phone, a portable game machine, a portable information terminal, and an audio reproducing device.

The electronic device can be incorporated along a flat surface or a curved surface of an inside wall or an outside wall of a house or a building. The electronic device can be incorporated along a flat surface or a curved surface of an interior or an exterior of a car or the like.

### Mobile Phone

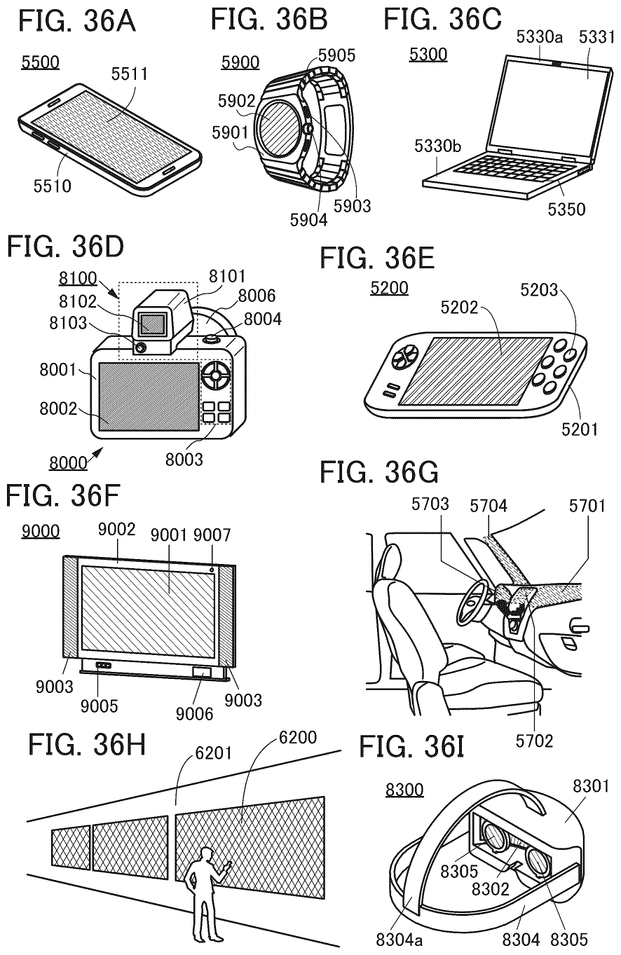

An information terminal 5500 illustrated in FIG. 36A is a mobile phone (smartphone), which is a type of information terminal. The information terminal 5500 includes a housing 5510 and a display portion 5511, and as input interfaces, a touch panel is provided in the display portion 5511 and a button is provided in the housing 5510.

### Wearable Terminal

FIG. 36B is an external view of an information terminal 5900 that is an example of a wearable terminal. The information terminal 5900 includes a housing 5901, a display portion 5902, an operation button 5903, a crown 5904, and a band 5905.

### Information Terminal

FIG. 36C illustrates a laptop information terminal 5300. The laptop information terminal 5300 illustrated in FIG. 36C includes, for example, a display portion 5331 in a housing 5330a and a keyboard portion 5350 in a housing 5330b.

Although the smartphone, the wearable terminal, and the laptop information terminal are respectively illustrated in FIG. 36A to FIG. 36C as examples of the electronic devices, one embodiment of the present invention can be used for information terminals other than a smartphone, a wearable terminal, and a laptop information terminal. Examples of information terminals other than a smartphone, a wearable terminal, and a laptop information terminal include a PDA (Personal Digital Assistant), a desktop information terminal, and a workstation.

### Camera

FIG. 36D is an external view of a camera 8000 to which a finder 8100 is attached. The camera 8000 includes a housing 8001, a display portion 8002, operation buttons 8003, and a shutter button 8004. In addition, a detachable lens 8006 is attached to the camera 8000. The finder 8100 includes a housing 8101, a display portion 8102, and a button 8103.

Note that the lens 8006 and the housing may be integrated with each other in the camera 8000.

The camera 8000 can take images by the press of the shutter button 8004 or touch on the display portion 8002 functioning as a touch panel.

The housing 8001 includes a mount including an electrode, so that, in addition to the finder 8100, for example, a stroboscope can be connected to the housing.

The housing 8101 is attached to the camera 8000 with the mount engaging with a mount of the camera 8000. In the finder 8100, a video received from the camera 8000 can be displayed on the display portion 8102.

The button 8103 has a function of a power button.

The display apparatus of one embodiment of the present invention can be used for the display portion 8002 of the camera 8000 and the display portion 8102 of the finder 8100. Note that a finder may be incorporated in the camera 8000.

### Game Machine

FIG. 36E is an external view of a portable game machine 5200 which is an example of a game machine. The portable game machine 5200 includes a housing 5201, a display portion 5202, and a button 5203.

Videos displayed on the portable game machine 5200 can be output with a display apparatus provided in a television device, a personal computer display, a game display, or a head-mounted display.

The portable game machine 5200 with low power consumption can be provided by applying the display apparatus described in the above embodiment to the portable game machine 5200. Moreover, heat generation from a circuit can be reduced owing to low power consumption; thus, the influence of heat generation on the circuit itself, a peripheral circuit, and a module can be reduced.

Although FIG. 36E illustrates the portable game machine as an example of a game machine, the electronic device of one embodiment of the present invention is not limited thereto. Examples of the electronic device of one embodiment of the present invention include a stationary game machine, an arcade game machine installed in entertainment facilities (e.g., a game center and an amusement park), and a throwing machine for batting practice installed in sports facilities.

### Television Device

FIG. 36F is a perspective view illustrating a television device. A television device 9000 includes a housing 9002, a display portion 9001, speakers 9003, an operation key 9005 (including a power switch or an operation switch), a connection terminal 9006, and a sensor 9007 (e.g., a sensor having a function of measuring force, displacement, a position, speed, acceleration, angular velocity, rotational frequency, distance, light (including infrared rays), liquid, magnetism, temperature, a chemical substance, sound, time, hardness, an electric field, current, voltage, power, radiation, a flow rate, humidity, gradient, oscillation, or an odor. Alternatively, a smell or light (including infrared rays), for example). The storage device of one embodiment of the present invention can be provided in the television device. The television device can include the display portion 9001 of, for example, 50 inches or more or 100 inches or more.

The television device 9000 with low power consumption can be provided by applying the display apparatus described in the above embodiment to the television device 9000. Moreover, heat generation from a circuit can be reduced owing to low power consumption; thus, the influence of heat generation on the circuit itself, a peripheral circuit, and a module can be reduced.

### Moving Vehicle

The display apparatus of one embodiment of the present invention can be used around a driver's seat in a car, which is a moving vehicle.

FIG. 36G is a diagram illustrating an area around a windshield inside a car. FIG. 36G illustrates a display panel 5701, a display panel 5702, and a display panel 5703 that are attached to a dashboard and a display panel 5704 that is attached to a pillar.

The display panel 5701 to the display panel 5703 can display various kinds of information such as navigation information, a speedometer, a tachometer, a mileage, a fuel meter, a gearshift indicator, and air-condition settings. The display content and layout displayed on the display panels can be changed appropriately to suit the user's preferences, so that the design can be improved. The display panel 5701 to the display panel 5703 can also be used as lighting devices.

The display panel 5704 can compensate for the view obstructed by the pillar (blind areas) by showing a video taken by an imaging unit provided for the car body. That is, showing an image taken by an imaging unit provided on the outside of the car body leads to elimination of blind areas and enhancement of safety. Display of a video that complements for a portion that cannot be seen makes it possible to confirm safety more naturally and comfortably. The display panel 5704 can also be used as a lighting device.

The display apparatus of one embodiment of the present invention can be used for the display panel 5701 to the display panel 5704, for example.

Although a car is described above as an example of a moving vehicle, the moving vehicle is not limited to a car. Examples of moving vehicles include a train, a monorail train, a ship, and a flying object (e.g., a helicopter, an unmanned aircraft (a drone), an airplane, and a rocket), and these moving vehicles can include the display apparatus of one embodiment of the present invention.

### Digital Signage

FIG. 36H illustrates an example of digital signage that can be attached to a wall. FIG. 36H illustrates a state where digital signage 6200 is attached to a wall 6201. The display apparatus of one embodiment of the present invention can be used in a display portion of the digital signage 6200, for example. An interface such as a touch panel may be provided in the digital signage 6200, for example.

Although the electronic device attachable to a wall is described above as an example of digital signage, the kind of digital signage is not limited thereto. Examples of the digital signage include digital signage attached to a pillar, freestanding digital signage placed on the ground, and digital signage mounted on a rooftop or a side wall of a building.

### Head-Mounted Display

FIG. 36I is a diagram illustrating the appearance of an electronic device 8300 that is a head-mounted display. The electronic device 8300 includes a housing 8301, a display portion 8302, a band-shaped fixture member 8304, a fixture member 8304a worn on a head, and a pair of lenses 8305.

Although not illustrated in FIG. 36I, the electronic device 8300 may include an interface such as an operation button or a power button.

A user can perceive display on the display portion 8302 through the lenses 8305. Note that the display portion 8302 is preferably placed in the curved state, in which case the user can feel a high realistic sensation. Another image displayed on another region of the display portion 8302 is seen through the lenses 8305, so that three-dimensional display using parallax can be performed. Note that the structure is not limited to the structure where one display portion 8302 is provided; two display portions 8302 may be provided and one display portion may be provided per eye of the user.

For the display portion 8302, a display apparatus with an extremely high resolution is preferably used, for example. When a high-resolution display apparatus is used for the display portion 8302, it is possible to display a more realistic video that does not allow the user to perceive pixels even when the displayed image is magnified using the lenses 8305.

The head-mounted display, which is an electronic device, may be an electronic device which is a glasses-type head-mounted display, instead of the electronic device 8300 in FIG. 36I, which is a goggle-type head-mounted display.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

### REFERENCE NUMERALS

DEV: semiconductor device, MEML_L: storage layer, MEML_H: storage layer, SWCL: circuit layer, SWCLA: circuit layer, SWCLB: circuit layer, SWCLC: circuit layer, ME_L: storage circuit, ME_H: storage circuit, MC_L: memory cell, MC_H: memory cell, WL_L: wiring, WL_H: wiring, BL_L: wiring, BL_H: wiring, BLUT_L: wiring, BLUT_H: wiring, MA_L: region, MA_H: region, MPX: selector, DMPX: selector, SW[00000]: switch, SW[00100]: switch, SW[00111]: switch, SW[01000]: switch, SW[01100]: switch, SW[01111]: switch, SW[10000]: switch, SW[10100]: switch, SW[10111]: switch, SW[11111]: switch, SW1: switch, SW2: switch, SW3: switch, SW4: switch, SW5: switch, SW6: switch, SWa1: switch, SWa2: switch, SWb1: switch, SWb2: switch, SWb3: switch, SWb4: switch, IT: terminal, IT1: terminal, IT2: terminal, OT: terminal, OT1: terminal, OT2: terminal, SL1: wiring, SL2: wiring, SL3: wiring, SL4: wiring, SL5: wiring, SL6: wiring, SLa1: wiring, SLa2: wiring, SLb1: wiring, SLb2: wiring, PON1: signal, PON2: signal, ADDR: signal, BW: signal, CE: signal, GW: signal, CLK: signal, WAKE: signal, WDA: signal, RDA: signal, SSIG: signal, DSIG: signal, MC: memory cell, M1: transistor, M2: transistor, M4: transistor, M4r: transistor, M5: transistor, M5r: transistor, M6: transistor, MN: transistor, C1: capacitor, C2: capacitor, C3: capacitor, C3r: capacitor, VR: variable resistor, MR: MTJ element, PCM: phase change memory, INV1: logic circuit, INV2: logic circuit, BL: wiring, BL[1]: wiring, BL[n]: wiring, BLB: wiring, WBL[1]: wiring, WBL[n]: wiring, RBL[1]: wiring, RBL[n]: wiring, WL: wiring, WL[1]: wiring, WL[m]: wiring, WIL: wiring, W2L: wiring, SL[1]: wiring, SL[n]: wiring, CL: wiring, CL[1]: wiring, CL[m]: wiring, C1L: wiring, C2L: wiring, OSL: circuit layer, ME: storage circuit, DRV: driver circuit region, DRVA: driver circuit region, VCOM: wiring, ANO: wiring, PSIG: signal, 10: memory cell, 22: PSW, 23: PSW, 31: peripheral circuit, 32: control circuit, 33: voltage generation circuit, 41: peripheral circuit, 42: row decoder, 43: row driver, 44: column decoder, 45: column driver, 46: sense amplifier, 47: input circuit, 48: output circuit, 50: driver circuit region, 60: cell array layer, 60_1: cell array layer, 60_2: cell array layer, 60_3: cell array layer, 60_k: cell array layer, 60_N: cell array layer, 70: cell array, 71: driver circuit, 72: driver circuit, 75: memory cell, 80: control processing region, 81: ALU, 82: ALU controller, 83: instruction decoder, 84: interrupt controller, 85: timing controller, 90: circuit layer, 100: memory hierarchy, 101: register, 102: first cache memory, 103: second cache memory, 104: main memory, 105: auxiliary storage device, 301: insulator, 311: substrate, 313: semiconductor region, 314a: low-resistance region, 314b: low-resistance region, 315: insulator, 316: conductor, 320: insulator, 324: insulator, 326: insulator, 328: conductor, 330: conductor, 350: insulator, 352: insulator, 356: conductor, 357: insulator, 361: conductor, 362: conductor, 363a: conductor, 363b: conductor, 364: conductor, 365: conductor, 366: conductor, 367: conductor, 400: transistor, 500: transistor, 500A: transistor, 500B: transistor, 500C: transistor, 502: conductor, 503: conductor, 504: conductor, 505: conductor, 505a: conductor, 505b: conductor, 512: insulator, 514: insulator, 516: insulator, 520: insulator, 522: insulator, 524: insulator, 531: metal oxide, 531a: metal oxide, 531b: metal oxide, 533: metal oxide, 540a: conductor, 540b: conductor, 542a: conductor, 542a1: conductor, 542a2: conductor, 542b: conductor, 542b1: conductor, 542b2: conductor, 543a: region, 543b: region, 544: conductor, 545: conductor, 550: insulator, 551: insulator, 552: insulator, 553: insulator, 554: insulator, 555: insulator, 560: conductor, 560a: conductor, 560b: conductor, 561: conductor, 561a: conductor, 561b: conductor, 563: conductor, 564: conductor, 565: conductor, 574: insulator, 580: insulator, 581: insulator, 583: insulator, 583a: insulator, 583b: insulator, 592: insulator, 593: insulator, 594: insulator, 595: insulator, 596: insulator, 597: insulator, 600: capacitor, 600A: capacitor, 700: electronic component, 704: circuit board, 710: semiconductor device, 711: mold, 712: land, 713: electrode pad, 714: wire, 715: driver circuit layer, 716: storage layer, 730: electronic component, 731: interposer, 732: package substrate, 733: electrode, 735: semiconductor device, 5200: portable game machine, 5201: housing, 5202: display portion, 5203: button, 5300: notebook information terminal, 5330a: housing, 5330b: housing, 5331: display portion, 5350: keyboard portion, 5500: information terminal, 5510: housing, 5511: display portion, 5600: large computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 5900: information terminal, 5901: housing, 5902: display portion, 5903: operation button, 5904: crown, 5905: band, 6200: digital signage, 6201: wall, 6500: electronic device, 6501: housing, 6502: display portion, 6503: power supply button, 6504: button, 6505: speaker, 6506: microphone, 6507: camera, 6508: light source, 6509: control device, 6600: electronic device, 6611: housing, 6612: keyboard, 6613: pointing device, 6614: external connection port, 6615: display portion, 6616: control device, 6800: artificial satellite, 6801: body, 6802: solar panel, 6803: antenna, 6805: secondary battery, 6807: control device, 7000: storage system, 7001: host, 7001sb: server, 7002: storage control circuit, 7003: storage, 7003md: storage device, 7004: storage area network, 8000: camera, 8001: housing, 8002: display portion, 8003: operation button, 8004: shutter button, 8006: lens, 8100: finder, 8101: housing, 8102: display portion, 8103: button, 8300: electronic device, 8301: housing, 8302: display portion, 8304: fixture member, 8304a: fixture member, 8305: lens, 9000: television device, 9001: display portion, 9002: housing, 9003: speaker, 9006: connection terminal, 9007: sensor

1. A semiconductor device comprising:
a first storage layer;
a second storage layer; and
a circuit layer,
wherein the first storage layer comprises a plurality of first storage circuits,
wherein the second storage layer comprises a second storage circuit,
wherein the circuit layer comprises a selector,
wherein the selector comprises a plurality of input terminals and an output terminal,
wherein the first storage layer is positioned below the circuit layer,
wherein the second storage layer is positioned above the circuit layer,
wherein the plurality of first storage circuits are electrically connected to the respective input terminals,
wherein the second storage circuit is electrically connected to the output terminal,
wherein the selector is configured to establish electrical continuity between one selected from the plurality of input terminals and the output terminal, and
wherein the semiconductor device is configured to write data read from the second storage circuit to the first storage circuit through the selector.

2. The semiconductor device according to claim 1, further comprising a semiconductor substrate comprising silicon,
wherein the first storage layer is positioned over the semiconductor substrate,
wherein the first storage circuit comprises a first transistor, and
wherein the first transistor comprises silicon in a channel formation region.

3. The semiconductor device according to claim 2,
wherein the second storage circuit comprises a second transistor,
wherein the second transistor comprises a metal oxide in a channel formation region,
wherein the metal oxide comprises one or more selected from indium, zinc, and an element M, and
wherein the element M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, magnesium, and antimony.

4. The semiconductor device according to claim 3,
wherein data of the second storage circuit has a size of 1 bit, 2 bits, 4 bits, 8 bits, 16 bits, 32 bits, 64 bits, 128 bits, or 256 bits.

5. The semiconductor device according to claim 4,
wherein the first storage circuit and the second storage circuit are not connected through a system bus.

6. A semiconductor device comprising:
a first storage layer;
a second storage layer; and
a circuit layer,
wherein the first storage layer comprises a plurality of first storage circuits,
wherein the second storage layer comprises a second storage circuit,
wherein the second storage circuit comprises a capacitor and a second transistor,
wherein the capacitor comprises a first conductor, a second conductor, a first insulator, and a second insulator,
wherein the second transistor comprises the second conductor, a third conductor, a fourth conductor, a third insulator, a fourth insulator, and a metal oxide,
wherein the circuit layer comprises a selector,
wherein the selector comprises a plurality of input terminals and an output terminal,
wherein the first storage layer is positioned below the circuit layer,
wherein the second storage layer is positioned above the circuit layer,
wherein the first insulator comprises a first opening,
wherein the first conductor is positioned on a side surface and a bottom surface of the first opening and a top surface of the first insulator,
wherein the second insulator is positioned on a top surface of the first insulator and a top surface of the first conductor,
wherein the second conductor is positioned in a region of the top surface of the second insulator that overlaps with the first conductor,
wherein the third insulator is positioned on a top surface of the second conductor,
wherein the third conductor is positioned on a top surface of the third insulator,
wherein the third insulator and the third conductor comprise a second opening,
wherein the metal oxide is positioned on a side surface of the second opening, a top surface of the second conductor, and a top surface of the third conductor,
wherein the fourth insulator is positioned on a top surface of the metal oxide and a top surface of the third conductor,
wherein the fourth conductor is positioned in a region of a top surface of the fourth insulator that overlaps with the metal oxide,
wherein the plurality of first storage circuits are electrically connected to the respective input terminals,
wherein the third conductor is electrically connected to the output terminal,
wherein the selector is configured to establish electrical continuity between one selected from the plurality of input terminals and the output terminal, and
wherein the semiconductor device is configured to write data read from the second storage circuit to the first storage circuit through the selector.

7. The semiconductor device according to claim 6,
wherein the metal oxide comprises one or more selected from indium, zinc, and an element M, and
wherein the element M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, magnesium, and antimony.

8. The semiconductor device according to claim 7, further comprising a semiconductor substrate comprising silicon,
wherein the first storage layer is positioned over the semiconductor substrate,
wherein the first storage circuit comprises a first transistor, and
wherein the first transistor comprises silicon in a channel formation region.

9. The semiconductor device according to claim 8,
wherein the second insulator comprises oxide comprising one or more selected from hafnium, aluminum, gallium, yttrium, zirconium, tungsten, titanium, tantalum, nickel, germanium, and magnesium.

10. The semiconductor device according to claim 9,
wherein data of the second storage circuit has a size of 1 bit, 2 bits, 4 bits, 8 bits, 16 bits, 32 bits, 64 bits, 128 bits, or 256 bits.

11. The semiconductor device according to claim 10,
wherein the first storage circuit and the second storage circuit are not connected through a system bus.

12. An electronic device comprising:
the semiconductor device according to claim 1; and a housing.
